(19) United States
(12) Patent Application Publication
(10) Pub. No.: US 2025/0248228 A1
(43) Pub. Date: Jul. 31, 2025

(54) DISPLAY PANEL AND METHOD FOR MANUFACTURING THE SAME, DISPLAY PANEL MOTHERBOARD, AND DISPLAY APPARATUS

(71) Applicants: Hefei Visionox Technology Co., Ltd., Hefei (CN); Visionox Technology Inc., Jiangsu (CN)

(72) Inventors: Zhiwei ZHOU, Hefei (CN); Liusong NI, Hefei (CN); Jinfang ZHANG, Hefei (CN); Lu ZHANG, Hefei (CN); Wenyu ZENG, Hefei (CN); Meng ZHANG, Hefei (CN); Jingxi HAN, Hefei (CN); Chuanru DAI, Hefei (CN); Xiujian ZHU, Hefei (CN)

(73) Assignees: Hefei Visionox Technology Co., Ltd., Hefei (CN); Visionox Technology Inc., Jiangsu (CN)

(21) Appl. No.: 18/987,703

(22) Filed: Dec. 19, 2024

Related U.S. Application Data
(63) Continuation of application No. PCT/CN2024/102786, filed on Jun. 30, 2024.

(30) Foreign Application Priority Data
Jan. 29, 2024 (CN) 202410124714.7
Jan. 29, 2024 (CN) 202410124722.1
Mar. 22, 2024 (CN) 202410337767.7
Apr. 15, 2024 (CN) 202410451548.1

(51) Int. Cl. H10K 59/122; H10K 59/12

(52) U.S. Cl. CPC H10K 59/122; H10K 59/1201

(57) ABSTRACT

A display panel and method for manufacturing the same, a display panel motherboard, and a display apparatus. The display panel includes: a base plate; a pixel defining layer; an isolation structure layer including a first isolation layer and a second isolation layer, the isolation structure layer enclosing and forming a plurality of first type of openings and a functional opening; a plurality of light-emitting devices; and a protrusion length of at least a portion of the second isolation layer enclosing and forming the functional opening relative to the first isolation layer and towards the functional opening being less than a protrusion length of the second isolation layer enclosing and forming at least a portion of the first type of openings relative to the first isolation layer and towards the first type of opening.

### CROSS REFERENCE TO RELATED APPLICATION

The present application is a continuation application of International Application No. PCT/CN2024/102786, filed on Jun. 30, 2024, which claims priority to Chinese Patent Application No. 202410124714.7 filed on Jan. 29, 2024, Chinese Patent Application No. 202410124722.1 filed on Jan. 29, 2024, Chinese Patent Application No. 202410337767.7 filed on Mar. 22, 2024, and Chinese Patent Application No. 202410451548.1 filed on Apr. 15, 2024, all of which are incorporated herein by reference in their entireties.

### TECHNICAL FIELD

The present application relates to the technical field of display, and particularly to a display panel and method for manufacturing the same, a display panel motherboard, and a display apparatus.

### BACKGROUND

Planar display apparatus based on Organic Light Emitting Diode (OLED) and Light Emitting Diode (LED), etc., are widely used in cell phones, TVs, notebook computers, desktop computers, and other consumer electronic products due to their high image quality, power saving, thin body and wide range of applications, and have become the mainstream of the display apparatus.

However, the processing performance of the current OLED display products needs to be improved.

### SUMMARY

Embodiments of the present application provide a display panel and method for manufacturing the same, a display panel motherboard, and a display apparatus, aiming to improve the processing reliability of the display panel.

Some embodiments of a first aspect of the present application provide a display panel having a display area and a non-display area, the display panel including: a base plate; a pixel defining layer arranged at one side of the base plate, the pixel defining layer including a pixel defining portion and a plurality of pixel openings enclosed and formed by the pixel defining portion; an isolation structure layer arranged at a side of the pixel defining layer away from the base plate, the isolation structure layer including a first isolation layer and a second isolation layer located at a side of the first isolation layer away from the base plate, the isolation structure layer enclosing and forming a plurality of first type of openings located in the display area and a functional opening located in the non-display area, the first type of opening being in communication with a corresponding one of the pixel openings; a plurality of light-emitting devices, at least a portion of a structure of the light-emitting device being arranged within a corresponding one of the first type of openings; and a protrusion length of at least a portion of the second isolation layer enclosing and forming the functional opening relative to the first isolation layer and towards the functional opening being less than a protrusion length of the second isolation layer enclosing and forming at least a portion of the first type of openings relative to the first isolation layer and towards the first type of opening.

Some embodiments of the first aspect of the present application further provide a display panel having a display area and a non-display area, the display panel including: a base plate; a pixel defining layer arranged at one side of the base plate, the pixel defining layer including a pixel defining portion and a plurality of pixel openings enclosed and formed by the pixel defining portion; an isolation structure layer arranged at a side of the pixel defining layer away from the base plate, the isolation structure layer including a first isolation layer and a second isolation layer located at a side of the first isolation layer away from the base plate, the isolation structure layer enclosing and forming a plurality of first type of openings located in the display area and a functional opening located in the non-display area, the first type of opening being in communication with a corresponding one of the pixel openings, the second isolation layer enclosing and forming the first type of opening protruding from the first isolation layer towards the first type of opening; a plurality of light-emitting devices, at least a portion of a structure of the light-emitting device being arranged within a corresponding one of the first type of openings; and the second isolation layer forming a hollow structure at a side of the first isolation layer away from the base plate, the hollow structure being in communication with the functional opening and arranged around at least a portion of the functional opening.

Some embodiments of the first aspect of the present application further provide a display panel having a display area and a non-display area, the display panel including: a base plate; a pixel defining layer arranged at one side of the base plate, the pixel defining layer including a pixel defining portion and a plurality of pixel openings enclosed and formed by the pixel defining portion; an isolation structure layer arranged at one side of the base plate and including an isolation structure at least partially located in the display area and an edge structure connected with the isolation structure and located in the non-display area, the isolation structure enclosing and forming an isolation opening in communication with the pixel opening, the edge structure including a main structure connected with the isolation structure and a plurality of convex structures protruding towards a second area relative to the main structure, the edge structure enclosing and forming a functional opening, an edge area of the functional opening including a first recess protruding towards the edge structure, the first recess being arranged penetrating the edge structure in a thickness direction of the display panel and located between adjacent convex structures; and a plurality of light-emitting devices, at least a portion of a structure of the light-emitting device being arranged within the isolation opening.

Some embodiments of the first aspect of the present application further provide a display panel having a first specific area and a second area that are adjacent, the display panel including: a base plate; an isolation structure arranged at one side of the base plate and located in the first specific area, the isolation structure enclosing and forming an isolation opening; a plurality of first auxiliary structures located within the second area and arranged at a side of the base plate towards the isolation structure, the first auxiliary structures being spaced apart from the isolation structure, and adjacent first auxiliary structures being spaced apart; and a light-emitting layer including a light-emitting unit arranged within the isolation opening.

Some embodiments of the first aspect of the present application further provide a display panel having a display area and a non-display area that are adjacent, the display panel including: a base plate; an isolation structure arranged at one side of the base plate and enclosing and forming an isolation opening; a plurality of convex structures spaced apart from each other and connected to an edge portion of the isolation structure away from the display area; and a light-emitting layer located in the display area and including a light-emitting unit arranged within the isolation opening.

Some embodiments of the first aspect of the present application further provide a display panel having a second sub-area and a display area surrounding the second sub-area; the display panel including: a base plate; an isolation structure layer located on the base plate and enclosing and forming an isolation opening; in a direction away from the base plate, the isolation structure layer including a first isolation layer and a second isolation layer that are stacked; and in the isolation structure layer around the second sub-area, a protrusion length of a side of the second isolation layer in a direction towards the second sub-area relative to the first isolation layer being less than a protrusion length of a side of the second isolation layer in a direction away from the second sub-area relative to the first isolation layer.

Some embodiments of a second aspect of the present application provide a display panel motherboard having a display area and a non-display area, the non-display area including a first area adjacent to the display area and a second area located at a side of the first area away from the display area, the second area including a first sub-area and a second sub-area located at a side of the first sub-area away from the first area, the display panel including: a base plate; a pixel defining layer arranged at one side of the base plate, the pixel defining layer including a pixel defining portion and a plurality of pixel openings enclosed and formed by the pixel defining portion; an isolation structure layer arranged at a side of the pixel defining layer away from the base plate, the isolation structure layer including an isolation structure, an edge structure, and an auxiliary structure spaced apart from the edge structure, the isolation structure enclosing and forming an isolation opening located in the display area and in communication with the pixel opening, the isolation structure including a first isolation portion and a second isolation portion located at a side of the first isolation portion away from the base plate, the edge structure being located in the first area and enclosing and forming a functional opening, the edge structure including a first edge portion and a second edge portion located at a side of the first edge portion away from the base plate, the auxiliary structure including a second auxiliary structure located in the second sub-area, a protrusion length of at least a portion of the second edge portion relative to the first edge portion and towards the functional opening being less than a protrusion length of the second isolation portion relative to the first isolation portion and towards the isolation opening; and a plurality of light-emitting devices, at least a portion of a structure of the light-emitting device being arranged within a corresponding isolation opening.

Some embodiments of a third aspect of the present application provide a method for manufacturing a display panel having a display area and a non-display area, the method including: preparing a pixel defining material layer on a base plate; preparing an isolation structure layer on the pixel defining material layer, the isolation structure layer including a first isolation layer and a second isolation layer located at a side of the first isolation layer away from the base plate, the isolation structure layer enclosing and forms at least a portion of first type of openings located in the display area and a functional opening located in the non-display area, a protrusion length of at least a portion of the second isolation layer enclosing and forming the functional opening relative to the first isolation layer and towards the functional opening being less than a protrusion length of the second isolation layer enclosing and forming at least a portion of the first type of openings relative to the first isolation layer and towards the first type of opening; depositing a first protective material layer on the isolation structure layer, the first protective material layer forming a first hollow area at the first type of opening located in the display area; and patterning a portion of the pixel defining material layer exposed from the first hollow area and the first type of opening located in the display area to form at least a portion of pixel openings, the pixel opening being in communication with the first type of opening.

Some embodiments of the third aspect of the present application further provide a method for manufacturing a display panel having a display area and a non-display area, the method including: preparing a pixel defining material layer on a base plate; preparing, on the pixel defining material layer, a first isolation material layer located in the display area and the non-display area; preparing, on the first isolation material layer, a second isolation material layer located in the display area and the non-display area; patterning the first isolation material layer and the second isolation material layer within the display area to form at least a portion of first type of openings located in the display area; depositing a first protective material layer on the second isolation material layer, the first protective material layer forming a first hollow area at the first type of opening located in the display area; patterning a portion of the pixel defining material layer exposed from the first hollow area and the first type of opening located in the display area to form at least a portion of pixel openings, the pixel opening being in communication with the first type of opening; and patterning the first isolation material layer and the second isolation material layer within the non-display area to form an isolation structure layer enclosing and forms the first type of openings and a functional opening at least partially located in the non-display area.

Some embodiments of a fourth aspect of the present application provide a display apparatus, including: the display panel of any of the above implementations or the display panel manufactured by the method of any of the above implementations; and a photosensitive assembly arranged corresponding to the functional opening of the display panel.

The display panel according to the embodiments of the present application has a display area and a non-display area, and the display panel includes a base plate, a pixel defining layer, an isolation structure layer, and a plurality of light-emitting devices. The pixel defining layer includes a pixel defining portion and a plurality of pixel openings enclosed and formed by the pixel defining portion, and the isolation structure layer is arranged at a side of the pixel defining layer away from the base plate and encloses and forms a plurality of first type of openings located in the display area and a functional opening located in the non-display area. The functional opening may facilitate increasing the light transmittance of the non-display area, so that when the display panel is applied to a display apparatus, the photosensitive assembly for sensing light in the display apparatus may be correspondingly arranged under the functional opening, and thus the photosensitive assembly can better sense light through the functional opening.

The first type of opening is in communication with the corresponding pixel opening, and both the isolation structure layer and the pixel defining layer may be used to divide the sub-pixels of the display panel. At least a portion of the structure of the light-emitting device is arranged within the corresponding first type of opening, so that the light-emitting device within the first type of opening can be used to achieve light emitting and display of the display area in the display panel.

The isolation structure layer includes a first isolation layer and a second isolation layer located at a side of the first isolation layer away from the base plate, and a protrusion length of at least a portion of the second isolation layer enclosing and forming the functional opening relative to the first isolation layer and towards the functional opening is less than a protrusion length of the second isolation layer enclosing and forming at least a portion of the first type of openings relative to the first isolation layer and towards the first type of opening.

By arranging a greater protrusion length of the second isolation layer enclosing and forming at least a portion of the first type of openings relative to the first isolation layer and towards the first type of opening, when preparing the light-emitting device of the display panel, at least a portion of the material of the light-emitting device may be directly vapor deposited as a whole, and the second isolation layer enclosing and forming the first type of opening can block at least a portion of the material for preparing the light-emitting device to separate the material of the light-emitting device between adjacent sub-pixels, so as to facilitate forming a plurality of light-emitting devices that are spaced apart and located within the first type of openings. Therefore, no fine mask is needed when preparing the light-emitting device of the display panel, for example, no fine metal mask (FMM) is needed when vapor depositing the material of the light-emitting device, thereby better reducing the production and preparation costs of the display panel.

By arranging a less protrusion length of at least a portion of the second isolation layer enclosing and forming the functional opening relative to the first isolation layer and towards the functional opening, when new material is formed on the isolation structure layer during the manufacturing of the display panel, for example, when organic material is formed on the isolation structure layer, the second isolation layer located at the periphery of the functional opening within the non-display area is less likely to block the organic material, and the new material may better fall in the vicinity of the first isolation layer at the periphery of the functional opening. Moreover, when new material is formed on the isolation structure layer, the second isolation layer with a less protrusion length is less likely to excessively block gas discharging, so that gas is less likely to be retained under the second isolation layer at the periphery of the functional opening, thereby better increasing the structure stability and processing reliability of the display panel.

### BRIEF DESCRIPTION OF THE DRAWINGS

The features, advantages and technical effects of the exemplary embodiments of the present application will be described below with reference to the accompanying drawings, which are not drawn to actual scale.

FIG. 1 shows a schematic structural diagram of a display panel according to an embodiment of the present application;

FIG. 2 shows a partial schematic diagram of a display panel according to an embodiment of the present application;

FIG. 3 shows a partial sectional view of a display panel according to an embodiment of the present application;

FIG. 4 shows a partial sectional view of a display panel within a display area according to an embodiment of the present application;

FIG. 5 shows a partial sectional view of a display panel according to another embodiment of the present application;

FIG. 6 shows a partial sectional view of a display panel according to yet another embodiment of the present application;

FIG. 7 shows a partial schematic diagram of a display panel according to another embodiment of the present application;

FIG. 8 shows a partially enlarged schematic diagram of an orthographic projection of an isolation structure layer on a base plate according to an embodiment of the present application;

FIG. 9 shows a partial sectional view of a display panel according to yet another embodiment of the present application;

FIG. 10 shows a partial sectional view of a display panel according to yet another embodiment of the present application;

FIG. 11 shows a partial sectional view of a display panel according to yet another embodiment of the present application;

FIG. 12 shows a partial sectional view of a display panel according to yet another embodiment of the present application;

FIG. 13 shows a partial schematic diagram of a display panel according to yet another embodiment of the present application;

FIG. 14 shows a partial sectional view of a display panel according to yet another embodiment of the present application;

FIG. 15 shows a partial sectional view of a display panel according to yet another embodiment of the present application;

FIG. 16 shows a partial sectional view of a display panel according to yet another embodiment of the present application;

FIG. 17 shows a partial sectional view of a display panel according to yet another embodiment of the present application;

FIG. 18 shows a partially enlarged schematic diagram of an orthographic projection of an isolation structure layer on a base plate according to another embodiment of the present application;

FIG. 19 shows a partial sectional view of a display panel according to yet another embodiment of the present application;

FIG. 20 shows a partial sectional view of a display panel according to yet another embodiment of the present application;

FIG. 21 shows a partial sectional view of a display panel according to yet another embodiment of the present application;

FIG. 22 shows a partial sectional view of a display panel according to yet another embodiment of the present application;

FIG. 23 shows a partial sectional view of a display panel according to yet another embodiment of the present application;

FIG. 24 shows a schematic structural diagram of a display panel according to another embodiment of the present application;

FIG. 25 shows a partial sectional view of a display panel according to yet another embodiment of the present application;

FIG. 26 shows a partial schematic diagram of a display panel according to yet another embodiment of the present application;

FIG. 27 shows a partially enlarged schematic diagram of an orthographic projection of an isolation structure and a first auxiliary structure on a base plate according to an embodiment of the present application;

FIG. 28 shows a partial sectional view of a display panel according to yet another embodiment of the present application;

FIG. 29 shows a partial schematic diagram of a display panel according to yet another embodiment of the present application;

FIG. 30 shows a partially enlarged schematic diagram of an orthographic projection of an isolation structure, a convex structure, and a first auxiliary structure on a base plate according to an embodiment of the present application;

FIG. 31 shows a schematic structural diagram of a display panel according to yet another embodiment of the present application;

FIG. 32 shows a partial sectional view of a display panel according to yet another embodiment of the present application;

FIG. 33 shows a partial schematic diagram of a display panel according to yet another embodiment of the present application;

FIG. 34 shows a partially enlarged schematic diagram of an orthographic projection of an isolation structure and a convex structure on a base plate according to an embodiment of the present application;

FIG. 35 shows a partial schematic diagram of a display panel according to yet another embodiment of the present application;

FIG. 36 shows a partially enlarged schematic diagram of an orthographic projection of an isolation structure and a convex structure on a base plate according to another embodiment of the present application;

FIG. 37 shows a schematic diagram of an area distribution of a display panel according to an embodiment of the present application;

FIG. 38 shows a first schematic structural diagram of a portion of film layers of a display panel according to an embodiment of the present application;

FIG. 39 shows a schematic diagram of an isolation structure layer before and after lateral etching according to an embodiment of the present application;

FIG. 40 shows a second schematic structural diagram of a portion of film layers of a display panel according to an embodiment of the present application;

FIG. 41 shows a third schematic structural diagram of a portion of film layers of a display panel according to an embodiment of the present application;

FIG. 42 shows a fourth schematic structural diagram of a portion of film layers of a display panel according to an embodiment of the present application;

FIG. 43 shows a fifth schematic structural diagram of a portion of film layers of a display panel according to an embodiment of the present application;

FIG. 44 shows a sixth schematic structural diagram of a portion of film layers of a display panel according to an embodiment of the present application;

FIG. 45 shows a partially enlarged diagram of a second sub-area according to an embodiment of the present application;

FIG. 46 shows a partial sectional view of a display panel motherboard according to an embodiment of the present application;

FIG. 47 shows a top view of a display panel motherboard according to an embodiment of the present application;

FIG. 48 shows a partially enlarged diagram of a second sub-area of the display panel in FIG. 47;

FIG. 49 shows a sectional view of the display panel motherboard along a section line A-A in FIG. 47;

FIG. 50 shows a sectional view of a preparation process of a display panel motherboard according to an embodiment of the present application;

FIG. 51 shows an enlarged diagram of yet another second sub-area according to an embodiment of the present application;

FIG. 52 shows an enlarged diagram of yet another second sub-area according to an embodiment of the present application;

FIG. 53 shows a partially enlarged diagram of yet another sub-area according to an embodiment of the present application;

FIG. 54 shows an enlarged diagram of yet another second sub-area according to an embodiment of the present application;

FIG. 55 shows a sectional view of yet another display panel motherboard according to an embodiment of the present application;

FIG. 56 shows a sectional view of yet another display panel motherboard according to an embodiment of the present application;

FIG. 57 shows a sectional view of yet another display panel motherboard according to an embodiment of the present application;

FIG. 58 shows a flow chart of a method for manufacturing a display panel according to an embodiment of the present application;

FIGS. 59 to 65 show schematic diagrams of a preparation process of a method for manufacturing a display panel according to an embodiment of the present application;

FIG. 66 shows a schematic diagram of a preparation process of a method for manufacturing a display panel according to another embodiment of the present application;

FIGS. 67 to 69 show schematic diagrams of a preparation process of a method for manufacturing a display panel according to yet another embodiment of the present application;

FIGS. 70 and 71 show schematic diagrams of a preparation process of a method for manufacturing a display panel according to yet another embodiment of the present application;

FIG. 72 shows a flow chart of a method for manufacturing a display panel according to another embodiment of the present application;

FIGS. 73 to 77 show schematic diagrams of a preparation process of a method for manufacturing a display panel according to yet another embodiment of the present application;

FIGS. 78 to 82 show schematic diagrams of a preparation process of a method for manufacturing a display panel according to yet another embodiment of the present application;

FIG. 83 shows a flow chart of a method for manufacturing a display panel according to yet another embodiment of the present application;

FIG. 84 shows a flow chart of a method for manufacturing a display panel according to yet another embodiment of the present application;

FIGS. 85 to 89 show schematic diagrams of a preparation process of a method for manufacturing a display panel according to yet another embodiment of the present application;

FIG. 90 shows a flow chart of a method for manufacturing a display panel according to yet another embodiment of the present application;

FIG. 91 shows a flow chart of a method for manufacturing a display panel according to an embodiment of the present application;

FIG. 92 shows a process flow chart corresponding to FIG. 91;

FIG. 93 shows a flow chart of step S13 in FIG. 91;

FIG. 94 shows a process flow chart corresponding to FIG. 93;

FIG. 95 shows a flow chart of step S14 of FIG. 91;

FIG. 96 shows a process flow chart corresponding to FIG. 95;

FIG. 97 shows a process flow chart of a portion of a method for manufacturing a display panel according to an embodiment of the present application;

FIG. 98 shows a process flow chart of another portion of a method for manufacturing a display panel according to an embodiment of the present application.

### REFERENCE NUMERALS

10—display panel; 10a—first protective material layer; 10aa—first hollow area; 10b—second protective material layer; 10ba—first thickness area; 10bb—second thickness area; 10bc—second hollow area; 10c—third protective material layer; 10e—isolation material layer; 11—pixel defining material layer; 12—first isolation material layer; 13—second isolation material layer; 14—isolation preliminary structure; 14a—isolation preliminary opening; 15—edge preliminary structure; 15a—functional preliminary opening; 16—auxiliary preliminary structure; 17—first type of preliminary opening; 18—metal layer;
100—base plate; 110—substrate; 120—first insulating layer; 130—second insulating layer; 140—third insulating layer; 150—transistor; 151—gate; 152—source/drain; 160—storage capacitor; 161—first electrode plate; 162—second electrode plate; 170—driving circuit layer;
200—pixel defining layer; 210—pixel defining portion; 220—pixel opening;
300—isolation structure layer; 300a—first type of opening; 300aa—first opening; 300ab—second opening; 300ac—third opening; 300b—functional opening; 300ba—first recess; 301—first isolation layer; 301a—first surface; 301b—second surface; 302—second isolation layer; 302a—third surface; 302b—hollow structure; 303—third isolation layer; 310—isolation structure; 310a—isolation opening; 311—first isolation portion; 312—second isolation portion; 320—edge structure; 320a—first edge portion; 320b—second edge portion 321—main structure; 321a—first main portion; 321b—second main portion; 322—convex structure; 322a—first convex portion; 322b—second convex portion; 330—auxiliary structure; 331—first auxiliary structure; 331a—first auxiliary portion; 331b—second auxiliary portion; 332—second auxiliary structure; 332a—third auxiliary portion; 332b—fourth auxiliary portion; 332c—drainage groove; 332d—drainage auxiliary groove; 332e—positioning marking opening; 332f—concave-convex structure;
400—light-emitting device; 401—first type of light-emitting device; 402—second type of light-emitting device; 403—third type of light-emitting device; 410—first electrode layer; 411—first electrode; 420—light-emitting layer; 421—light-emitting unit; 430—second electrode layer; 431—second electrode;
500—first encapsulation layer; 510—encapsulation unit;
600—second encapsulation layer;
700—third encapsulation layer;
20—display panel motherboard;
30—half-tone mask plate; 31—first mask opening; 32—second mask opening;
TA—first specific area;
AA—display area;
NA—non-display area; NA1—first area; NA2—second area; NA21—first sub-area; NA22—second sub-area;
A1—first isolation area; A2—second isolation area;
B1—first edge;
B2—second edge;
B3—third edge; B31—first sub-edge; B32—second sub-edge;
B4—fourth edge;
B5—fifth edge;
S1—first spacing; S2—second spacing;
H—functional hole;
L—cutting line;
X—first direction;
Y—second direction;
Z—thickness direction.

### DETAILED DESCRIPTION

Features and exemplary embodiments of various aspects of the present application will be described in detail below. In the following detailed description, a number of specific details are presented to provide a full understanding of the present application. However, it will be apparent to those skilled in the art that the present application can be implemented without some of these specific details. The following description of embodiments is provided merely to provide a better understanding of the present application by illustrating examples of the present application. In the accompanying drawings and the following description, at least some of the well-known structures and techniques are not illustrated to avoid unnecessarily obscuring the present application; and the dimension of some of the structures may be exaggerated for clarity. Furthermore, the features, structures, or characteristics described below may be combined in one or more embodiments in any suitable manner.

The embodiments of the present application provide a display panel and method for manufacturing the same, a display panel motherboard, and a display apparatus, and various embodiments of which will be described below in connection with the accompanying drawings.

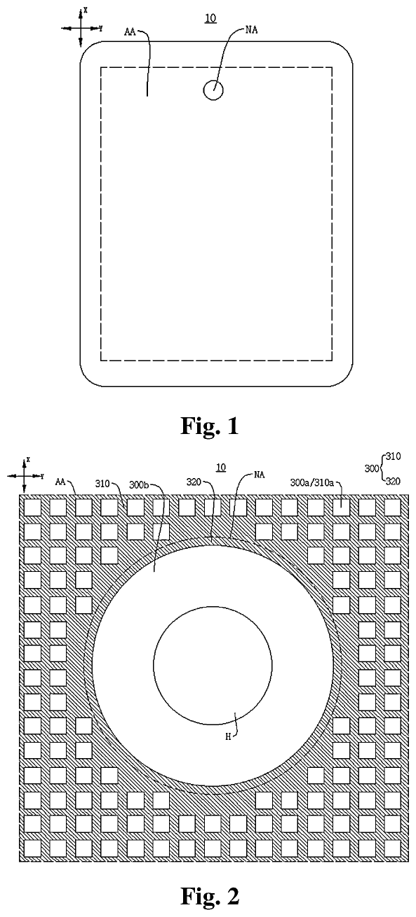

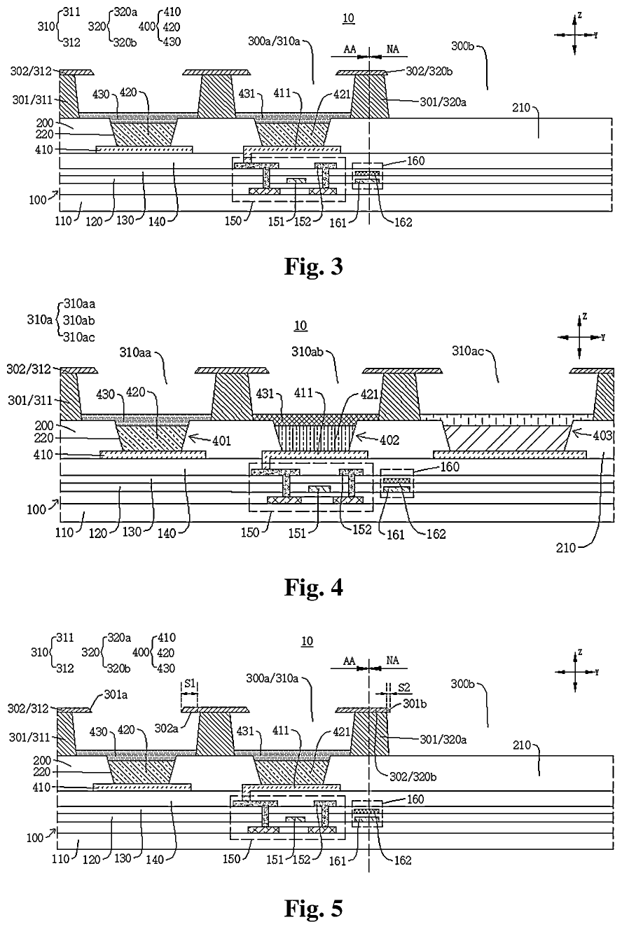

FIG. 1 shows a schematic structural diagram of a display panel 10 according to an embodiment of the present application, FIG. 2 shows a partial schematic diagram of the display panel 10 according to an embodiment of the present application, and FIG. 3 shows a partial sectional view of the display panel 10 according to an embodiment of the present application. In the drawings, the X direction is a first direction, the Y direction is a second direction, and the Z direction may be a thickness direction of the display panel 10. The first direction X, the second direction Y, and the thickness direction Z of the display panel 10 intersect with each other, and for example, the first direction X, the second direction Y, and the thickness direction Z of the display panel 10 may be perpendicular to each other. Alternatively, the first direction X may be a length direction of the display panel 10, and the second direction Y may be a width direction of the display panel 10.

As shown in FIGS. 1 to 3, the embodiments of the first aspect of the present application provide a display panel 10 having a display area AA and a non-display area NA, and the display panel 10 includes: a base plate 100; a pixel defining layer 200 arranged at one side of the base plate 100, the pixel defining layer 200 including a pixel defining portion 210 and a plurality of pixel openings 220 enclosed and formed by the pixel defining portion 210; an isolation structure layer 300 arranged at a side of the pixel defining layer 200 away from the base plate 100, the isolation structure layer 300 including a first isolation layer 301 and a second isolation layer 302 located at a side of the first isolation layer 301 away from the base plate 100, the isolation structure layer 300 enclosing and forming a plurality of first type of openings 300a located in the display area AA and a functional opening 300b located in the non-display area NA, the first type of opening 300a being in communication with a corresponding one of the pixel openings 220; a plurality of light-emitting devices 400, at least a portion of a structure of the light-emitting device 400 being arranged within a corresponding one of the first type of openings 300a; and a protrusion length of at least a portion of the second isolation layer 302 enclosing and forming the functional opening 300b relative to the first isolation layer 301 and towards the functional opening 300b being less than a protrusion length of the second isolation layer 302 enclosing and forming at least a portion of the first type of openings 300a relative to the first isolation layer 301 and towards the first type of opening 300a.

The display panel 10 according to the embodiments of the present application has a display area AA and a non-display area NA, and the display panel 10 includes a base plate 100, a pixel defining layer 200, an isolation structure layer 300, and a plurality of light-emitting devices 400.

The pixel defining layer 200 includes a pixel defining portion 210 and a plurality of pixel openings 220 enclosed and formed by the pixel defining portion 210, and the isolation structure layer 300 is arranged at a side of the pixel defining layer 200 away from the base plate 100 and encloses and forms a plurality of first type of openings 300A located in the display area AA and a functional opening 300b located in the non-display area NA. The functional opening 300b may facilitate increasing the light transmittance of the non-display area NA, so that when the display panel 10 is applied to a display apparatus, the photosensitive assembly for sensing light in the display apparatus may be correspondingly arranged under the functional opening (the functional hole herein may be a light-transmitting opening), and thus the photosensitive assembly can better sense light through the functional opening.

Optionally, the photosensitive assembly may include at least one of: a distance sensor, a camera, an under-screen fingerprint recognition module, an infrared light emitting diode (IR-LED), a proximity sensor, or other components capable of sensing light.

The first type of opening 300a is in communication with the corresponding pixel opening 220, and both the isolation structure layer 300 and the pixel defining layer 200 may be used to divide the sub-pixels of the display panel 10. At least a portion of the structure of the light-emitting device 400 is arranged within the corresponding first type of opening 300a, so that the light-emitting device 400 within the first type of opening 300a can be used to achieve light emitting and display of the display area AA in the display panel 10.

Optionally, the first type of opening 300a being in communication with the corresponding pixel opening 220 may mean that adjacent first type of openings 300a may be in communication with the pixel opening 220, for example, the first type of openings 300a of which the orthographic projections on the base plate 100 at least partially overlapping may be in communication with the pixel opening 220. Specifically, a single first type of opening 300a may be in communication with a single pixel opening 220.

The isolation structure layer 300 includes a first isolation layer 301 and a second isolation layer 302 located at a side of the first isolation layer 301 away from the base plate 100, and a protrusion length of at least a portion of the second isolation layer 302 enclosing and forming the functional opening 300b relative to the first isolation layer 301 and towards the functional opening 300b is less than a protrusion length of the second isolation layer 302 enclosing and forming at least a portion of the first type of openings 300a relative to the first isolation layer 301 and towards the first type of opening 300a.

By arranging a greater protrusion length of the second isolation layer 302 enclosing and forming at least a portion of the first type of openings 300a relative to the first isolation layer 301 and towards the first type of opening 300a, when preparing the light-emitting device 400 of the display panel 10, at least a portion of the material of the light-emitting device 400 may be directly vapor deposited as a whole, and the second isolation layer 302 enclosing and forming the first type of opening 300a can block at least a portion of the material for preparing the light-emitting device 400 to separate the material of the light-emitting device 400 between adjacent sub-pixels, so as to facilitate forming a plurality of light-emitting devices 400 that are spaced apart and located within the first type of openings 300a. Therefore, no fine mask is needed when preparing the light-emitting device 400 of the display panel 10, for example, no fine metal mask (FMM) is needed when vapor depositing the material of the light-emitting device 400, thereby better reducing the production and preparation costs of the display panel 10.

By arranging a less protrusion length of at least a portion of the second isolation layer 302 enclosing and forming the functional opening 300b relative to the first isolation layer 301 and towards the functional opening 300b, when new material is formed on the isolation structure layer 300 during the manufacturing of the display panel 10, for example, when organic material is formed on the isolation structure layer 300, the second isolation layer 302 located at the periphery of the functional opening 300b within the non-display area NA is less likely to block the organic material, and the new material may better fall in the vicinity of the first isolation layer 301 at the periphery of the functional opening 300b. Moreover, when new material is formed on the isolation structure layer 300, the second isolation layer 302 with a less protrusion length is less likely to excessively block gas discharging, so that gas is less likely to be retained under the second isolation layer 302 at the periphery of the functional opening 300b, thereby better increasing the structure stability and processing reliability of the display panel 10.

In some embodiments of the present application, the base plate 100 may include a substrate 110 and a transistor 150 arranged at a side of the substrate 110 towards a first electrode layer 410, and the transistor 150 includes a gate 151 and a source/drain 152. Optionally, the base plate 100 may further include a storage capacitor 160 which, for example, may include a first electrode plate 161 and a second electrode plate 162 located at side of the first electrode plate 161 away from the substrate 110.

As an example, the base plate 100 may further include a first insulating layer 120, a second insulating layer 130, and a third insulating layer 140 that are located at a side of the substrate 110 towards the transistor 150 and stacked in sequence on the substrate 110, and the gate 151 and the first electrode plate 161 may be arranged in the same layer, for example, the gate 151 and the first electrode plate 161 may be located at a side of the first insulating layer 120 towards the substrate 110. The second electrode plate 162 may be located between the first insulating layer 120 and the second insulating layer 130, and the source/drain 152 may be located between the second insulating layer 130 and the third insulating layer 140.

Optionally, in a direction away from the base plate 100, the light-emitting device 400 may include a first electrode layer 410, a light-emitting layer 420, and a second electrode layer 430 that are stacked in sequence. The light-emitting layer 420 may include a light-emitting unit 421 at least partially located within the pixel opening 220 and the isolation opening 310a, the first electrode layer 410 may include a first electrode 411 located at a side of the light-emitting layer 420 towards the base plate 100, and the second electrode layer 430 may include a second electrode 431 located at a side of the light-emitting layer 420 away from the base plate 100.

Optionally, the light-emitting unit 421 may include a hole inject layer (HIL), a hole transport layer (HTL), a light-emitting structure, an electron inject layer (EIL), and an electron transport layer (ETL).

In these optional embodiments, the first electrode layer 410 and the second electrode layer 430 may be used as the pixel electrode layers of the display panel 10, and one of the first electrode 411 and the second electrode 431 may be used as an anode and the other one as a cathode to drive the light-emitting unit 421 to emit light. In the embodiments of the present application, for example, the first electrode 411 is the anode of the display panel 10, and the second electrode 431 is the cathode of the display panel 10.

In some embodiments of the present application, when organic material is formed on the isolation structure layer 300 during the manufacturing of the display panel 10, the second isolation layer 302 with a less protrusion length in the present application is less likely to excessively block gas discharging when the organic material is vapor deposited at the periphery of the functional opening 300b.

For example, reference may be made to the following embodiments in the method for manufacturing the display panel 10, the second isolation layer 302 with a less protrusion length in the present application is less likely to excessively block gas discharging when the photoresist is vapor deposited at the periphery of the functional opening 300b during the preparation of the pixel defining layer 200.

Specifically, during the manufacturing of the display panel 10, the material of the pixel defining layer 200 may be prepared as a whole on the formed first electrode 411, and then the isolation structure layer 300 may be prepared on the material of the pixel defining layer 200, in which the whole material of the pixel defining layer 200 covering the first electrode 411 may better protect the first electrode 411, so that when the material of the isolation structure layer 300 is etched, the first electrode 411 is less likely to be damaged by the etching material which is blocked by the material of the pixel defining layer 200. After the isolation structure layer 300 is prepared, the material of the pixel defining layer 200 may be patterned using a photolithographic process to form the pixel defining layer 200. Therefore, when the photoresist is deposited on the material of the pixel defining layer 200 and the isolation structure layer 300 during the photolithographic process, the second isolation layer 302 with a less protrusion length is less likely to excessively block gas discharging at the periphery of the functional opening 300b, so that gas is less likely to be retained under the second isolation layer 302 at the periphery of the functional opening 300b, thereby better increasing the structure stability of the display panel 10.

In some embodiments of the present application, the area of the orthographic projection of the first type of opening 300a on the base plate 100 may be less than the area of the orthographic projection of the functional opening 300b on the base plate 100. Compared with the first type of opening 300a with a smaller size, if the structure of the isolation structure layer 300 at the periphery of the functional opening 300b is not specially arranged, gas is more likely to be retained at the periphery of the functional opening 300b with a larger size when organic material is formed on the isolation structure layer 300.

Therefore, by arranging a less protrusion length of at least a portion of the second isolation layer 302 enclosing and forming the functional opening 300b relative to the first isolation layer 301 and towards the functional opening 300b, when new material is formed on the isolation structure layer 300 during the manufacturing of the display panel 10, the second isolation layer 302 at the periphery of the functional opening 300b with a larger size is less likely to excessively block gas discharging at the periphery of the first isolation layer 301, so that gas is less likely to be retained at the periphery of the functional opening 300b with a larger size, thereby better increasing the processing reliability of the display panel 10.

Optionally, the protrusion length of the second isolation layer 302 enclosing and forming the first type of opening 300a relative to the first isolation layer 301 and towards the first type of opening 300a may be greater than 0, i.e., the second isolation layer 302 may protrude from the first isolation layer 301 towards the first type of opening 300a, so that in manufacturing the display panel 10, the second isolation layer 302 may better block and separate the material between adjacent light-emitting devices 400.

Optionally, a protrusion length of at least a portion of the second isolation layer 302 enclosing and forming the functional opening 300b relative to the first isolation layer 301 and towards the functional opening 300b being less than a protrusion length of the second isolation layer 302 enclosing and forming at least a portion of the first type of openings 300a relative to the first isolation layer 301 and towards the first type of opening 300a may mean that the protrusion length of at least a portion of the second isolation layer 302 enclosing and forming the functional opening 300b relative to the first isolation layer 301 and towards the functional opening 300b is less than a maximum protrusion length of the second isolation layer 302 enclosing and forming the first type of opening 300a relative to the first isolation layer 301 and towards the first type of opening 300a, so as to better determine the protrusion length of the second isolation layer 302 relative to the first isolation layer 301 and towards the functional opening 300b. For example, in the isolation structure layer 300, the protrusion length of the second isolation layer 302 relative to the first isolation layer 301 and towards the functional opening 300b may be set according to the maximum protrusion length of the second isolation layer 302 relative to the first isolation layer 301 and towards the first type of opening 300a. That is, in the experiments for manufacturing the display panel 10, a plurality of experiments may be performed according to the maximum protrusion length of the second isolation layer 302 relative to the first isolation layer 301 and towards the first type of opening 300a, and the protrusion length of the second isolation layer 302 relative to the first isolation layer 301 and towards the functional opening 300b may be gradually reduced in each experiment, until that gas is less likely to be retained at the periphery of the functional opening 300b in a certain experiment, and thus the protrusion length of the second isolation layer 302 relative to the first isolation layer 301 and towards the functional opening 300b may be better determined.

FIG. 4 shows a partial sectional view of the display panel 10 within the display area AA according to an embodiment of the present application.

As shown in FIG. 4, in some optional embodiments, at least a portion of the plurality of light-emitting devices 400 may have different colors. For example, a portion of the light-emitting devices 400 may be a first type of light-emitting device 401 for emitting red light, a portion of the light-emitting devices 400 may be a second type of light-emitting device 402 for emitting green light, and a portion of the light-emitting devices 400 may be a third type of light-emitting device 403 for emitting blue light.

Optionally, the first type of openings 300a may include a first opening 300aa for accommodating the first type of light-emitting device 401, a second opening 300ab for accommodating the second type of light-emitting device 402, and a third opening 300ac for accommodating the third type of light-emitting device 403.

Optionally, the protrusion length of the second isolation layer 302 relative to the first isolation layer 301 and towards the first opening 300aa, the protrusion length of the second isolation layer 302 relative to the first isolation layer 301 and towards the second opening 300ab side, and the protrusion length of the second isolation layer 302 relative to the first isolation layer 301 and towards the third opening 300ac may be different from each other.

In some optional embodiments, the first type of openings 300a includes a first type of sub-opening and a second type of sub-opening with an opening area less than the first type of sub-opening, and the protrusion length of at least a portion of the second isolation layer 302 enclosing and forming the functional opening 300b relative to the first isolation layer 301 and towards the functional opening 300b is less than a protrusion length of the second isolation layer 302 enclosing and forming the first type of sub-opening relative to the first isolation layer 301 and towards the first type of opening 300a.

Optionally, the first type of sub-opening may be any one of the first opening 300aa, the second opening 300ab, and the third opening 300ac, and the second type of sub-opening may be any one of the first opening 300aa, the second opening 300ab, and the third opening 300ac except the first type of sub-opening. For example, if the opening area of the third opening 300ac is greater than the opening area of the first opening 300aa and the second opening 300ab, the first type of sub-opening may be the third opening 300ac, and the second type of sub-opening may be the first opening 300aa or the second opening 300ab.

Optionally, the protrusion length of at least a portion of the second isolation layer 302 enclosing and forming the functional opening 300b relative to the first isolation layer 301 and towards the functional opening 300b is less than a protrusion length of the second isolation layer 302 enclosing and forming the largest first type of opening 300a relative to the first isolation layer 301 and towards the first type of opening 300a.

Optionally, the largest first type of opening 300a may refer to the first type of opening 300a with the largest opening area, or the first type of opening 300a of which the area of the orthographic projection on the base plate 100 is the largest. For example, the largest first type of opening 300a may be the third opening 300ac, i.e., the third opening 300ac may have the largest opening area among the first opening 300aa, the second opening 300ab, and the third opening 300ac.

In these optional embodiments, since gas is more likely to be retained at the periphery of the first type of opening 300a with a larger opening area on the base plate 100, by arranging that the protrusion length of at least a portion of the second isolation layer 302 enclosing and forming the functional opening 300b relative to the first isolation layer 301 and towards the functional opening 300b is less than the protrusion length of the second isolation layer 302 enclosing and forming the first type of sub-opening relative to the first isolation layer 301 and towards the first type of opening 300a, the protrusion length of the second isolation layer 302 relative to the first isolation layer 301 and towards the first type of opening 300a can be better determined.

For example, in the isolation structure layer 300, the protrusion length of the second isolation layer 302 relative to the first isolation layer 301 and towards the functional opening 300b may be set according to the protrusion length of the second isolation layer 302 relative to the first isolation layer 301 and towards the largest first type of opening 300a. That is, in the experiments for manufacturing the display panel 10, the protrusion length of the second isolation layer 302 relative to the first isolation layer 301 and towards the largest first type of opening 300a may be reasonably set so that gas is less likely to be retained at the periphery of the largest first type of opening 300a, then a plurality of experiments may be performed according to the protrusion length of the second isolation layer 302 relative to the first isolation layer 301 and towards the largest first type of opening 300a, and the protrusion length of the second isolation layer 302 relative to the first isolation layer 301 and towards the functional opening 300b may be gradually reduced in each experiment, until that gas is less likely to be retained at the periphery of the functional opening 300b in a certain experiment, and thus the protrusion length of the second isolation layer 302 relative to the first isolation layer 301 and towards the functional opening 300b may be better determined.

In some optional embodiments, the protrusion length of at least a portion of the second isolation layer 302 enclosing and forming the functional opening 300b relative to the first isolation layer 301 and towards the functional opening 300b may be less than a minimum protrusion length of the second isolation layer 302 enclosing and forming the first type of opening 300a relative to the first isolation layer 301 and towards the first type of opening 300a, so as to better reduce the protrusion length of at least a portion of the second isolation layer 302 enclosing and forming the functional opening 300b relative to the first isolation layer 301 and towards the functional opening 300b, thereby further reducing the influence of the second isolation layer 302 on gas discharging, so that gas is less likely to be retained under the second isolation layer 302 at the periphery of the functional opening 300b, and the structure stability and processing reliability of the display panel 10 can be better increased.

Optionally, the protrusion length of at least a portion of the second isolation layer 302 enclosing and forming the functional opening 300b relative to the first isolation layer 301 and towards the functional opening 300b may be less than 0.8 micron.

FIG. 5 shows a partial sectional view of the display panel 10 according to another embodiment of the present application, and FIG. 6 shows a partial sectional view of the display panel 10 according to yet another embodiment of the present application.

As shown in FIGS. 5 and 6, in some optional embodiments, a minimum spacing between an orthographic projection of an edge of the second isolation layer 302 corresponding to the first type of opening 300a on the base plate 100 and an orthographic projection of an edge of a surface of the first isolation layer 301 away from the base plate 100 corresponding to the first type of opening 300a on the base plate 100 is a first spacing S1, which may be greater than 0, so as to achieve that the second isolation layer 302 enclosing and forming the first type of opening 300a protrudes from the first isolation layer 301 towards the first type of opening 300a.

Optionally, the edge of the second isolation layer 302 corresponding to the first type of opening 300a may refer to the edge of the second isolation layer 302 enclosing and forming the first type of opening 300a. Optionally, the edge of the surface of the first isolation layer 301 away from the base plate 100 corresponding to the first type of opening 300a may refer to the edge of the surface of the first isolation layer 301 away from the base plate 100 enclosing and forming the first type of opening 300a.

Optionally, the protrusion length of the second isolation layer 302 relative to the first isolation layer 301 and towards the functional opening 300b may be greater than or equal to 0. A minimum spacing between an orthographic projection of an edge of the second isolation layer 302 corresponding to the functional opening 300b on the base plate 100 and an orthographic projection of an edge of the surface of the first isolation layer 301 away from the base plate 100 corresponding to the functional opening 300b on the base plate 100 is a second spacing S2, which may be less than the first spacing S1, so as to achieve that the protrusion length of the second isolation layer 302 enclosing and forming the functional opening 300b relative to the first isolation layer 301 and towards the functional opening 300b is less than the protrusion length of the second isolation layer 302 enclosing and forming the first type of opening 300a relative to the first isolation layer 301 and towards the first type of opening 300a, thereby better reducing the block of the second isolation layer 302 at the periphery of the functional opening 300b on gas discharging.

Optionally, the edge of the second isolation layer 302 corresponding to the functional opening 300b may refer to the edge of the second isolation layer 302 enclosing and forming the functional opening 300b. Optionally, the edge of the surface of the first isolation layer 301 away from the base plate 100 corresponding to the functional opening 300b may refer to the edge of the surface of the first isolation layer 301 away from the base plate 100 enclosing and forming the functional opening 300b.

In some optional embodiments, as shown in FIG. 5, if the protrusion length of the second isolation layer 302 relative to the first isolation layer 301 and towards the functional opening 300b is greater than 0, the second spacing S2 is greater than 0, and the orthographic projection of the edge of the second isolation layer 302 corresponding to the functional opening 300b on the base plate 100 is located at a side of the orthographic projection of the edge of the surface of the first isolation layer 301 away from the base plate 100 corresponding to the first type of opening 300a on the base plate 100 towards the functional opening 300b, and the second isolation layer 302 may be arranged protruding from the first isolation layer 301 towards the functional opening 300b.

Optionally, an angle between a surface of the second isolation layer 302 towards the base plate 100 and a surface of the first isolation layer 301 towards the first type of opening 300a may be less than an angle between at least a portion of the surface of the second isolation layer 302 towards the base plate 100 and a surface of the first isolation layer 301 towards the functional opening 300b, so that when organic material is formed on the isolation structure layer 300, the gas at the periphery of the functional opening 300b may be better discharged outwardly along the sidewall of the first isolation layer 301, thereby better increasing the structure stability and processing reliability of the display panel 10.

Optionally, the surface of the first isolation layer 301 towards the first type of opening 300a may be a first surface 301a, the surface of the first isolation layer 301 towards the functional opening 300b may be a second surface 301b, and the surface of the second isolation layer 302 towards the base plate 100 may be a third surface 302a. Herein, an end of the first surface 301a away from the base plate 100 may be connected with an end of a portion of the third surface 302a close to the first isolation layer 301, and an end of the second surface 301b away from the base plate 100 may be connected with an end of a portion of the third surface 302a close to the first isolation layer 301.

In some embodiments, the first surface 301a, the second surface 301b, and the third surface 302a may all be planar. Herein, the angle between the surface of the second isolation layer 302 towards the base plate 100 and the surface of the first isolation layer 301 towards the first type of opening 300a may refer to the angle between the third surface 302a and the first surface 301a; and the angle between the surface of the second isolation layer 302 towards the base plate 100 and the surface of the first isolation layer 301 towards the functional opening 300b may refer to the angle between the third surface 302a and the second surface 301b.

In some other embodiments, at least a portion of the first surface 301a may be curved, or at least a portion of the second surface 301b may be curved, or at least a portion of the third surface 302a may be curved. Herein, a tangent plane tangent to an edge of the first surface 301a towards the third surface 302a is a first tangent plane, a tangent plane tangent to an edge of the second surface 301b towards the third surface 302a is a second tangent plane, and a tangent plane tangent to an edge of the third surface 302a towards the first surface 301a or the second surface 301b is a third tangent plane. The angle between the surface of the second isolation layer 302 towards the base plate 100 and the surface of the first isolation layer 301 towards the first type of opening 300a may refer to the angle between the third tangent plane and the first tangent plane; and the angle between the surface of the second isolation layer 302 towards the base plate 100 and the surface of the first isolation layer 301 towards the functional opening 300b may refer to the angle between the third tangent plane and the second tangent plane.

In some optional embodiments, as shown in FIG. 6, if the protrusion length of the second isolation layer 302 relative to the first isolation layer 301 and towards the functional opening 300b is equal to 0, the second spacing S2 is equal to 0, and the second isolation layer 302 may not protrude from the first isolation layer 301 towards the functional opening 300b, so that when organic material is formed on the isolation structure layer 300, the gas at the periphery of the functional opening 300b may be better discharged outwardly along the sidewalls of the first isolation layer 301 and the second isolation layer 302, thereby better increasing the structure stability and processing reliability of the display panel 10.

Optionally, the second spacing S2 may be 70% of the first spacing S1, or the second spacing S2 may be 50% of the first spacing S1, or the second spacing S2 may be 30% of the first spacing S1.

As shown in FIG. 6, optionally, the protrusion length of the second isolation layer 302 relative to the first isolation layer 301 and towards the functional opening 300b being equal to 0 may mean that an orthographic projection of an edge of the second isolation layer 302 corresponding to the functional opening 300b on the base plate 100 at least partially overlaps an orthographic projection of an edge of a surface of the first isolation layer 301 away from the base plate 100 corresponding to the functional opening 300b on the base plate 100.

In some optional embodiments, the isolation structure layer 300 includes an isolation structure 310 at least partially located in the display area AA and an edge structure 320 located in the non-display area NA, the first type of openings 300a include an isolation opening 310a enclosed and formed by the isolation structure 310, the edge structure 320 encloses and forms the functional opening 300b, and the isolation structure 310 includes a first isolation portion 311 and a second isolation portion 312 located at a side of the first isolation portion 311 away from the base plate 100.

Optionally, the light-emitting device 400 may be at least partially located within the isolation opening 310a, and the isolation opening 310a may be in communication with the pixel opening 220. Optionally, the first isolation portion 311 may participate in forming the first isolation layer 301, and the second isolation portion 312 may participate in forming the second isolation layer 302.

Optionally, the isolation structure 310 may be configured to separate the material of the light-emitting layer 420 and the second electrode layer 430 when preparing the light-emitting layer 420 and the second electrode layer 430, so as to divide sub-pixels. Optionally, a protrusion length of the second isolation portion 312 relative to the first isolation portion 311 and towards the first type of opening 300a may be greater than 0, i.e., the second isolation portion 312 may be arranged protruding from the first isolation portion 311 towards the first type of opening 300a, so that when preparing the light-emitting device 400 of the display panel 10, at least a portion of the material of the light-emitting device 400 may be directly vapor deposited as a whole, and the second isolation portion 312 can block at least a portion of the material for preparing the light-emitting device 400 to separate the material of the light-emitting device 400 between adjacent sub-pixels, so as to facilitate forming a plurality of light-emitting devices 400 that are spaced apart and located within the isolation openings 310a, and thus no fine mask is needed when preparing the light-emitting device 400 of the display panel 10.

Optionally, the isolation structure 310 may be a mesh in shape, in which the hollow areas in the isolation structure 310, which is a mesh in shape, may form the isolation openings 310a.

Optionally, the isolation structure 310 may include an electrically conductive material. For example, the first isolation portion 311 may include an electrically conductive material, so that the second electrode 431 may be connected with the isolation structure 310 to enable the second electrodes 431 in adjacent isolation openings 310a to be connected with each other through the isolation structure 310 to form a planar electrode, so as to facilitate the control of the second electrodes 431 in the display panel 10.

In some embodiments, as shown in FIGS. 5 and 6, the edge structure 320 includes a first edge portion 320a and a second edge portion 320b located at a side of the first edge portion 320a away from the base plate 100, and a protrusion length of at least a portion of the second edge portion 320b relative to the first edge portion 320a and towards the functional opening 300b is less than a protrusion length of the second isolation portion 312 relative to the first isolation portion 311 and towards the isolation opening 310a.

Optionally, the first edge portion 320a may participate in forming the first isolation layer 301, and the second edge portion 320b may participate in forming the second isolation layer 302.

Optionally, the first edge portion 320a and the first isolation portion 311 may be arranged in the same layer and made of the same material, and the second edge portion 320b and the second isolation portion 312 may be arranged in the same layer and made of the same material, so that the edge structure 320 and the isolation structure 310 may be prepared by the same or similar preparation process and preparation equipment. Optionally, the edge structure 320 may be connected with the isolation structure 310, for example, the edge structure 320 and the isolation structure 310 may be integrally prepared.

Optionally, the protrusion length of the second edge portion 320b relative to the first edge portion 320a and towards the functional opening 300b may be greater than or equal to 0. For example, as shown in FIG. 5, if the protrusion length of the second edge portion 320b relative to the first edge portion 320a and towards the functional opening 300b is greater than 0, the second edge portion 320b may be arranged protruding from the first edge portion 320b towards the functional opening 300b. For example, as shown in FIG. 6, if the protrusion length of the second edge portion 320b relative to the first edge portion 320a and towards the functional opening 300b is equal to 0, the orthographic projection of the second edge portion 320b on the base plate 100 may be located within the orthographic projection of a surface of the first edge portion 320a away from the base plate 100 on the base plate 100.

Optionally, if the protrusion length of the second edge portion 320b relative to the first edge portion 320a and towards the functional opening 300b is equal to 0, an orthographic projection of an edge of the second edge portion 320b corresponding to the functional opening 300b on the base plate 100 at least partially overlaps an orthographic projection of an edge of a surface of the first edge portion 320a away from the base plate 100 corresponding to the functional opening 300b on the base plate 100, so that when organic material is formed on the isolation structure layer 300, the gas at the periphery of the functional opening 300b may be better discharged outwardly along the sidewalls of the first edge portion 320a and the second edge portion 320b, thereby better increasing the structure stability and processing reliability of the display panel 10.

In these optional embodiments, by arranging that the protrusion length of at least a portion of the second edge portion 320b relative to the first edge portion 320a and towards the functional opening 300b is less than the protrusion length of the second isolation portion 312 relative to the first isolation portion 311 and towards the isolation opening 310a, when new material is formed on the isolation structure layer 300 during the manufacturing of the display panel 10, the second edge portion 320b with a less protrusion length is less likely to excessively block gas discharging at the periphery of the functional opening 300b, so that gas is less likely to be retained under the second edge portion 320b at the periphery of the functional opening 300b, thereby better increasing the structure stability and processing reliability of the display panel 10.

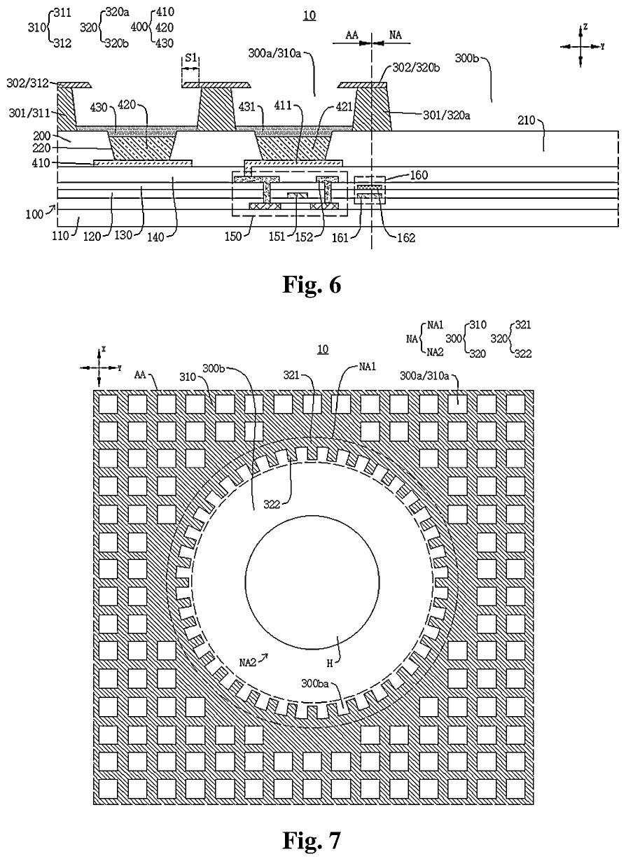

FIG. 7 shows a partial schematic diagram of the display panel 10 according to another embodiment of the present application.

As shown in FIG. 7, in some optional embodiments, the functional opening 300b includes a first recess 300ba arranged in an edge area and penetrating the edge structure 320 in the thickness direction Z of the display panel 10.

Optionally, the edge area may refer to an edge area of the functional opening 300b close to the edge structure 320. Optionally, the first recess 300ba may be formed by inwardly recessing a portion of the surface of the edge structure 320 towards the functional opening 300b.

In these optional embodiments, by arranging the first recess 300ba, when new material is formed on the isolation structure layer 300 during the manufacturing of the display panel 10, the first recess 300ba protruding towards the edge structure 320 can improve the gas discharging path during the formation of the new material, so that when the new material is deposited on the isolation structure layer 300 along a certain direction, under the extrusion force of the deposited material, the gas between the new material and the edge structure 320 and the gas between the new material and the base plate 100 may be discharged outwardly, under the guide of the edge structure 320 at the periphery of the first recess 300ba, from the edge of the edge structure 320 at the periphery of the first recess 300ba in a direction away from the display area AA, thereby better increasing the structure stability and processing reliability of the display panel 10.

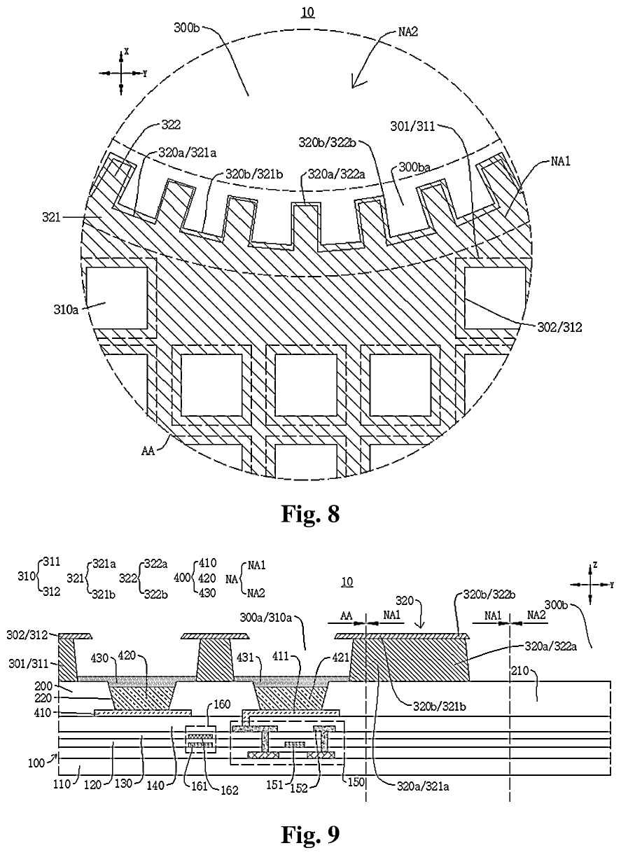

FIG. 8 shows a partially enlarged schematic diagram of the orthographic projection of the isolation structure layer 300 on the base plate 100 according to an embodiment of the present application.

As shown in FIG. 8, in some optional embodiments, if the edge structure 320 includes the first edge portion 320a and the second edge portion 320b, a protrusion length of at least a portion of the second edge portion 320b relative to the first edge portion 320a and towards the first recess 300ba is less than the protrusion length of the second isolation portion 312 relative to the first isolation portion 311 and towards the isolation opening 310a.

Optionally, as shown in FIG. 8, the protrusion length of the second edge portion 320b relative to the first edge portion 320a and towards the first recess 300ba may be greater than zero or equal to 0.

In these optional embodiments, by arranging that the protrusion length of at least a portion of the second edge portion 320b relative to the first edge portion 320a and towards the first recess 300ba is less than the protrusion length of the second isolation portion 312 relative to the first isolation portion 311 and towards the isolation opening 310a, when new material is formed on the isolation structure layer 300, gas may be discharged outwardly, under the guide of the edge structure 320 at the periphery of the first recess 300ba, from the edge of the edge structure 320 at the periphery of the first recess 300ba in the direction away from the display area AA, and also gas is less likely to be blocked by the second edge portion 320b with a less protrusion length and can be discharged outwardly in the thickness direction Z of the display panel 10, thereby better increasing the structure stability and processing reliability of the display panel 10.

In some optional embodiments, the non-display area NA includes a first area NA1 adjacent to the display area AA and a second area NA2 located at a side of the first area NA1 away from the display area AA, the edge structure 320 is located in the first area NA1 and includes a main structure 321 connected with the isolation structure 310 and a plurality of convex structures 322 protruding towards the second area NA2 relative to the main structure 321, and the first recess 300ba is located between adjacent convex structures 322.

Optionally, the main structure 321 may include a first main portion 321a and a second main portion 321b located at a side of the first main portion 321a away from the base plate 100, the first main portion 321a may participate in forming the first edge portion 320a, and the second main portion 321b may participate in forming of the second edge portion 320b.

Optionally, the first main portion 321a and the first isolation portion 311 may be arranged in the same layer and made of the same material, and the second main portion 321b and the second isolation portion 312 may be arranged in the same layer and made of the same material, so that the main structure 321 and the isolation structure 310 may be prepared by the same or similar preparation process and preparation equipment. Optionally, the first main portion 321a of the main structure 321 and the first isolation portion 311 may be integrally prepared, and the second main portion 321b of the main structure 321 and the second isolation portion 312 may be integrally prepared.

Optionally, the convex structure 322 may include a first convex portion 322a and a second convex portion 322b located at a side of the first convex portion 322a away from the base plate 100, the first convex portion 322a may participate in forming the first edge portion 320a, and the second convex portion 322b may participate in forming the second edge portion 320b.

Optionally, the first convex portion 322a and the first isolation portion 311 may be arranged in the same layer and made of the same material, and the second convex portion 322b and the second isolation portion 312 may be arranged in the same layer and made of the same material, so that the convex structure 322 and the isolation structure 310 may be prepared by the same or similar preparation process and preparation equipment. Optionally, the first convex portion 322a of the convex structure 322 and the first main portion 321a of the main structure 321 may be integrally prepared, and the second convex portion 322b of the convex structure 322 and the second main portion 321b of the main structure 321 may be integrally prepared.

In these optional embodiments, when new material is formed on the isolation structure layer 300 during the manufacturing of the display panel 10, the convex structure 322 protruding relative to the main structure 321 can improve the gas discharging path during the formation of the material, so that when the material is deposited on the isolation structure layer 300 along a certain direction, under the extrusion force of the deposited material, the gas between the new material and the edge structure 320 and the gas between the new material and the base plate 100 may be discharged outwardly, under the guide of the convex structure 322, from the edge of the convex structure 322 in a direction towards the second area NA2, thereby better increasing the structure stability and processing reliability of the display panel 10.

In some optional embodiments, in a direction from the display area AA to a center of the functional opening 300b, a size of the first recess 300ba in a direction perpendicular to a straight line from the display area to the center of the functional opening gradually increases (not shown), so that when new material is formed on the isolation structure layer 300, gas is discharged outwardly, under the guide of the edge structure 320 at the periphery of the first recess 300ba, from the edge of the edge structure 320 at the periphery of the first recess 300ba in the direction away from the display area AA. For example, the orthographic projection of the first recess 300ba on the base plate 100 may be similar to a trapezoid in shape.

Optionally, in the direction from the display area AA to the center of the functional opening 300b, the size of the first recess 300ba in the direction perpendicular to a straight line from the display area to the center of the functional opening gradually increasing may mean that in the direction away from the display area AA, the distance between the convex structures 322 at two sides of the first recess 300ba gradually increases.

In some optional embodiments, the size (which refers to the average size) of the convex structure in a direction perpendicular to a straight line from the center of the functional opening to the center of the convex structure is 0.5 times to 10 times the size of the isolation opening (which may refer to the maximum contour size of the pixel opening with a greater area from a plurality of different pixel openings); or the size (which refers to the average size) of the first recess in a direction from the center of the functional opening to the center of the recess is in the arrange of 60 nanometers to 100 microns; or the size of the first recess in a direction perpendicular to a straight line from the center of the functional opening to the center of the recess is 0.5 times to 10 times the size of the isolation opening. The center herein refers to the center of the corresponding pattern of the corresponding structure on a plane parallel to the base plate.

Optionally, the size of the convex structure in the direction perpendicular to a straight line from the center of the functional opening to the center of the convex structure is 0.8, 1.5, 3, 5, or 8 times the contour size of the isolation opening.

Optionally, the size of the first recess in the direction perpendicular to a straight line from the center of the functional opening to the center of the recess is 0.8, 1.5, 3, 5, or 8 times the contour size of the isolation opening.

Optionally, the size of the first recess in the direction from the center of the functional opening to the center of the recess is 100 nanometers, 300 nanometers, 600 nanometers, 1 micron, 5 microns, 10 microns, 20 microns, 30 microns, 40 microns, 60 microns, or 100 microns.

In these optional embodiments, by reasonably setting the sizes of the convex structure 322 and the first recess 300ba according to the isolation opening 310a, when new material is formed on the isolation structure layer 300 during the manufacturing of the display panel 10, gas may be less likely to be retained at the periphery of the convex structure 322 and the first recess 300ba and may be better discharged outwardly along the edge of the convex structure 322 at the periphery of the first recess 300ba.

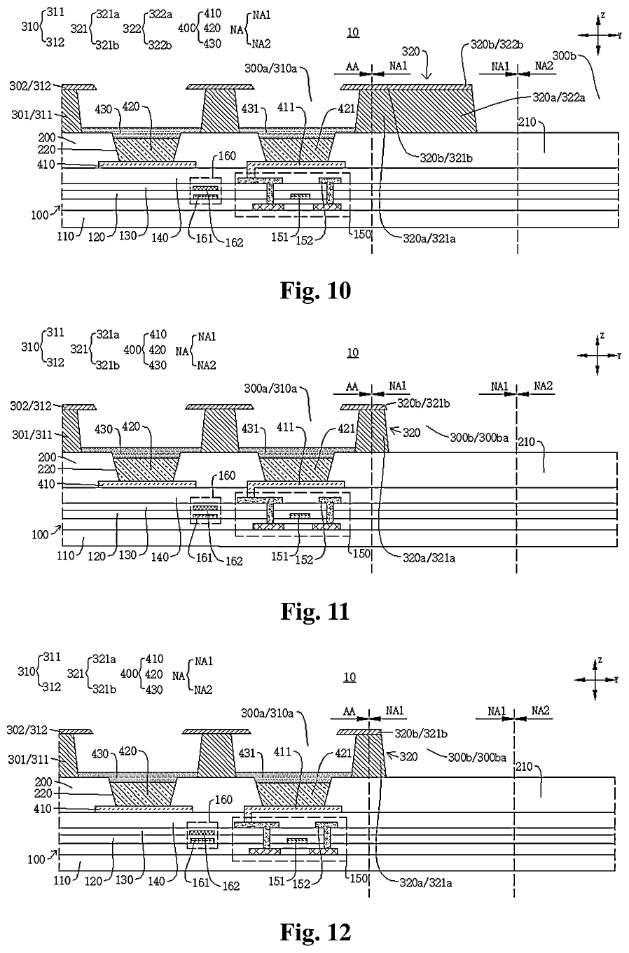

FIG. 9 shows a partial sectional view of the display panel 10 according to yet another embodiment of the present application, and FIG. 10 shows a partial sectional view of the display panel 10 according to yet another embodiment of the present application.

As shown in FIGS. 9 and 10, in some optional embodiments, a protrusion length of at least a portion of the second convex portion 322b relative to the first convex portion 322a and towards the functional opening 300b is less than a protrusion length of the second isolation portion 312 relative to the first isolation portion 311 of the isolation structure 310 and towards the isolation opening 310a.

Optionally, as shown in FIGS. 9 and 10, the protrusion length of the second convex portion 322b relative to the first convex portion 322a and towards the functional opening 300b may be greater than or equal to 0.

Optionally, an orthographic projection of the second convex portion 322b on the base plate 100 is located within an orthographic projection of the first convex portion 322a on the base plate 100, so as to better shorten the protrusion length of the second convex portion 322b relative to the first convex portion 322a.

Further optionally, as shown in FIG. 10, the orthographic projection of the second convex portion 322b on the base plate 100 is located within an orthographic projection of a surface of the first convex portion 322a away from the base plate 100 on the base plate 100, so that the protrusion length of the second convex portion 322b relative to the first convex portion 322a and towards the functional opening 300b may be equal to 0.

Optionally, if the protrusion length of the second convex portion 322b relative to the first convex portion 322a and towards the functional opening 300b is equal to 0, an orthographic projection of an edge of the second convex portion 322b corresponding to the functional opening 300b on the base plate 100 at least partially overlaps an orthographic projection of an edge of a surface of the first convex portion 322a away from the base plate 100 corresponding to the functional opening 300b on the base plate 100, so that when organic material is formed on the isolation structure layer 300, the gas at the periphery of the functional opening 300b may be better discharged outwardly along the sidewalls of the first convex portion 322a and the second convex portion 322b, thereby better increasing the structure stability and processing reliability of the display panel 10.

In these optional embodiments, by arranging that the protrusion length of at least a portion of the second convex portion 322b relative to the first convex portion 322a and towards the functional opening 300b is less than the protrusion length of the second isolation portion 312 relative to the first isolation portion 311 of the isolation structure 310 and towards the isolation opening 310a, when new material is formed on the isolation structure layer 300, gas can be less likely to be blocked by the second convex portion 322b with a less protrusion length and can be discharged outwardly in the thickness direction Z of the display panel 10, thereby better increasing the structure stability and processing reliability of the display panel 10.

FIG. 11 shows a partial sectional view of the display panel 10 according to yet another embodiment of the present application, and FIG. 12 shows a partial sectional view of the display panel 10 according to yet another embodiment of the present application.

As shown in FIGS. 11 and 12, in some optional embodiments, a protrusion length of at least a portion of the second main portion 321b relative to the first main portion 321a and towards the first recess 300ba is less than the protrusion length of the second isolation portion 312 relative to the first isolation portion 311 of the isolation structure 310 and towards the isolation opening 310a.

Optionally, the protrusion length of the second main portion 321b relative to the first main portion 321a and towards the first recess 300ba may be greater than or equal to 0.

Optionally, an orthographic projection of the second main portion 321b on the base plate 100 is located within an orthographic projection of the first main portion 321a on the base plate 100, so as to better shorten the protrusion length of the second main portion 321b relative to the first main portion 321a.

Further optionally, as shown in FIG. 12, the orthographic projection of the second main portion 321b on the base plate 100 is located within an orthographic projection of a surface of the first main portion 321a away from the base plate 100 on the base plate 100, so that the protrusion length of the second main portion 321b relative to the first main portion 321a and towards the first recess 300ba may be equal to 0.

Optionally, if the protrusion length of the second main portion 321b relative to the first main portion 321a and towards the first recess 300ba is equal to 0, an orthographic projection of an edge of the second main portion 321b corresponding to the first recess 300ba on the base plate 100 at least partially overlaps an orthographic projection of an edge of a surface of the first main portion 321a away from the base plate 100 corresponding to the first recess 300ba on the base plate 100, so that when organic material is formed on the isolation structure layer 300, the gas at the periphery of the functional opening 300b may be better discharged outwardly along the sidewalls of the first main portion 321a and the second main portion 321b, thereby better increasing the structure stability and processing reliability of the display panel 10.

In these optional embodiments, by arranging that the protrusion length of at least a portion of the second main portion 321b relative to the first main portion 321a and towards the first recess 300ba is less than the protrusion length of the second isolation portion 312 relative to the first isolation portion 311 of the isolation structure 310 and towards the isolation opening 310a, when new material is formed on the isolation structure layer 300, gas can be less likely to be blocked by the second main portion 321b with a less protrusion length and can be discharged outwardly in the thickness direction Z of the display panel 10, thereby better increasing the structure stability and processing reliability of the display panel 10.

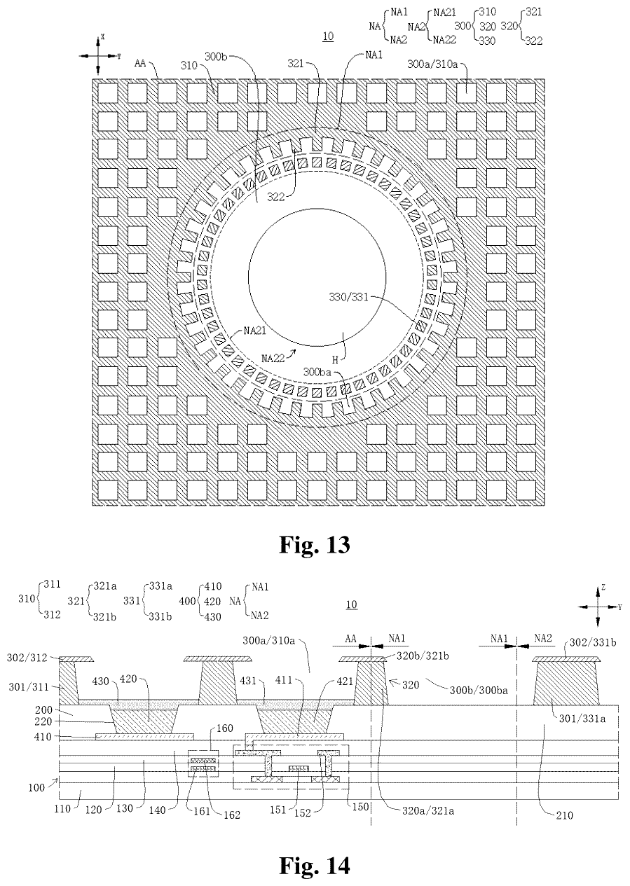

FIG. 13 shows a partial schematic diagram of the display panel 10 according to yet another embodiment of the present application.

As shown in FIG. 13, in some optional embodiments, the isolation structure layer 300 further includes an auxiliary structure 330 located within the functional opening 300b and spaced apart from the edge structure 320.

Optionally, the auxiliary structure 330 may be arranged in the second area NA2.

Optionally, the second area NA2 includes a first sub-area NA21 and a second sub-area NA22 located at a side of the first sub-area NA21 away from the first area NA1, the auxiliary structure 330 includes a plurality of first auxiliary structures 331 located in the first sub-area NA21, and the plurality of first auxiliary structures 331 are spaced apart and distributed around a periphery of the second sub-area NA22.

Optionally, the spacing between the first auxiliary structure 331 and the edge structure 320 may be less than or equal to 10 microns. For example, the spacing between the first auxiliary structure 331 and the edge structure 320 may be less than or equal to 1 micron, 2 microns, 3 microns, 5 microns, or 7 microns.

In these optional embodiments, by arranging the auxiliary structure 330, which is spaced apart from the edge structure 320, within the functional opening 300b, when the isolation structure layer 300 is etched and prepared, the etching material located within the functional opening 300b in the second area NA2 can also etch the material of the auxiliary structure 330, so that the auxiliary structure 330 may restrict the delivery of the etching material within the functional opening 300b towards the edge structure 320 to better reduce the etching amount of the etching material on the material of the edge structure 320, and thus the edge structure 320 is less likely to be damaged by over etching, thereby better increasing the structure stability of the display panel 10. Moreover, the auxiliary structure 330 not only reduces the etching amount of the etching material on the material of the edge structure 320, but also can facilitate achieving the topography of the edge structure 320 in the above embodiments. That is, the arrangement of the auxiliary structure 330 can reduce the etching amount of the etching material on the material of the edge structure 320, so as to facilitate forming the topography in which the protrusion length of at least a portion of the second convex portion 322b relative to the first convex portion 322a and towards the functional opening 300b is less than the protrusion length of the second isolation portion 312 relative to the first isolation portion 311 of the isolation structure 310 and towards the isolation opening 310a, as well as the topography in which the protrusion length of at least a portion of the second main portion 321b relative to the first main portion 321a and towards the first recess 300ba is less than the protrusion length of the second isolation portion 312 relative to the first isolation portion 311 of the isolation structure 310 and towards the isolation opening 310a.

In addition, by arranging that the adjacent auxiliary structures 330 are spaced apart, when new material is formed on the isolation structure layer 300 during the manufacturing of the display panel 10, for example, when the material is deposited on the isolation structure layer 300 along a certain direction, the gas between the new material and the auxiliary structure 330 and the gas between the new material and the base plate 100 may be discharged outwardly, under the guide of the spacing between the adjacent auxiliary structures 330, from the edge of the auxiliary structure 330, thereby better increasing the structure stability and processing reliability of the display panel 10.

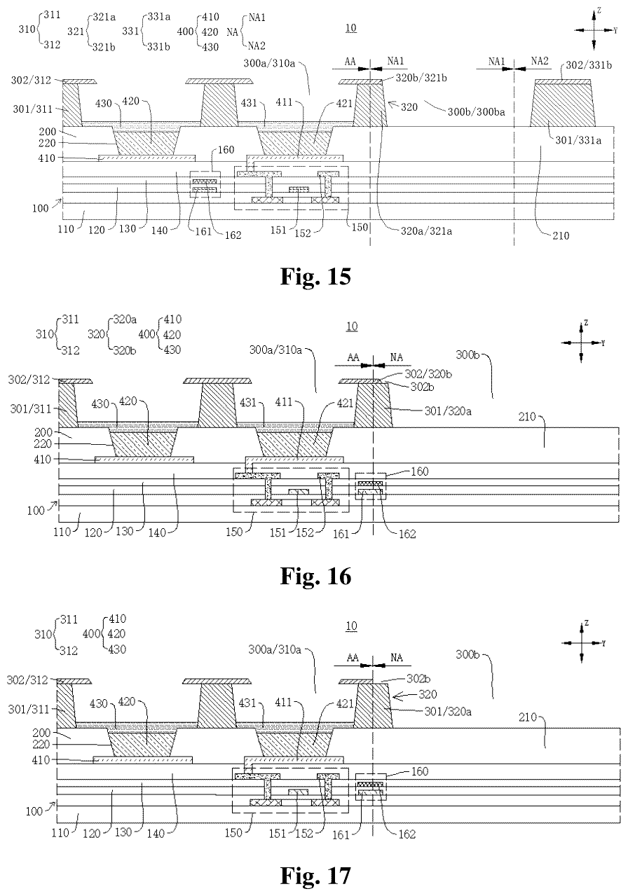

FIG. 14 shows a partial sectional view of the display panel 10 according to yet another embodiment of the present application, and FIG. 15 shows a partial sectional view of the display panel 10 according to yet another embodiment of the present application.

As shown in FIGS. 14 and 15, in some optional embodiments, the first auxiliary structure 331 includes a first auxiliary portion 331a and a second auxiliary portion 331b located at a side of the first auxiliary portion 331a away from the base plate 100, and a protrusion length of at least a portion of the second auxiliary portion 331b relative to the first auxiliary portion 331a and towards the functional opening 300b is less than the protrusion length of the second isolation portion 312 relative to the first isolation portion 311 and towards the isolation opening 310a.

Optionally, the first auxiliary portion 331a may participate in forming the first isolation layer 301, and the second auxiliary portion 331b may participate in forming the second isolation layer 302.

Optionally, the first auxiliary portion 331a and the first isolation portion 311 may be arranged in the same layer and made of the same material, and the second auxiliary portion 331b and the second isolation portion 312 may be arranged in the same layer and made of the same material, so that the first auxiliary structure 331 and the isolation structure 310 may be prepared by the same or similar preparation process and preparation equipment. Optionally, the first auxiliary portion 331a of the first auxiliary structure 331 and the first isolation portion 311 may be integrally prepared, and the second auxiliary portion 331b of the first auxiliary structure 331 and the second isolation portion 312 may be integrally prepared.

Optionally, the protrusion length of the second auxiliary portion 331b relative to the first auxiliary portion 331a and towards the functional opening 300b may be greater than or equal to 0.

Optionally, an orthographic projection of the second auxiliary portion 331b on the base plate 100 is located within an orthographic projection of the first auxiliary portion 331a on the base plate 100, so as to better shorten the protrusion length of the second auxiliary portion 331b relative to the first auxiliary portion 331a.

Further optionally, as shown in FIG. 15, the orthographic projection of the second auxiliary portion 331b on the base plate 100 is located within an orthographic projection of a surface of the first auxiliary portion 331a away from the base plate 100 on the base plate 100, so that the protrusion length of the second auxiliary portion 331b relative to the first auxiliary portion 331a and towards the functional opening 300b may be equal to 0.

Optionally, if the protrusion length of the second auxiliary portion 331b relative to the first auxiliary portion 331a and towards the functional opening 300b is equal to 0, an orthographic projection of an edge of the second auxiliary portion 331b corresponding to the functional opening 300b on the base plate 100 at least partially overlaps an orthographic projection of an edge of a surface of the first auxiliary portion 331a away from the base plate 100 corresponding to the functional opening 300b on the base plate 100, so that when organic material is formed on the isolation structure layer 300, the gas at the periphery of the functional opening 300b may be better discharged outwardly along the sidewalls of the first auxiliary portion 331a and the second auxiliary portion 331b, thereby better increasing the structure stability and processing reliability of the display panel 10.

In these optional embodiments, by arranging that the protrusion length of at least a portion of the second auxiliary portion 331b relative to the first auxiliary portion 331a and towards the functional opening 300b is less than the protrusion length of the second isolation portion 312 relative to the first isolation portion 311 of the isolation structure 310 and towards the isolation opening 310a, when new material is formed on the isolation structure layer 300, gas can be less likely to be blocked by the second auxiliary portion 331b with a less protrusion length and can be discharged outwardly in the thickness direction Z of the display panel 10, thereby better increasing the structure stability and processing reliability of the display panel 10.

In some optional embodiments, the display panel 10 is provided with a functional hole H in the second sub-area NA22, so that if a photosensitive assembly is correspondingly arranged at the functional opening 300b, the photosensitive assembly may better sense light through the functional hole H.

Optionally, the edge structure 320 and the first auxiliary structure 331 may be arranged around at least a portion of the functional hole H.

FIG. 16 shows a partial sectional view of the display panel 10 according to yet another embodiment of the present application.

Referring to FIG. 16 and in conjunction with FIGS. 1 to 15, the embodiments of the first aspect of the present application further provide a display panel 10 having a display area AA and a non-display area NA, the display panel 10 includes: a base plate 100; a pixel defining layer 200 arranged at one side of the base plate 100, the pixel defining layer 200 including a pixel defining portion 210 and a plurality of pixel openings 220 enclosed and formed by the pixel defining portion 210; an isolation structure layer 300 arranged at a side of the pixel defining layer 200 away from the base plate 100, the isolation structure layer 300 including a first isolation layer 301 and a second isolation layer 302 located at a side of the first isolation layer 301 away from the base plate 100, the isolation structure layer 300 enclosing and forming a plurality of first type of openings 300a located in the display area AA and a functional opening 300b located in the non-display area NA, the first type of opening 300a being in communication with a corresponding one of the pixel openings 220, the second isolation layer 302 enclosing and forming the first type of opening 300a protruding from the first isolation layer 301 towards the first type of opening 300a; a plurality of light-emitting devices 400, at least a portion of a structure of the light-emitting device 400 being arranged within a corresponding one of the first type of openings 300a; and the second isolation layer 302 forming a hollow structure 302b at a side of the first isolation layer 301 away from the base plate 100, the hollow structure 302b being in communication with the functional opening 300b and arranged around at least a portion of the functional opening 300b.

The display panel 10 according to the embodiments of the present application has a display area AA and a non-display area NA, and the display panel 10 includes a base plate 100, a pixel defining layer 200, an isolation structure layer 300, and a plurality of light-emitting devices 400. The pixel defining layer 200 includes a pixel defining portion 210 and a plurality of pixel openings 220 enclosed and formed by the pixel defining portion 210, and the isolation structure layer 300 is arranged at a side of the pixel defining layer 200 away from the base plate 100 and encloses and forms a plurality of first type of openings 300A located in the display area AA and a functional opening 300b located in the non-display area NA. The functional opening 300b may facilitate increasing the light transmittance of the non-display area NA, so that when the display panel 10 is applied to a display apparatus, the photosensitive assembly for sensing light in the display apparatus may be correspondingly arranged under the functional opening, and thus the photosensitive assembly can better sense light through the functional opening.

The first type of opening 300a is in communication with the corresponding pixel opening 220, and both the isolation structure layer 300 and the pixel defining layer 200 may be used to divide the sub-pixels of the display panel 10. At least a portion of the structure of the light-emitting device 400 is arranged within the corresponding first type of opening 300a, so that the light-emitting device 400 within the first type of opening 300a can be used to achieve light emitting and display of the display area AA in the display panel 10.

The isolation structure layer 300 includes a first isolation layer 301 and a second isolation layer 302 located at a side of the first isolation layer 301 away from the base plate 100, the second isolation layer 302 enclosing and forming the first type of opening 300a is arranged protruding from the first isolation layer 301 towards the first type of opening 300a, so that when preparing the light-emitting device 400 of the display panel 10, at least a portion of the material of the light-emitting device 400 may be directly vapor deposited as a whole, and the second isolation layer 302 enclosing and forming the first type of opening 300a can block at least a portion of the material for preparing the light-emitting device 400 to separate the material of the light-emitting device 400 between adjacent sub-pixels, so as to facilitate forming a plurality of light-emitting devices 400 that are spaced apart and located within the first type of openings 300a. Therefore, no fine mask is needed when preparing the light-emitting device 400 of the display panel 10, for example, no fine metal mask is needed when vapor depositing the material of the light-emitting device 400, thereby better reducing the production and preparation costs of the display panel 10.

The second isolation layer 302 forms a hollow structure 302b at a side of the first isolation layer 301 away from the base plate 100, and the hollow structure 302b is in communication with the functional opening 300b and arranged around at least a portion of the functional opening 300b, so that when new material is formed on the isolation structure layer 300 during the manufacturing of the display panel 10, for example, when organic material is formed on the isolation structure layer 300, the second isolation layer 302 located at the periphery of the functional opening 300b within the non-display area NA is less likely to block the organic material, and the new material may better fall in the vicinity of the first isolation layer 301 at the periphery of the functional opening 300b. Moreover, when new material is formed on the isolation structure layer 300, the second isolation layer 302 is less likely to excessively block gas discharging, so that when organic material is formed on the isolation structure layer 300, the gas at the periphery of the functional opening 300b may be better discharged outwardly along the sidewall of the first isolation layer 301, thereby better increasing the structure stability and processing reliability of the display panel 10.

Optionally, the structure of the display panel 10 further according to the embodiments of the first aspect of the present application may be arranged with reference to any of the above embodiments, and thus the display panel 10 further according to the embodiments of the present application may have the beneficial effects of the display panel 10 in any of the above embodiments, which will not be repeated herein. For example, the base plate 100 may be the base plate 100 in any of the above embodiments. For example, the light-emitting device 400 may be the light-emitting device 400 in any of the above embodiments.

In some optional embodiments, at the hollow structure 302b, the protrusion length of the second isolation layer 302 relative to the first isolation layer 301 and towards the functional opening 300b is less than 0. For example, at the hollow structure 302b at the periphery of the functional opening 300b, at least a portion of the second isolation layer 302 may be arranged inwardly relative to the first isolation layer 301 towards a direction away from the functional opening 300b.

Optionally, if the second isolation layer 302 at the periphery of the functional opening 300b forms the hollow structure 302b at the side of the first isolation layer 301 away from the base plate 100, a portion of the functional opening 300b at the hollow structure 302b may be enclosed and formed only by the first isolation layer 301.

Referring to FIG. 16 and in conjunction with FIGS. 1 to 15, in some optional embodiments, the isolation structure layer 300 includes an isolation structure 310 at least partially located in the display area AA and an edge structure 320 located in the non-display area NA, the first type of openings 300a include an isolation opening 310a enclosed and formed by the isolation structure 310, the edge structure 320 encloses and forms the functional opening 300b, the isolation structure 310 includes a first isolation portion 311 and a second isolation portion 312 located at a side of the first isolation portion 311 away from the base plate 100, and the second isolation portion 312 is arranged protruding from the first isolation portion 311 towards the isolation opening 310a.

Optionally, the light-emitting device 400 may be at least partially located within the isolation opening 310a, and the isolation opening 310a may be in communication with the pixel opening 220. Optionally, the first isolation portion 311 may participate in forming the first isolation layer 301, and the second isolation portion 312 may participate in forming the second isolation layer 302.

Optionally, the isolation structure 310 may be the isolation structure 310 in any of the above embodiments. For example, the isolation structure 310 may be configured to separate the material of the light-emitting layer 420 and the second electrode layer 430 when preparing the light-emitting layer 420 and the second electrode layer 430, so as to divide sub-pixels. The second isolation portion 312 may be arranged protruding from the first isolation portion 311 towards the first type of opening 300a, i.e., a protrusion length of the second isolation portion 312 relative to the first isolation portion 311 and towards the first type of opening 300a may be greater than 0, so that when preparing the light-emitting device 400 of the display panel 10, at least a portion of the material of the light-emitting device 400 may be directly vapor deposited as a whole, and the second isolation portion 312 can block at least a portion of the material for preparing the light-emitting device 400 to separate the material of the light-emitting device 400 between adjacent sub-pixels, so as to facilitate forming a plurality of light-emitting devices 400 that are spaced apart and located within the isolation openings 310a, and thus no fine mask is needed when preparing the light-emitting device 400 of the display panel 10.

In some optional embodiments, the edge structure 320 includes a first edge portion 320a, the second isolation layer 302 is provided with a hollow structure 302b at a side of the first edge portion 320a away from the base plate 100, and the hollow structure 302b is in communication with the functional opening 300b and arranged around at least a portion of the functional opening 300b.

Optionally, at the hollow structure 302b, the protrusion length of the second isolation layer 302 relative to the first edge portion 320a and towards the functional opening 300b is less than 0.

Optionally, as shown in FIG. 16, the edge structure 320 may include a first edge portion 320a and a second edge portion 320b, while the second edge portion 320b may be arranged inwardly relative to the first edge portion 320a towards a side away from the functional opening 300b. Therefore, the second isolation layer 302 being provided with a hollow structure 302b at a side of the first edge portion 320a away from the base plate 100 may mean that the second edge portion 320b of the second isolation layer 302 may be arranged only partially covering the first edge portion 320a.

FIG. 17 shows a partial sectional view of the display panel 10 according to yet another embodiment of the present application.

Optionally, as shown in FIG. 17, the edge structure 320 may include only the first edge portion 320a. The second isolation layer 302 being provided with a hollow structure 302b at a side of the first edge portion 320a away from the base plate 100 may mean that the second isolation layer 302 may not cover the first edge portion 320a.

In these optional embodiments, by arranging that the second isolation layer 302 is provided with the hollow structure 302b at the side of the first edge portion 320a away from the base plate 100, the block of gas discharging of the second isolation layer 302 at the periphery of the functional opening 300b can be better reduced, so that when organic material is formed on the isolation structure layer 300, the gas at the periphery of the functional opening 300b may be better discharged outwardly along the sidewall of the first edge portion 320a, thereby better increasing the structure stability and processing reliability of the display panel 10.

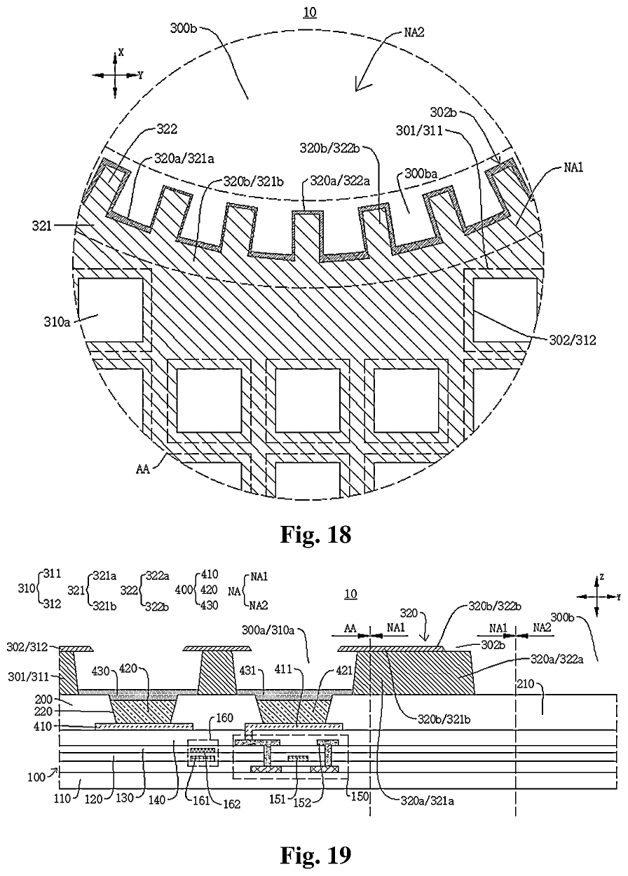

FIG. 18 shows a partially enlarged schematic diagram of the orthographic projection of the isolation structure layer 300 on the base plate 100 according to another embodiment of the present application.

Referring to FIG. 18 and in conjunction with FIGS. 1 to 15, in some optional embodiments, the functional opening 300b includes a first recess 300ba arranged in an edge area and penetrating the edge structure 320 in the thickness direction Z of the display panel 10.

Optionally, the edge area of the functional opening 300b may refer to an edge area of the functional opening 300b close to the edge structure 320. Optionally, the first recess 300ba may be formed by inwardly recessing a portion of the surface of the edge structure 320 towards the functional opening 300b.

In these optional embodiments, by arranging the first recess 300ba, when new material is formed on the isolation structure layer 300 during the manufacturing of the display panel 10, the first recess 300ba protruding towards the edge structure 320 can improve the gas discharging path during the formation of the new material, so that when the new material is deposited on the isolation structure layer 300 along a certain direction, under the extrusion force of the deposited material, the gas between the new material and the edge structure 320 and the gas between the new material and the base plate 100 may be discharged outwardly, under the guide of the edge structure 320 at the periphery of the first recess 300ba, from the edge of the edge structure 320 at the periphery of the first recess 300ba in a direction away from the display area AA, thereby better increasing the structure stability and processing reliability of the display panel 10.

As shown in FIG. 18, in some optional embodiments, the hollow structure 302b is in communication with the first recess 300ba and arranged around at least a portion of the first recess 300ba.

Optionally, at the hollow structure 302b, the protrusion length of the second isolation layer 302 relative to the first edge portion 320a and towards the first recess 300ba is less than 0.

In these optional embodiments, by arranging that the hollow structure 302b is in communication with the first recess 300ba and arranged around at least a portion of the first recess 300ba, the block of gas discharging of the second isolation layer 302 at the periphery of the first recess 300ba can be better reduced, so that when organic material is formed on the isolation structure layer 300, the gas at the periphery of the first recess 300ba may also be better discharged outwardly from the sidewall of the first edge portion 320a in the thickness direction Z of the display panel 10, thereby better increasing the structure stability and processing reliability of the display panel 10.

In some optional embodiments, the non-display area NA includes a first area NA1 adjacent to the display area AA and a second area NA2 located at a side of the first area NA1 away from the display area AA, the edge structure 320 is located in the first area NA1 and includes a main structure 321 connected with the isolation structure 310 and a plurality of convex structures 322 protruding towards the second area NA2 relative to the main structure 321, and the first recess 300ba is located between adjacent convex structures 322.

In these optional embodiments, when new material is formed on the isolation structure layer 300 during the manufacturing of the display panel 10, the convex structure 322 protruding relative to the main structure 321 can improve the gas discharging path during the formation of the material, so that when the material is deposited on the isolation structure layer 300 along a certain direction, under the extrusion force of the deposited material, the gas between the new material and the edge structure 320 and the gas between the new material and the base plate 100 may be discharged outwardly, under the guide of the convex structure 322, from the edge of the convex structure 322 in a direction towards the second area NA2, thereby better increasing the structure stability and processing reliability of the display panel 10.

Optionally, the convex structure 322 may include a first convex portion 322a, and the main structure 321 may include a first main portion 321a.

Optionally, the first convex portion 322a may participate in forming the first edge portion 320a. Optionally, the first convex portion 322a and the first isolation portion 311 may be arranged in the same layer and made of the same material, so that the convex structure 322 and the isolation structure 310 may be prepared by the same or similar preparation process and preparation equipment. Optionally, the first convex portion 322a of the convex structure 322 and the first main portion 321a of the main structure 321 may be integrally prepared.

Optionally, the first main portion 321a may participate in forming the first edge portion 320a. Optionally, the first main portion 321a and the first isolation portion 311 may be arranged in the same layer and made of the same material, so that the main structure 321 and the isolation structure 310 may be prepared by the same or similar preparation process and preparation equipment. Optionally, the first main portion 321a of the main structure 321 and the first isolation portion 311 may be integrally prepared.

FIG. 19 shows a partial sectional view of the display panel 10 according to yet another embodiment of the present application.

As shown in FIG. 19, in some optional embodiments, the second isolation layer 302 is provided with a hollow structure 302b at a side of the first convex portion 322a away from the base plate 100.

Optionally, at the hollow structure 302b, the protrusion length of the second isolation layer 302 relative to the first convex portion 322a and towards the functional opening 300b is less than 0.

Optionally, as shown in FIG. 19, the convex structure 322 may include a first convex portion 322a and a second convex portion 322b, while the second convex portion 322b may be arranged inwardly relative to the first convex portion 322a towards a side away from the functional opening 300b. Therefore, the second isolation layer 302 being provided with a hollow structure 302b at a side of the first convex portion 322a away from the base plate 100 may mean that the second convex portion 322b of the convex structure 322 may be arranged only partially covering the first convex portion 322a.

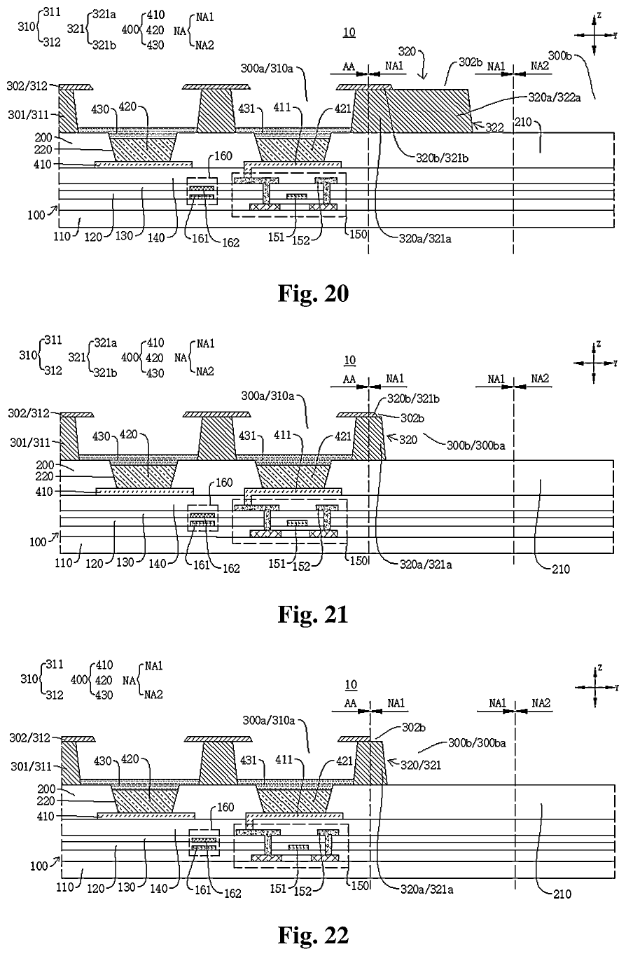

FIG. 20 shows a partial sectional view of the display panel 10 according to yet another embodiment of the present application.

Optionally, as shown in FIG. 20, the convex structure 322 may include only the first convex portion 322a. The second isolation layer 302 being provided with a hollow structure 302b at a side of the first convex portion 322a away from the base plate 100 may mean that the second isolation layer 302 may not cover the first convex portion 322a.

In these optional embodiments, by arranging that the second isolation layer 302 is provided with the hollow structure 302b at the side of the first convex portion 322a away from the base plate 100, the block of gas discharging of the second isolation layer 302 at the periphery of the functional opening 300b can be better reduced, so that when organic material is formed on the isolation structure layer 300, the gas at the periphery of the functional opening 300b may be better discharged outwardly along the sidewall of the first convex portion 322a, thereby better increasing the structure stability and processing reliability of the display panel 10.

FIG. 21 shows a partial sectional view of the display panel 10 according to yet another embodiment of the present application.

In some optional embodiments, the second isolation layer 302 is provided with a hollow structure 302b at a side of the first main portion 321a away from the base plate 100.

Optionally, at the hollow structure 302b, the protrusion length of the second isolation layer 302 relative to the first main portion 321a and towards the functional opening 300b is less than 0.

Optionally, as shown in FIG. 21, the main structure 321 may include a first main portion 321a and a second main portion 321b, while the second main portion 321b may be arranged inwardly relative to the first main portion 321a towards a side away from the functional opening 300b. Therefore, the second isolation layer 302 being provided with a hollow structure 302b at a side of the first main portion 321a away from the base plate 100 may mean that the second main portion 321b of the second isolation layer 302 may be arranged only partially covering the first main portion 321a.

FIG. 22 shows a partial sectional view of the display panel 10 according to yet another embodiment of the present application.

Optionally, as shown in FIG. 22, the main structure 321 may include only the first main portion 321a. The second isolation layer 302 being provided with a hollow structure 302b at a side of the first main portion 321a away from the base plate 100 may mean that the second isolation layer 302 may not cover the first main portion 321a.

In these optional embodiments, by arranging that the second isolation layer 302 is provided with the hollow structure 302b at the side of the first main portion 321a away from the base plate 100, the block of gas discharging of the second isolation layer 302 at the periphery of the functional opening 300b can be better reduced, so that when organic material is formed on the isolation structure layer 300, the gas at the periphery of the functional opening 300b may be better discharged outwardly along the sidewall of the first main portion 321a, thereby better increasing the structure stability and processing reliability of the display panel 10.

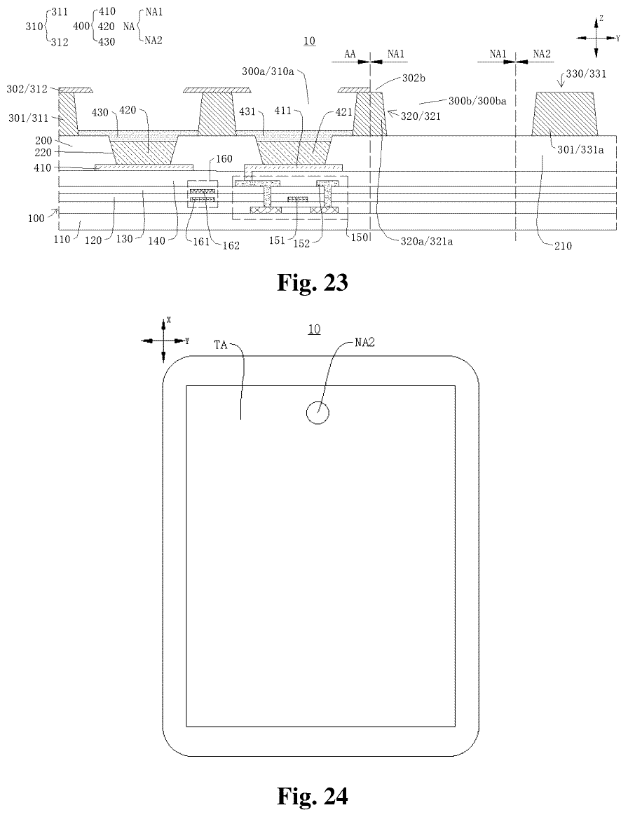

FIG. 23 shows a partial sectional view of the display panel 10 according to yet another embodiment of the present application.

Referring to FIG. 23 and in conjunction with FIGS. 1 to 15, in some optional embodiments, the isolation structure layer 300 further includes an auxiliary structure 330 located within the functional opening 300b and spaced apart from the edge structure 320.

Optionally, the auxiliary structure 330 may be arranged in the second area NA2.

Optionally, the second area NA2 includes a first sub-area NA21 and a second sub-area NA22 located at a side of the first sub-area NA21 away from the first area NA1, the auxiliary structure 330 includes a plurality of first auxiliary structures 331 located in the first sub-area NA21, and the plurality of first auxiliary structures 331 are spaced apart and distributed around a periphery of the second sub-area NA22.

In these optional embodiments, by arranging the auxiliary structure 330, which is spaced apart from the edge structure 320, within the functional opening 300b, when the isolation structure layer 300 is etched and prepared, the etching material located within the functional opening 300b in the second area NA2 can also etch the material of the auxiliary structure 330, so that the auxiliary structure 330 may restrict the delivery of the etching material within the functional opening 300b towards the edge structure 320 to better reduce the etching amount of the etching material on the material of the edge structure 320, and thus the edge structure 320 is less likely to be damaged by over etching, thereby better increasing the structure stability of the display panel 10. Moreover, the auxiliary structure 330 not only reduces the etching amount of the etching material on the material of the edge structure 320, but also can facilitate achieving the topography of the edge structure 320 in the above embodiments. That is, the arrangement of the auxiliary structure 330 can reduce the etching amount of the etching material on the material of the edge structure 320, so as to facilitate forming the topography in which the protrusion length of at least a portion of the second convex portion 322b relative to the first convex portion 322a and towards the functional opening 300b is less than the protrusion length of the second isolation portion 312 relative to the first isolation portion 311 of the isolation structure 310 and towards the isolation opening 310a, as well as the topography in which the protrusion length of at least a portion of the second main portion 321b relative to the first main portion 321a and towards the first recess 300ba is less than the protrusion length of the second isolation portion 312 relative to the first isolation portion 311 of the isolation structure 310 and towards the isolation opening 310a.

In addition, by arranging that the adjacent auxiliary structures 330 are spaced apart, when new material is formed on the isolation structure layer 300 during the manufacturing of the display panel 10, for example, when the material is deposited on the isolation structure layer 300 along a certain direction, the gas between the new material and the auxiliary structure 330 and the gas between the new material and the base plate 100 may be discharged outwardly, under the guide of the spacing between the adjacent auxiliary structures 330, from the edge of the auxiliary structure 330, thereby better increasing the structure stability and processing reliability of the display panel 10.

In some optional embodiments, the first auxiliary structure 331 includes a first auxiliary portion 331a, and the second isolation layer 302 is provided with a hollow structure 302b at a side of the first auxiliary portion 331a away from the base plate 100.

Optionally, as shown in FIG. 23, the auxiliary structure 330 may include only the first auxiliary portion 331a. The second isolation layer 302 being provided with a hollow structure 302b at a side of the first auxiliary portion 331a away from the base plate 100 may mean that the second isolation layer 302 may not cover the first auxiliary portion 331a.

In these optional embodiments, by arranging that the second isolation layer 302 is provided with the hollow structure 302b at the side of the first auxiliary portion 331a away from the base plate 100, the block of gas discharging of the second isolation layer 302 at the periphery of the functional opening 300b can be better reduced, so that when organic material is formed on the isolation structure layer 300, the gas at the periphery of the functional opening 300b may be better discharged outwardly along the sidewall of the first auxiliary portion 331a, thereby better increasing the structure stability and processing reliability of the display panel 10.

Referring to FIGS. 1 to 23, the embodiments of the first aspect of the present application further provide a display panel 10 having a display area AA and a non-display area NA, the display panel 10 includes: a base plate 100; a pixel defining layer 200 arranged at one side of the base plate 100, the pixel defining layer 200 including a pixel defining portion 210 and a plurality of pixel openings 220 enclosed and formed by the pixel defining portion 210; an isolation structure layer 300 arranged at one side of the base plate 100 and including an isolation structure 310 at least partially located in the display area AA and an edge structure 320 connected with the isolation structure 310 and located in the non-display area NA, the isolation structure 310 enclosing and forming an isolation opening 310a in communication with the pixel opening 220, the edge structure 320 including a main structure 321 connected with the isolation structure 310 and a plurality of convex structures 322 protruding towards a second area NA2 relative to the main structure 321, the edge structure 320 enclosing and forming a functional opening 300b, an edge area of the functional opening 300b including a first recess 300ba protruding towards the edge structure 320, the first recess 300ba being arranged penetrating the edge structure 320 in a thickness direction Z of the display panel 10 and located between adjacent convex structures 322; and a plurality of light-emitting devices 400, at least a portion of a structure of the light-emitting device 400 being arranged within the isolation opening 310a.

The display panel 10 according to the embodiments of the present application has a display area AA and a non-display area NA, and the display panel 10 includes a base plate 100, a pixel defining layer 200, an isolation structure layer 300, and a plurality of light-emitting devices 400. The pixel defining layer 200 includes a pixel defining portion 210 and a plurality of pixel openings 220 enclosed and formed by the pixel defining portion 210, the isolation structure layer 300 is arranged at a side of the pixel defining layer 200 away from the base plate 100, the isolation structure layer 300 includes an isolation structure 310 at least partially located in the display area AA and an edge structure 320 connected with the isolation structure 310 and located in the non-display area NA, the isolation structure 310 encloses and forms an isolation opening 310a in communication with the pixel opening 220, and both the isolation structure 310 and the pixel defining layer 200 may be used to divide the sub-pixels of the display panel 10. At least a portion of the structure of the light-emitting device 400 is arranged within the isolation opening 310a, and the light-emitting device 400 within the isolation opening 310a can be used to achieve light emitting and display of the display area AA in the display panel 10.

The edge structure 320 encloses and forms the functional opening 300b, which may facilitate increasing the light transmittance of the non-display area NA, so that when the display panel 10 is applied to a display apparatus, the photosensitive assembly for sensing light in the display apparatus may be correspondingly arranged under the functional opening, and thus the photosensitive assembly can better sense light through the functional opening.

The edge structure 320 includes the main structure 321 connected with the isolation structure 310 and a plurality of convex structures 322 protruding towards the second area NA2 relative to the main structure 321, the edge area of the functional opening 300b includes the first recess 300ba protruding towards the edge structure 320, and the first recess 300ba is arranged penetrating the edge structure 320 in the thickness direction Z of the display panel 10 and located between adjacent convex structures 322. When new material is formed on the isolation structure layer 300 during the manufacturing of the display panel 10, the first recess 300ba protruding towards the edge structure 320 can improve the gas discharging path during the formation of the new material, so that when the new material is deposited on the isolation structure layer 300 along a certain direction, under the extrusion force of the deposited material, the gas between the new material and the edge structure 320 and the gas between the new material and the base plate 100 may be discharged outwardly, under the guide of the convex structure 322 at the periphery of the first recess 300ba, from the edge of the convex structure 322 at the periphery of the first recess 300ba in a direction away from the display area AA, thereby better increasing the structure stability and processing reliability of the display panel 10.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

For example, the base plate 100 may be the base plate 100 in any of the above embodiments. For example, the light-emitting device 400 may be the light-emitting device 400 in any of the above embodiments. For example, the isolation structure layer 300 may be the isolation structure layer 300 in any of the above embodiments, and may include the isolation structure 310, the edge structure 320, and the auxiliary structure 330 in any of the above embodiments.

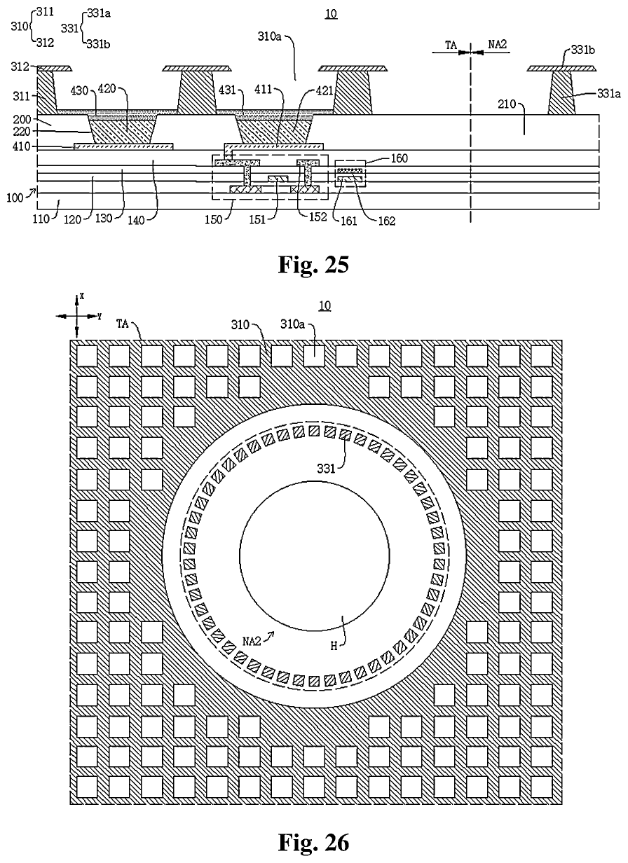

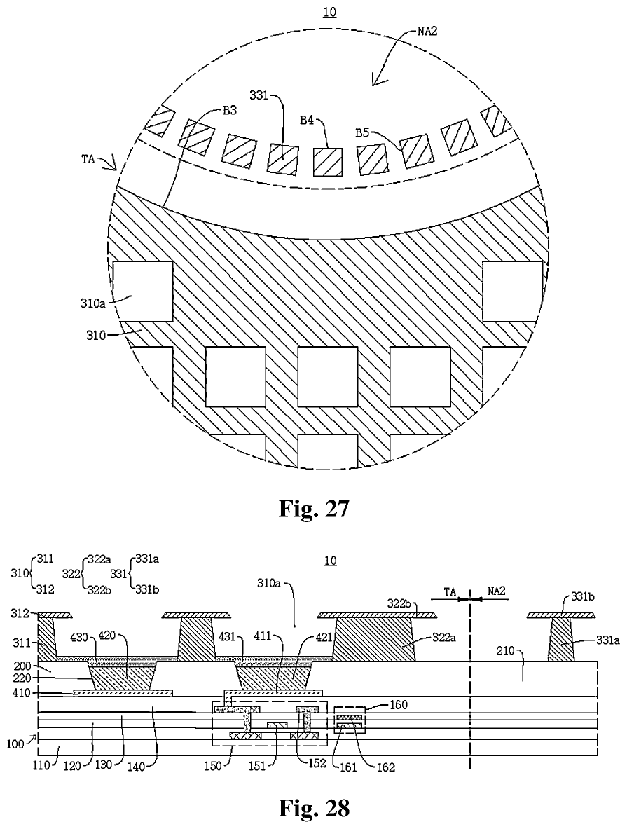

FIG. 24 shows a schematic structural diagram of the display panel 10 according to another embodiment of the present application, FIG. 25 shows a partial sectional view of the display panel 10 according to yet another embodiment of the present application, FIG. 26 shows a partial schematic diagram of the display panel 10 according to yet another embodiment of the present application, and FIG. 27 shows a partially enlarged schematic diagram of an orthographic projection of the isolation structure 310 and the first auxiliary structure 331 on the base plate 100 according to an embodiment of the present application.

Referring to FIGS. 24 to 27 in conjunction with the figures in the above embodiments, the embodiments of the first aspect of the present application further provide a display panel 10 having a first specific area TA and a second area NA2 that are adjacent, the display panel 10 includes: a base plate 100; an isolation structure 310 arranged at one side of the base plate 100 and located in the first specific area TA, the isolation structure 310 enclosing and forming an isolation opening 310a; a plurality of first auxiliary structures 331 located within the second area NA2 and arranged at a side of the base plate 100 towards the isolation structure 310, the first auxiliary structures 331 being spaced apart from the isolation structure 310, and adjacent first auxiliary structures 331 being spaced apart; and a light-emitting layer 420 including a light-emitting unit 421 arranged within the isolation opening 310a.

The display panel 10 according to the embodiments of the present application has a first specific area TA and a second area NA2 that are adjacent, and the display panel 10 includes a base plate 100, an isolation structure 310, a plurality of first auxiliary structures 331, and a light-emitting layer 420. The isolation structure 310 is arranged at one side of the base plate 100 and located in the first specific area TA, the isolation structure 310 encloses and forms an isolation opening 310a, and the isolation structure 310 may be used to divide the sub-pixels of the display panel 10. The light-emitting layer 420 includes a light-emitting unit 421 arranged within the isolation opening 310a, so that the display panel 10 within the first specific area TA may be used to emit light and display.

By arranging the first auxiliary structure 331 within the second area NA2, when the isolation structure 310 is etched and prepared, the etching material located within the second area NA2 can also etch the material of the first auxiliary structure 331, so that the first auxiliary structure 331 may restrict the delivery of the etching material within the second area NA2 towards the isolation structure 310 to better reduce the etching amount of the etching material on the material of the isolation structure 310, and thus the isolation structure 310 is less likely to be damaged by over etching, thereby better increasing the structure stability of the display panel 10. In addition, by arranging that the adjacent first auxiliary structures 331 are spaced apart, when new material is formed on the first auxiliary structure 331 during the manufacturing of the display panel 10, for example, when the material is deposited on the first auxiliary structure 331 along a certain direction, the gas between the material and the first auxiliary structure 331 and the gas between the material and the base plate 100 may be discharged outwardly, under the guide of the spacing between the adjacent first auxiliary structures 331, from the edge of the first auxiliary structure 331, thereby better increasing the structure stability and processing reliability of the display panel 10.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

Optionally, the first specific area TA may include the first area NA1 in the display area AA and the non-display area NA in any of the above embodiments.

In some embodiments of the present application, at least a portion of the first specific area TA of the display panel 10 may be used as the display area of the display panel 10, i.e., at least a portion of the first specific area TA of the display panel 10 may emit light and display. The second area NA2 of the display panel 10 may be used as the non-display area of the display panel 10, e.g., the second area NA2 of the display panel 10 may be used as a functional area of the display panel 10, and the light transmittance of the second area NA2 may be greater than the light transmittance of the first specific area TA. When the display panel 10 is applied to a display apparatus, the photosensitive assembly for sensing light in the display apparatus may be correspondingly arranged under the second area NA2, and the photosensitive assembly may better sense light through the second area NA2, in which the photosensitive assembly may include at least one of: a distance sensor, a camera, an under-screen fingerprint recognition module, an infrared light emitting diode, a proximity sensor, or other components capable of sensing light. As another example, the second area NA2 may be used as a frame area of the display panel 10.

For ease of description, in the following embodiments, for example, the second area NA2 is used as the functional area of the display panel 10. Optionally, the display panel 10 is provided with a functional hole H in the second area NA2, so that if a photosensitive assembly is correspondingly arranged at the second area NA2, the photosensitive assembly may better sense light through the functional hole H.

Optionally, the isolation structure 310 may be arranged around at least a portion of the second area NA2, so that the isolation structure 310 is less likely to affect the light transmittance of the second area NA2.

Optionally, there are a plurality of first auxiliary structures 331 which are spaced apart from each other and arranged around at least a portion of the second area NA2. For example, the plurality of first auxiliary structures 331 are arranged around at least a portion of the functional hole H, so that the first auxiliary structures 331 may be better distributed at a side of the isolation structure 310 towards the second area NA2, so as to better prevent the etching material with a higher concentration within the second area NA2 from flowing to the isolation structure 310, thereby better reducing the etching amount of the etching material on the material of the isolation structure 310, and thus the isolation structure 310 is less likely to be damaged by over etching.

In some embodiments of the present application, the isolation structure 310 may be configured to separate the material of the light-emitting layer 420 when preparing the light-emitting layer 420, so as to divide sub-pixels. Herein, the shape of the isolation structure 310 may be set in various ways and may be any of the shapes capable of blocking and separating the material of the light-emitting layer 420 within the adjacent isolation openings 310a.

In some optional embodiments, the isolation structure 310 may include a first isolation portion 311 and a second isolation portion 312 located at a side of the first isolation portion 311 away from the base plate 100, and the second isolation portion 312 is arranged protruding from the first isolation portion 311 towards the isolation opening 310a.

By arranging that the second isolation portion 312 is arranged protruding from the first isolation portion 311 towards the isolation opening 310a, when vapor depositing the light-emitting layer 420 of the display panel 10, the second isolation portion 312 can block at least a portion of the material for preparing the light-emitting layer 420 to separate the light-emitting layer 420 between adjacent sub-pixels, and also facilitate forming a plurality of light-emitting units 421 that are spaced apart. Therefore, no fine mask is needed when vapor depositing the light-emitting layer 420 of the display panel 10, for example, no fine metal mask is needed when vapor depositing the light-emitting layer 420, thereby better reducing the production and preparation costs of the display panel 10.

Optionally, the second isolation portion 312 may be further arranged protruding from the first isolation portion 311 towards the second area NA2. For example, the second isolation portion 312 located on the isolation structure 310 between the adjacent convex structures 322 may be further arranged protruding from the first isolation portion 311 towards the second area NA2

In some optional embodiments, the shape of the first auxiliary structure 331 may be similar to the shape of the isolation structure 310. For example, the first auxiliary structure 331 includes a first auxiliary portion 331a and a second auxiliary portion 331b located at a side of the first auxiliary portion 331a away from the base plate 100, and the second auxiliary portion 331b is arranged protruding from the first auxiliary portion 331a, e.g., an orthographic projection of the first auxiliary portion 331a on the base plate 100 is located within an orthographic projection of the second auxiliary portion 331b on the base plate 100. Herein, when the material of the isolation structure 310 is etched using an etching material, the etching material may also etch the first auxiliary structure 331, which can reduce the etching amount of the etching material on the material of the isolation structure 310, and also obtain, in the first auxiliary structure 331, the shape in which the second auxiliary portion 331b is arranged protruding from the first auxiliary portion 331a.

Optionally, the first auxiliary portion 331a and the first isolation portion 311 may be arranged in the same layer and made of the same material, or the second auxiliary portion 331b and the second isolation portion 312 may be arranged in the same layer and made of the same material, so that the first auxiliary structure 331 and the isolation structure 310 may be prepared in the same preparation process, so as to increase the manufacturing efficiency of the display panel 10.

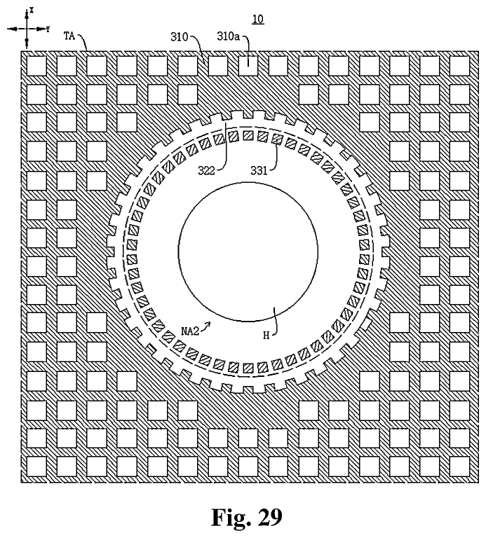

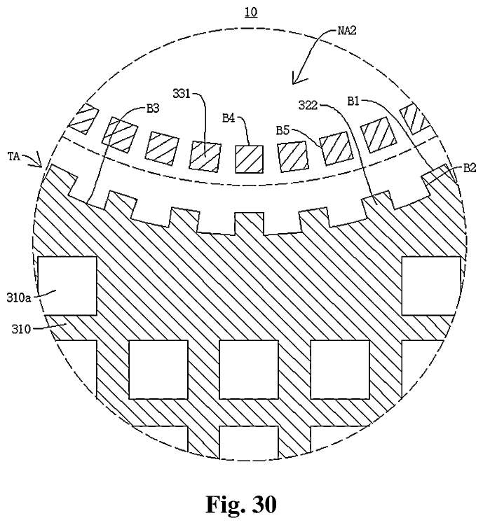

FIG. 28 shows a partial sectional view of the display panel 10 according to yet another embodiment of the present application, FIG. 29 shows a partial schematic diagram of the display panel 10 according to yet another embodiment of the present application, and FIG. 30 shows a partially enlarged schematic diagram of an orthographic projection of the isolation structure 310, the convex structure 322, and the first auxiliary structure 331 on a base plate 100 according to an embodiment of the present application.

As shown in FIGS. 28 to 30, in some optional embodiments, the display panel 10 further includes a convex structure 322 connected with the isolation structure 310 and arranged at a side of the isolation structure 310 towards the second area NA2, and the first auxiliary structure 331 is spaced apart from the convex structure 322.

Optionally, the convex structure 322 may be further arranged in the first specific area TA.

In these optional embodiments, by arranging that the convex structure 322 is connected with the isolation structure 310 and arranged at the side of the isolation structure 310 towards the second area NA2, i.e., by arranging the convex structure 322 protruding towards the second area NA2 at an edge portion of the isolation structure 310, when the isolation structure 310 is etched and prepared, the etching material can also etch the material of the convex structure 322, so as to better reduce the etching amount of the etching material on the material of the isolation structure 310, and thus the isolation structure 310 is less likely to be damaged by over etching, thereby better increasing the structure stability of the display panel 10.

Moreover, when new material is formed on the isolation structure 310 during the manufacturing of the display panel 10, for example, when organic material is formed on the isolation structure 310, the convex structure 322 protruding relative to the isolation structure 310 can improve the gas discharging path during the formation of the material, so that when the material is deposited on the isolation structure 310 along a certain direction, under the extrusion force of the deposited material, the gas between the material and an edge portion of the isolation structure 310 towards the second area NA2, the gas between the material and the convex structure 322, or the gas between the material and the base plate 100 may be discharged outwardly, under the guide of the convex structure 322, from the edge of the convex structure 322, thereby better increasing the structure stability of the display panel 10.

In some optional embodiments, the convex structure 322 may include a first convex portion 322a which is integrally prepared with the first isolation portion 311, or the convex structure 322 may include a second convex portion 322b which is integrally prepared with the second isolation portion 312, so that at least a portion of the convex structure 322 and the isolation structure 310 may be prepared in the same preparation process, so as to increase the manufacturing efficiency of the display panel 10.

Optionally, the shape of the convex structure 322 may be similar to the shape of the isolation structure 310. For example, the convex structure 322 may include a first convex portion 322a and a second convex portion 322b which may be arranged protruding from the first convex portion 322a towards the second area NA2. Herein, when the material of the isolation structure 310 is etched using an etching material, the etching material may also etch the convex structure 322, which can reduce the etching amount of the etching material on the material of the isolation structure 310, and also obtain, in the convex structure 322, the shape in which the second convex portion 322b protrudes from the first convex portion 322a towards the second area NA2.

As shown in FIGS. 29 and 30, in these optional embodiments, by arranging the convex structure 322 protruding towards the second area NA2 at an edge portion of the isolation structure 310, when the material of the isolation structure 310 is etched to prepare the first isolation portion 311 and the second isolation portion 312, the etching material located at the edge portion of the isolation structure 310 towards the second area NA2 can also etch the material of the convex structure 322, so as to better reduce the etching amount of the etching material on the material of the isolation structure 310, and thus the isolation structure 310 is less likely to be damaged by over etching, thereby better increasing the structure stability of the display panel 10.

Optionally, the area of the orthographic projection of the first auxiliary structure 331 on the base plate 100 may be greater than the area of the orthographic projection of the convex structure 322 on the base plate 100, so that the first auxiliary portion 331a of the first auxiliary structure 331 is less likely to be removed by etching.

In some optional embodiments, there are a plurality of convex structures 322 which are spaced apart from each other and arranged around at least a portion of the second area NA2. For example, the plurality of convex structures 322 are spaced apart from each other and arranged around at least a portion of the functional hole H.

Optionally, the convex structure 322 may be arranged protruding from the isolation structure 310 towards the second area NA2, e.g., the convex structure 322 may be arranged protruding from the isolation structure 310 towards the functional hole H.

In these optional embodiments, by arranging that the plurality of convex structures 322 are spaced apart from each other and arranged around at least a portion of the second area NA2, when material is deposited on the isolation structure 310 along a certain direction, the gas between the material and the isolation structure 310 or the gas between the material and the convex structure 322 may be discharged outwardly, under the guide of the spacing between the adjacent convex structures 322, from the edge of the convex structure 322, thereby better increasing the structure stability of the display panel 10. Moreover, the convex structures 322 arranged around at least a portion of the second area NA2 can further reduce the etching amount of the etching material on the isolation structure 310, so that the isolation structure 310 is less likely to be damaged by over etching, thereby better increasing the structure stability of the display panel 10.

In some embodiments of the present application, the shape of the convex structure 322 may be set in various ways and may be a shape which facilitates gas discharging when material is formed on the convex structure 322.

As shown in FIGS. 29 and 30, in some optional embodiments, the orthographic projection of the convex structure 322 on the base plate 100 may have a first edge B1 and a second edge B2 which may intersect with each other. For example, the first edge B1 and the second edge B2 may be perpendicular to each other.

In these optional embodiments, by arranging that the first edge B1 intersects the second edge B2, when material is deposited on the isolation structure 310 and the convex structure 322 along a certain direction, for example, when material is deposited on the isolation structure 310 and the convex structure 322 along any of the first direction X, the second direction Y, the circumferential direction of the functional hole H, or the radial direction of the functional hole H, if one of the first edge B1 and the second edge B2 cannot well fit the depositing direction of the material, the other one of the first edge B1 and the second edge B2 may well fit the depositing direction of the material. For example, if one of the first edge B1 and the second edge B2 is perpendicular to the depositing direction of the material, the angle between the other one of the first edge B1 and the second edge B2 and the depositing direction of the material may be less than 90 degrees, so that when material is deposited on the isolation structure 310 and the convex structure 322 along a certain direction, under the extrusion force of the deposited material, the gas between the material and the edge of the isolation structure 310 towards the second area NA2 or the gas between the material and the convex structure 322 may be better discharged outwardly under the guide of at least one of the first edge B1 and the second edge B2, thereby better increasing the structural stability of the display panel 10.

Optionally, the first edge B1 intersecting the second edge B2 may mean that the first edge B1 and the second edge B2 may be straight edges and intersect with each other, so as to enhance gas guiding effect of the edge portion of the convex structure 322, which can facilitate gas discharging. Optionally, a curved edge (not shown) may be connected between the first edge B1 and the second edge B2 for transition.

In some optional embodiments, the orthographic projection of the convex structure 322 on the base plate 100 may be approximately polygonal. For example, the orthographic projection of the convex structure 322 on the base plate 100 may be approximately rectangular or triangular, etc., in which the convex structure 322 of which the orthographic projection is approximately rectangular may have a better extension size than other shapes, which can facilitate gas discharging. For ease of description, in the following embodiments, for example, the orthographic projection of the convex structure 322 on the base plate 100 is approximately rectangular.

Optionally, the first edge B1 may be located at a side of the second edge B2 away from the isolation structure 310, and the second edges B2 are arranged at both sides of the first edge B1.

In some optional embodiments, the side of the orthographic projection of the isolation structure 310 on the base plate 100 towards the second area NA2 has a third edge B3, and the second edge B2 intersects the third edge B3.

Optionally, the second edge B2 may be connected between the first edge B1 and the third edge B3, and the second edge B2 is perpendicular to the third edge B3.

Optionally, the second edge B2 intersecting the third edge B3 may mean that the second edge B2 and the third edge B3 may be straight edges and intersect with each other. Optionally, a curved edge (not shown) may be connected between the third edge B3 and the second edge B2 for transition.

In these optional embodiments, by arranging that the second edge B2 intersects the third edge B3, when material is deposited on the isolation structure 310 and the convex structure 322 along a certain direction, if the third edge B3 cannot well fit the depositing direction of the material, the second edge B2 may well fit the depositing direction of the material. For example, if the third edge B3 is perpendicular to the depositing direction of the material, the angle between the second edge B2, which intersects the third edge B3, and the depositing direction of the material may be less than 90 degrees, so that when material is deposited on the isolation structure 310 and the convex structure 322 along a certain direction, under the extrusion force of the deposited material, the gas between the material and the edge of the isolation structure 310 towards the second area NA2 or the gas between the material and the convex structure 322 may be better discharged outwardly under the guide of the second edge B2, thereby better increasing the structural stability of the display panel 10.

In some embodiments of the present application, the shape of the first auxiliary structure 331 may be set in various ways and may be a shape which facilitates gas discharging when material is formed on the first auxiliary structure 331.

In some optional embodiments, the orthographic projection of the first auxiliary structure 331 on the base plate 100 has a fourth edge B4 and a fifth edge B5 which may intersect with each other. For example, the fourth edge B4 and the fifth edge B5 may be perpendicular to each other.

In these optional embodiments, by arranging that the fourth edge B4 intersects the fifth edge B5, when material is deposited on the first auxiliary structure 331 along a certain direction, for example, when material is deposited on the first auxiliary structure 331 along any of the first direction X, the second direction Y, the circumferential direction of the functional hole H, or the radial direction of the functional hole H, if one of the fourth edge B4 and the fifth edge B5 cannot well fit the depositing direction of the material, the other one of the fourth edge B4 and the fifth edge B5 may well fit the depositing direction of the material. For example, if one of the fourth edge B4 and the fifth edge B5 is perpendicular to the depositing direction of the material, the angle between the other one of the fourth edge B4 and the fifth edge B5 and the depositing direction of the material may be less than 90 degrees, so that when material is deposited on the first auxiliary structure 331 along a certain direction, under the extrusion force of the deposited material, the gas between the material and the auxiliary structure may be better discharged outwardly under the guide of at least one of the fourth edge B4 and the fifth edge B5, thereby better increasing the structural stability of the display panel 10.

Optionally, the fourth edge B4 intersecting the fifth edge B5 may mean that the fourth edge B4 and the fifth edge B5 may be straight edges and intersect with each other, so as to enhance gas guiding effect of the edge portion of the first auxiliary structure 331, which can facilitate gas discharging. Optionally, a curved edge (not shown) may be connected between the fourth edge B4 and the fifth edge B5 for transition.

In some optional embodiments, the orthographic projection of the first auxiliary structure 331 on the base plate 100 may be approximately polygonal. For example, the orthographic projection of the first auxiliary structure 331 on the base plate 100 may be approximately rectangular or triangular, etc., in which the first auxiliary structure 331 of which the orthographic projection is approximately rectangular may have a better extension size than other shapes, which can facilitate gas discharging. For ease of description, in the following embodiments, for example, the orthographic projection of the first auxiliary structure 331 on the base plate 100 is approximately rectangular.

Optionally, the first auxiliary structure 331 may be arranged extending along a direction from the isolation structure 310 to the second area NA2. For example, the first auxiliary structure 331 may be arranged extending along a direction from the isolation structure 310 to the functional hole H, so as to facilitate gas discharging.

Optionally, the fifth edge B5 may intersect the fourth edge B4. Optionally, the number of the fourth edges B4 and the number of the fifth edges B5 may be two, the two fourth edges B4 may be spaced apart in the direction from the isolation structure 310 to the second area NA2, and the fifth edges B5 may be respectively arranged at both sides of the fourth edge B4.

In some optional embodiments, the first auxiliary structure 331 may be arranged close to the isolation structure 310. Optionally, if the display panel 10 does not include the convex structure 322, the minimum spacing between the first auxiliary structure 331 and the isolation structure 310 may be less than or equal to 20 microns, e.g., less than or equal to 20 microns and greater than or equal to 3 microns, so that the first auxiliary structure 331 may better restrict the delivery of the etching material within the second area NA2 towards the isolation structure 310, thereby better reducing the etching amount of etching material on the material of the isolation structure 310.

Optionally, if the display panel 10 includes the convex structure 322, the minimum spacing between the first auxiliary structure 331 and the convex structure 322 may be less than or equal to 20 microns, e.g., less than or equal to 20 microns and greater than or equal to 3 microns, so that the first auxiliary structure 331 may better restrict the delivery of the etching material within the second area NA2 towards the isolation structure 310 and the convex structure 322, thereby better reducing the etching amount of etching material on the material of the isolation structure 310 and the convex structure 322.

As shown in FIGS. 25 and 28, in some optional embodiments, the display panel 10 further includes a pixel defining layer 200, the pixel defining layer 200 includes a pixel defining portion 210 and a pixel opening 220 enclosed and formed by the pixel defining portion 210, the pixel defining portion 210 is arranged around at least a portion of the first electrode 411, and the orthographic projection of the pixel opening 220 on the base plate 100 is located within the orthographic projection of the isolation opening 310a on the base plate 100.

In these optional embodiments, the first electrode 411 and the isolation structure 310 may be electrically insulated from each other by the pixel defining portion 210, so that the second electrode 431 is less likely to be short circuited with the first electrode 411 through the isolation structure 310, so as to increase the operation stability of the display panel 10.

In some embodiments of the present application, the relative positions between the pixel defining portion 210 and the isolation structure 310, between the pixel defining portion 210 and the convex structure 322, and between the pixel defining portion 210 and the first auxiliary structure 331 may be set in various ways. For example, as shown in FIGS. 28 and 25, the isolation structure 310, the convex structure 322, and the first auxiliary structure 331 may be arranged at a side of the pixel defining portion 210 away from the base plate 100, i.e., the isolation structure 310, the convex structure 322, and the first auxiliary structure 331 may be arranged directly on the pixel defining portion 210. Alternatively, for example, the pixel defining portion 210 may be provided with an accommodation slot, and at least a portion of the isolation structure 310, the convex structure 322, and the first auxiliary structure 331 may be located within the accommodation slot, so that the isolation structure 310, the convex structure 322, and the first auxiliary structure 331 are less likely to have an excessively great height relative to the base plate 100, and thus the thickness of the display panel 10 can be better reduced. For ease of description, in the following embodiments, for example, the isolation structure 310, the convex structure 322, and the first auxiliary structure 331 are arranged at the side of the pixel defining portion 210 away from the base plate 100.

In some embodiments of the present application, when organic material is formed on the isolation structure 310, the convex structure 322, and the first auxiliary structure 331 during the manufacturing of the display panel 10, the convex structure 322 and the first auxiliary structure 331 arranged in the present application may better discharge the gas that is likely to be generated when the organic material is deposited.

For example, reference may be made to the corresponding figures of the method in the following embodiments, the convex structure 322 and the first auxiliary structure 331 arranged in the present application may better discharge the gas at the corresponding position when the photoresist is deposited. Specifically, during the manufacturing of the display panel 10, a pixel defining material layer 11, which may be configured to form the pixel defining layer 200, may be prepared as a whole on the formed first electrode 411, and then the isolation structure 310, the convex structure 322, and the first auxiliary structure 331 may be prepared on the pixel defining material layer 11, in which the whole pixel defining material layer 11 covering the first electrode 411 may better protect the first electrode 411, so that when the materials of the isolation structure 310, the convex structure 322, and the first auxiliary structure 331 are etched, the first electrode 411 is less likely to be damaged by the etching material which is blocked by the pixel defining material layer 11. After the isolation structure 310, the convex structure 322, and the first auxiliary structure 331 are prepared on the pixel defining material layer 11, the pixel defining material layer 11 may be patterned using a photolithographic process to form the pixel defining layer 200 including the pixel defining portion 210 and the pixel opening 220 enclosed and formed by the pixel defining portion 210. Therefore, when a first protective material layer 10a (which may include, for example, the photoresist) is deposited, as a whole along a certain direction, on the pixel defining material layer 11, the isolation structure 310, the convex structure 322, and the first auxiliary structure 331 during the photolithographic process, under the extrusion force of the deposited material of the first protective material layer 10a, the gas between the material of the first protective material layer 10a and the edge of the isolation structure 310 towards the second area NA2, the gas between the material of the first protective material layer 10a and the convex structure 322, and the gas between the material of the first protective material layer 10a and the first auxiliary structure 331 may be discharged outwardly, under the guide of the convex structure 322 and the first auxiliary structure 331, from the edges of the convex structure 322 and the first auxiliary structure 331, thereby better increasing the structure stability of the display panel 10.

Referring to the figures in the above embodiments, the embodiments of the first aspect of the present application further provide a display panel 10 having a first specific area TA and a second area NA2 that are adjacent, the display panel 10 includes: a base plate 100; an isolation structure 310 arranged at one side of the base plate 100 and located in the first specific area TA, the isolation structure 310 enclosing and forming an isolation opening 310a; a convex structure 322 connected with the isolation structure 310 and arranged at a side of the isolation structure 310 towards the second area NA2; and a light-emitting layer 420 including a light-emitting unit 421 arranged within the isolation opening 310a.

The display panel 10 further according to the embodiments of the present application has a first specific area TA and a second area NA2 that are adjacent, and the display panel 10 includes a base plate 100, an isolation structure 310, a convex structure 322, and a light-emitting layer 420. The isolation structure 310 is arranged at one side of the base plate 100 and located in the first specific area TA, the isolation structure 310 encloses and forms an isolation opening 310a, and the isolation structure 310 may be used to divide the sub-pixels of the display panel 10. The light-emitting layer 420 includes a light-emitting unit 421 arranged within the isolation opening 310a, so that the display panel 10 within the first specific area TA may be used to emit light and display. By arranging that the convex structure 322 is connected with the isolation structure 310 and arranged at the side of the isolation structure 310 towards the second area NA2, i.e., by arranging the convex structure 322 protruding towards the second area NA2 at an edge portion of the isolation structure 310, when the isolation structure 310 is etched and prepared, the etching material can also etch the material of the convex structure 322, so as to better reduce the etching amount of the etching material on the material of the isolation structure 310, and thus the isolation structure 310 is less likely to be damaged by over etching, thereby better increasing the structure stability of the display panel 10.

Moreover, when new material is formed on the isolation structure 310 during the manufacturing of the display panel 10, for example, when organic material is formed on the isolation structure 310, the convex structure 322 protruding relative to the isolation structure 310 can also improve the gas discharging path during the formation of the material, so that when the material is deposited on the isolation structure 310 along a certain direction, under the extrusion force of the deposited material, the gas between the material and an edge portion of the isolation structure 310 towards the second area NA2, the gas between the material and the convex structure 322, or the gas between the material and the base plate 100 may be discharged outwardly, under the guide of the convex structure 322, from the edge of the convex structure 322, thereby better increasing the structure stability of the display panel 10.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

For example, the light-emitting layer 420 may be the light-emitting layer 420 in any of the above embodiments, and the display panel 10 may further include the first electrode layer 410 and the second electrode layer 430 in any of the above embodiments. For example, the isolation structure 310 may be the isolation structure 310 in any of the above embodiments, and the isolation structure 310 may include the first isolation portion 311 and the second isolation portion 312 in any of the above embodiments, so that the isolation structure 310 may be configured to separate the material of the light-emitting layer 420 when preparing the light-emitting layer 420, so as to divide sub-pixels. For example, the convex structure 322 may be the convex structure 322 in any of the above embodiments, so as to increase the ability of the convex structure 322 for guiding and discharging gas.

Optionally, the display panel 10 further according to the embodiments of the present application may not include the first auxiliary structure 331 in any of the above embodiments, or the display panel 10 may include the first auxiliary structure 331 in any of the above embodiments, which is not limited in the present application. If the display panel 10 includes the first auxiliary structure 331 in any of the above embodiments, the first auxiliary structure 331 may be arranged at a side of the convex structure 322 away from the isolation structure 310 and located within the second area NA2.

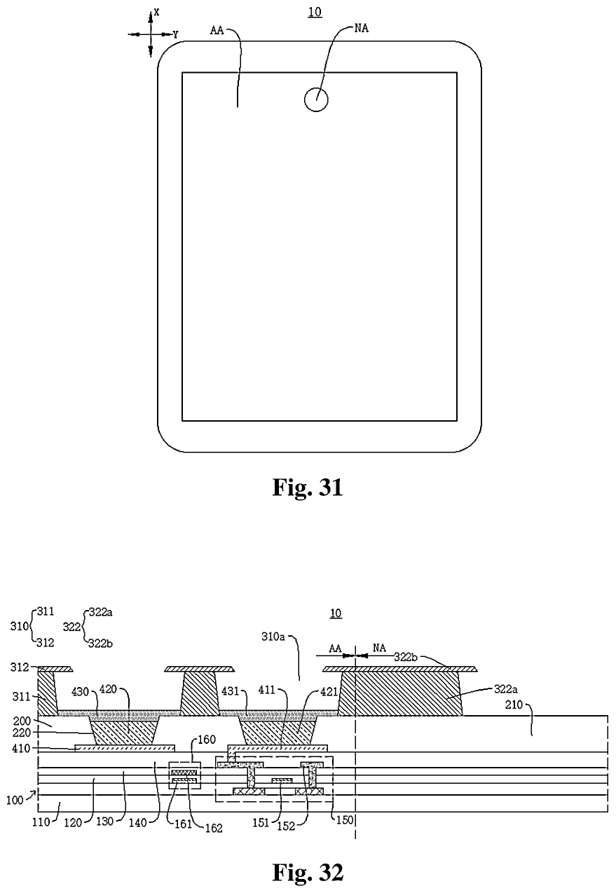

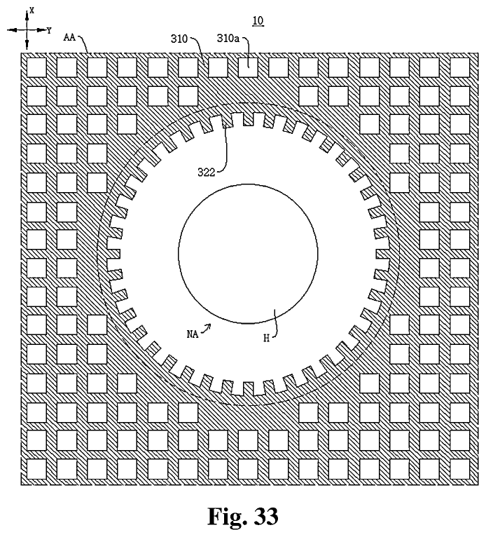

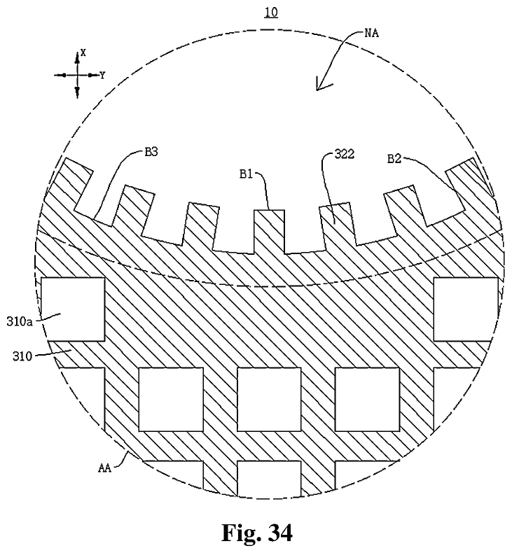

FIG. 31 shows a schematic structural diagram of the display panel 10 according to yet another embodiment of the present application, FIG. 32 shows a partial sectional view of the display panel 10 according to yet another embodiment of the present application, FIG. 33 shows a partial schematic diagram of the display panel 10 according to yet another embodiment of the present application, and FIG. 34 shows a partially enlarged schematic diagram of an orthographic projection of the isolation structure 310 and the convex structure 322 on the base plate 100 according to an embodiment of the present application.

As shown in FIGS. 31 to 34, the embodiments of the first aspect of the present application further provide a display panel 10 having a display area AA and a non-display area NA that are adjacent, the display panel 10 includes: a base plate 100; an isolation structure 310 arranged at one side of the base plate 100 and enclosing and forming an isolation opening 310a; a plurality of convex structures 322 spaced apart from each other and connected to an edge portion of the isolation structure 310 away from the display area AA; and a light-emitting layer 420 located in the display area AA and including a light-emitting unit 421 arranged within the isolation opening 310a.

The display panel 10 according to the embodiments of the present application has a display area AA and a non-display area NA that are adjacent, and the display panel 10 includes a base plate 100, an isolation structure 310, a plurality of convex structures 322, and a light-emitting layer 420. The isolation structure 310 is arranged at one side of the base plate 100 and encloses and forms an isolation opening 310a, and the isolation structure 310 may be used to divide the sub-pixels of the display panel 10. The light-emitting layer 420 is located in the display area AA and includes a light-emitting unit 421 arranged within the isolation opening 310a, so that the display panel 10 within the display area AA may be used to emit light and display. By arranging that a plurality of convex structures 322, which are spaced apart, are connected with the isolation structure 310 and arranged at a side of the isolation structure 310 away from the display area AA, when new material is formed on the isolation structure 310 during the manufacturing of the display panel 10, for example, when organic material is formed on the isolation structure 310, the convex structure 322 protruding relative to the isolation structure 310 can improve the gas discharging path during the formation of the material, so that when the material is deposited on the isolation structure 310 along a certain direction, under the extrusion force of the deposited material, the gas between the material and an edge portion of the isolation structure 310 away from the display area AA, the gas between the material and the convex structure 322, or the gas between the material and the base plate 100 may be discharged outwardly, under the guide of the convex structure 322, from the edge of the convex structure 322, for example, the gas may be better discharged outwardly from the spacing between the adjacent convex structures 322, thereby better increasing the structure stability and processing reliability of the display panel 10.

Moreover, by arranging the convex structure 322, which is protruding, at the edge portion of the isolation structure 310, when the isolation structure 310 is etched and prepared, the etching material can also etch the material of the convex structure 322, so that the convex structure 322 may better restrict the delivery of the etching material towards the isolation structure 310 to better reduce the etching amount of the etching material on the material of the isolation structure 310, and thus the isolation structure 310 is less likely to be damaged by over etching, thereby better increasing the structure stability of the display panel 10.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

Optionally, the non-display area NA may include the first area NA1 and the second area NA2 in any of the above embodiments.

In some embodiments of the present application, the isolation structure 310 is at least partially located in the display area AA, and at least a portion of the isolation opening 310a on the isolation structure 310 is located in the display area AA, so that the light-emitting unit 421 within the isolation opening 310a may participate in the light emitting and display of the display area AA in the display panel 10. Herein, a portion of the isolation structure 310 may be located in the display area AA, the other portion of the isolation structure 310 may be located in the non-display area NA, and the convex structure 322 may be located in the non-display area NA. The convex structure 322 being connected to an edge portion of the isolation structure 310 away from the display area AA may mean that the convex structure 322 may be connected to the side of a portion of the isolation structure 310 located in the non-display area NA away from a portion of the isolation structure 310 located in the display area AA.

Optionally, at least a portion of the isolation structure 310 located in the non-display area NA may be reused as the main structure 321 in any of the above embodiments. For example, the isolation structure 310 located in the display area AA in the display panel 10 further according to the embodiments of the first aspect of the present application may be the isolation structure 310 in any of the above embodiments, and the isolation structure 310 located in the non-display area NA may be reused as the main structure 321 in any of the located embodiments.

Optionally, at least a portion of the non-display area NA of the display panel 10 may be used as a functional area of the display panel 10, e.g., the light transmittance of at least a portion of the non-display area NA may be greater than the light transmittance of the display area AA. When the display panel 10 is applied to a display apparatus, the photosensitive assembly for sensing light in the display apparatus may be correspondingly arranged under the non-display area NA with a greater light transmittance, and the photosensitive assembly may better sense light through the non-display area NA with a greater light transmittance, in which the photosensitive assembly may include at least one of: a distance sensor, a camera, an under-screen fingerprint recognition module, an infrared light emitting diode, a proximity sensor, or other components capable of sensing light. Alternatively, at least a portion of the non-display area NA of the display panel 10 may be used as a frame area of the display panel 10.

For ease of description, in the following embodiments, for example, the non-display area NA is used as a functional area of the display panel 10. Optionally, the display panel 10 is provided with a functional hole H in the non-display area NA, so that if a photosensitive assembly is correspondingly arranged at the non-display area NA, the photosensitive assembly may better sense light through the functional hole H.

Optionally, the isolation structure 310 and the convex structure 322 may be arranged around at least a portion of the functional hole H. For example, a plurality of convex structures 322 may be connected with the isolation structure 310 and spaced apart at the periphery of the functional hole H, so that the arrangement of the isolation structure 310 and the convex structure 322 is less likely to affect the light transmittance at the functional hole H and can facilitate the outwardly discharging of gas from the edge of the convex structure 322 towards the functional hole H.

In some embodiments of the present application, the isolation structure 310 may be configured to separate the material of the light-emitting layer 420 when preparing the light-emitting layer 420, so as to divide sub-pixels. Herein, the shape of the isolation structure 310 may be set in various ways and may be any of the shapes capable of blocking and separating the material of the light-emitting layer 420 within the adjacent isolation openings 310a.

In some optional embodiments, the isolation structure 310 includes a first isolation portion 311 and a second isolation portion 312 located at a side of the first isolation portion 311 away from the base plate 100, and the second isolation portion 312 is arranged protruding from the first isolation portion 311 towards the isolation opening 310a.

By arranging that the second isolation portion 312 is arranged protruding from the first isolation portion 311 towards the isolation opening 310a, when vapor depositing the light-emitting layer 420 of the display panel 10, the second isolation portion 312 can block at least a portion of the material for preparing the light-emitting layer 420 to separate the light-emitting layer 420 between adjacent sub-pixels, and also facilitate forming a plurality of light-emitting units 421 that are spaced apart. Therefore, no fine mask is needed when vapor depositing the light-emitting layer 420 of the display panel 10, for example, no fine metal mask is needed when vapor depositing the light-emitting layer 420, thereby better reducing the production and preparation costs of the display panel 10.

Optionally, the second isolation portion 312 may be further arranged protruding from the first isolation portion 311 towards the functional hole H. For example, the second isolation portion 312 located on the isolation structure 310 between the adjacent convex structures 322 may be further arranged protruding from the first isolation portion 311 towards the functional hole H.

In some optional embodiments, the convex structure 322 may include a first convex portion 322a which is integrally prepared with the first isolation portion 311, or the convex structure 322 may include a second convex portion 322b which is integrally prepared with the second isolation portion 312, so that at least a portion of the convex structure 322 and the isolation structure 310 may be prepared in the same preparation process, so as to increase the manufacturing efficiency of the display panel 10.

In some optional embodiments, the shape of the convex structure 322 may be similar to the shape of the isolation structure 310. Optionally, the convex structure 322 may include a first convex portion 322a and a second convex portion 322b which may be arranged protruding from the first convex portion 322a towards a side away from the isolation structure 310, for example, the second convex portion 322b is arranged protruding from the first convex portion 322a towards the functional hole H. Herein, when the material of the isolation structure 310 is etched using an etching material, the etching material may also etch the convex structure 322, which can reduce the etching amount of the etching material on the material of the isolation structure 310, and also obtain, in the convex structure 322, the shape in which the second convex portion 322b protrudes from the first convex portion 322a towards a side away from the isolation structure 310.

As shown in FIGS. 33 and 34, in these optional embodiments, by arranging the convex structure 322, which is protruding, at an edge portion of the isolation structure 310 away from the display area AA, when the material of the isolation structure 310 is etched to prepare the first isolation portion 311 and the second isolation portion 312, the etching material located at the edge portion of the isolation structure 310 away from the display area AA can also etch the material of the convex structure 322, so as to better reduce the etching amount of the etching material on the material of the isolation structure 310, and thus the isolation structure 310 is less likely to be damaged by over etching, thereby better increasing the structure stability of the display panel 10.

In some embodiments of the present application, the shape of the convex structure 322 may be set in various ways and may be a shape which facilitates gas discharging when material is formed on the convex structure 322.

In some optional embodiments, the orthographic projection of the convex structure 322 on the base plate 100 has a first edge B1 and a second edge B2 which may intersect with each other. For example, the first edge B1 and the second edge B2 may be perpendicular to each other.

In these optional embodiments, by arranging that the first edge B1 intersects the second edge B2, when material is deposited on the isolation structure 310 and the convex structure 322 along a certain direction, for example, when material is deposited on the isolation structure 310 and the convex structure 322 along any of the first direction X, the second direction Y, the circumferential direction of the functional hole H, or the radial direction of the functional hole H, if one of the first edge B1 and the second edge B2 cannot well fit the depositing direction of the material, the other one of the first edge B1 and the second edge B2 may well fit the depositing direction of the material. For example, if one of the first edge B1 and the second edge B2 is perpendicular to the depositing direction of the material, the angle between the other one of the first edge B1 and the second edge B2 and the depositing direction of the material may be less than 90 degrees, so that when material is deposited on the isolation structure 310 and the convex structure 322 along a certain direction, under the extrusion force of the deposited material, the gas between the material and the edge portion of the isolation structure 310 away from the display area AA or the gas between the material and the convex structure 322 may be better discharged outwardly under the guide of at least one of the first edge B1 and the second edge B2, thereby better increasing the structural stability of the display panel 10.

Optionally, the first edge B1 intersecting the second edge B2 may mean that the first edge B1 and the second edge B2 may be straight edges and intersect with each other, so as to enhance gas guiding effect of the edge portion of the convex structure 322, which can facilitate gas discharging. Optionally, a curved edge (not shown) may be connected between the first edge B1 and the second edge B2 for transition.

In some optional embodiments, the orthographic projection of the convex structure 322 on the base plate 100 may be approximately polygonal. For example, the orthographic projection of the convex structure 322 on the base plate 100 may be approximately rectangular or triangular, etc., in which the convex structure 322 of which the orthographic projection is approximately rectangular may have a better extension size than other shapes, which can facilitate gas discharging. For ease of description, in the following embodiments, for example, the orthographic projection of the convex structure 322 on the base plate 100 is approximately rectangular.

Optionally, the first edge B1 is located at a side of the second edge B2 away from the isolation structure 310, and the second edges B2 are arranged at both sides of the first edge B1.

In some optional embodiments, the side of the orthographic projection of the isolation structure 310 on the base plate 100 towards the convex structure 322 has a third edge B3, and the second edge B2 intersects the third edge B3.

Optionally, the second edge B2 is connected between the first edge B1 and the third edge B3, and the second edge B2 is perpendicular to the third edge B3.

Optionally, the second edge B2 intersecting the third edge B3 may mean that the second edge B2 and the third edge B3 may be straight edges and intersect with each other. Optionally, a curved edge (not shown) may be connected between the third edge B3 and the second edge B2 for transition.

In these optional embodiments, by arranging that the second edge B2 intersects the third edge B3, when material is deposited on the isolation structure 310 and the convex structure 322 along a certain direction, if the third edge B3 cannot well fit the depositing direction of the material, the second edge B2 may well fit the depositing direction of the material. For example, if the third edge B3 is perpendicular to the depositing direction of the material, the angle between the second edge B2, which intersects the third edge B3, and the depositing direction of the material may be less than 90 degrees, so that when material is deposited on the isolation structure 310 and the convex structure 322 along a certain direction, under the extrusion force of the deposited material, the gas between the material and the edge portion of the isolation structure 310 away from the display area AA or the gas between the material and the convex structure 322 may be better discharged outwardly under the guide of the second edge B2, thereby better increasing the structural stability of the display panel 10.

In some embodiments of the present application, the extension manner of the convex structure 322 connected to the edge portion of the isolation structure 310 may be set in various ways, i.e., the protruding orientation of the convex structure 322 relative to the isolation structure 310 may be set in various ways, and the extension manner of the convex structure 322 may be set according to the direction in which material is deposited on the isolation structure 310 and the convex structure 322.

As shown in FIGS. 33 and 34, in some optional embodiments, the convex structure 322 may be formed extending along a direction from the isolation structure 310 to the center of circle of the functional hole H, so that when material is deposited on the isolation structure 310 and the convex structure 322 along the circumferential direction or radial direction of the functional hole H, the edge of the convex structure 322 may better guide the gas, so as to facilitate gas discharging at the isolation structure 310 and the upper edge of the convex structure 322. Specifically, when the material is deposited on the isolation structure 310 and the convex structure 322 along the circumferential direction of the functional hole H, under the extrusion force of the deposited material, the gas may be better discharged outwardly along the first edge B1 which forms an angle less than 90 degrees with the circumferential direction of the functional holes H. Moreover, when the material is deposited on the isolation structure 310 and the convex structure 322 along the radial direction of the functional hole H, under the extrusion force of the deposited material, the gas may be better discharged outwardly along the second edge B2 which forms an angle less than 90 degrees with the radial direction of the functional holes H.

In these optional embodiments, optionally, the convex structures 322 may be arranged symmetrically about at least one virtual line extending along the radial direction of the functional hole H, so as to facilitate outwardly discharging of gas, under the guide of the convex structures 322, along the circumferential direction or radial direction of the functional hole H.

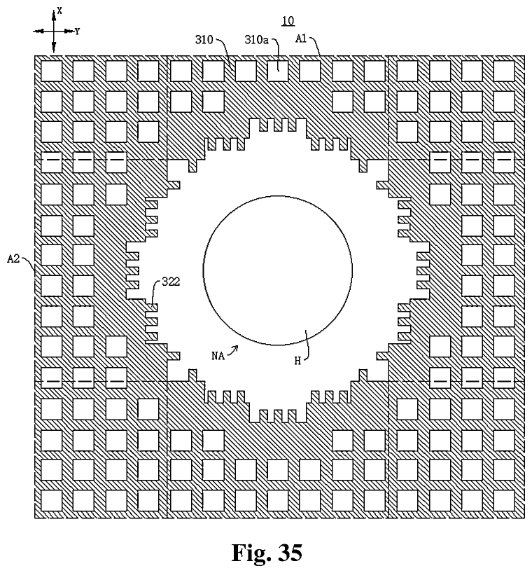

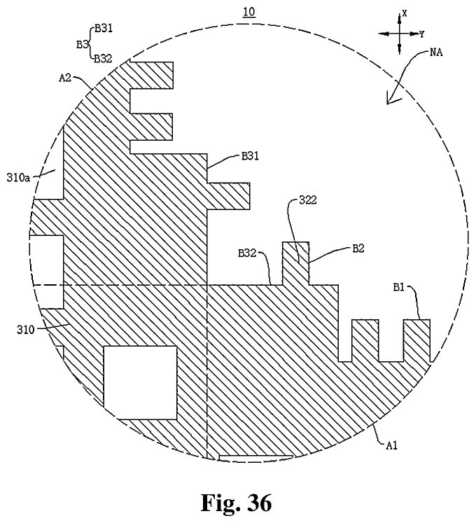

FIG. 35 shows a partial schematic diagram of the display panel 10 according to yet another embodiment of the present application, and FIG. 36 shows a partially enlarged schematic diagram of an orthographic projection of the isolation structure 310 and the convex structure 322 on the base plate 100 according to another embodiment of the present application.

As shown in FIGS. 35 and 36, in some other optional embodiments, the isolation structure 310 may include a first isolation area A1 located at least one side of the functional hole H in the first direction X, and the second edge B2 of the convex structure 322 connected with the isolation structure 310 located in the first isolation area A1 extends along the first direction X, or the isolation structure 310 includes a second isolation area A2 located at least one side of the functional hole H in the second direction Y, and the second edge B2 of the convex structure 322 connected with the isolation structure 310 located in the second isolation area A2 extends along the second direction Y.

In these optional embodiments, the convex structure 322 connected with the isolation structure 310 located in the first isolation area A1 may be formed extending along the first direction X. By arranging that the second edge B2 of the convex structure 322 connected with the isolation structure 310 located in the first isolation area A1 extends along the first direction X, when material is deposited on the isolation structure 310 and the convex structure 322 along the first direction X, the second edge B2 on the convex structure 322 extending along the first direction X may better guide the gas, so as to facilitate gas discharging at the isolation structure 310 and the upper edge of the convex structure 322. The convex structure 322 connected with the isolation structure 310 located in the second isolation area A2 may be formed extending along the second direction Y. By arranging that the second edge B2 of the convex structure 322 connected with the isolation structure 310 located in the second isolation area A2 extends along the second direction Y, when material is deposited on the isolation structure 310 and the convex structure 322 along the second direction Y, the second edge B2 on the convex structure 322 extending along second direction Y may better guide the gas, so as to facilitate gas discharging at the edge portion of the isolation structure 310 away from the display area AA and the upper edge of the convex structure 322.

Optionally, the first edge B1 of the convex structure 322 connected with the isolation structure 310 located in the first isolation area A1 may extend along the second direction Y, when material is deposited on the isolation structure 310 and the convex structure 322 along the second direction Y, the first edge B1 on the convex structure 322 extending along the second direction Y may better guide the gas, so as to facilitate gas discharging at the edge portion of the isolation structure 310 away from the display area AA and the upper edge of the convex structure 322.

Optionally, the convex structure 322 connected with the isolation structure 310 located in the first isolation area A1 may be arranged protruding from the isolation structure 310 of the first isolation area A1 in the second direction Y. For example, the convex structure 322 connected with the isolation structure 310 located in the first isolation area A1 may be arranged protruding, along the second direction Y, from the isolation structure 310 of the first isolation area A1 towards the functional hole H.

Optionally, the first edge B1 of the convex structure 322 connected with the isolation structure 310 located in the second isolation area A2 may extend along the first direction X, when material is deposited on the isolation structure 310 and the convex structure 322 along the first direction X, the first edge B1 on the convex structure 322 extending along the first direction X may better guide the gas, so as to facilitate gas discharging at the edge portion of the isolation structure 310 away from the display area AA and the upper edge of the convex structure 322.

Optionally, the convex structure 322 connected with the isolation structure 310 located in the second isolation area A2 may be arranged protruding from the isolation structure 310 of the second isolation area A2 in the first direction X. For example, the convex structure 322 connected with the isolation structure 310 located in the second isolation area A2 may be arranged protruding, along the first direction X, from the isolation structure 310 of the second isolation area A2 towards the functional hole H.

Optionally, the third edge B3 includes a first sub-edge B31 and a second sub-edge B32 connected to each other, the first sub-edge B31 extends along the first direction X, and the second sub-edge B32 extends along the second direction Y. The convex structure 322 located in the first isolation area A1 is connected to a side of the second sub-edge B32 towards the functional hole H, or the convex structure 322 located in the second isolation area A2 is connected to a side of the first sub-edge B31 towards the functional hole H.

By arranging the first sub-edge B31 extending along the first direction X, when material is deposited on the isolation structure 310 and the convex structure 322 along the first direction X, the first sub-edge B31 on the isolation structure 310 extending along the first direction X may better guide the gas, so as to facilitate gas discharging at the edge portion of the isolation structure 310 away from the display area AA and the upper edge of the convex structure 322. By arranging the second sub-edge B32 extending along the second direction Y, when material is deposited on the isolation structure 310 and the convex structure 322 along the second direction Y, the second sub-edge B32 on the isolation structure 310 extending along the second direction Y may better guide the gas, so as to facilitate gas discharging at the edge portion of the isolation structure 310 away from the display area AA and the upper edge of the convex structure 322. Moreover, by arranging that the convex structure 322 located in the first isolation area A1 is connected to the side of the second sub-edge B32 towards the functional hole H, and the convex structure 322 located in the second isolation area A2 is connected to the side of the first sub-edge B31 towards the functional hole H, the raising degree of the convex structure 322 relative to the isolation structure 310 is increased, so as to enhance the gas guiding and discharging effect of the convex structure 322.

In these optional embodiments, the specific sizes of the first isolation area A1 and the second isolation area A2 may be set according to the shape of the non-display area NA. Herein, the area of the orthographic projection of the first isolation area A1 on the base plate 100 may be equal to the area of the orthographic projection of the second isolation area A2 on the base plate 100, or the area of the orthographic projection of the first isolation area A1 on the base plate 100 may be greater or less than the area of the orthographic projection of the second isolation area A2 on the base plate 100, which is not limited in the present application.

Optionally, if the extension size of the non-display area NA in the first direction X is greater than the extension size of the non-display area NA in the second direction Y, the extension size of the first isolation area A1 in the second direction Y may be less than the extension size of the second isolation area A2 in the first direction X. Optionally, if the extension size of the non-display area NA in the second direction Y is greater than the extension size of the non-display area NA in the first direction X, the extension size of the first isolation area A1 in the second direction Y may be greater than the extension size of the second isolation area A2 in the first direction X.

Optionally, there may be two first isolation areas A1 which may be respectively arranged at both sides of the functional hole H in the first direction X. For the two first isolation areas A1, the convex structure 322 connected with the isolation structure 310 within any one of the first isolation areas A1 may be arranged protruding towards the other one of the first isolation areas A1. Herein, the orthographic projections of the two first isolation areas A1 on the base plate 100 may be of the same or different areas, which is not limited in the present application. Optionally, the extension sizes of the two first isolation areas A1, which are opposing to each other, in the second direction Y may be the same.

Optionally, there may be two second isolation areas A2 which may be respectively arranged at both sides of the functional hole H in the second direction Y. For the two second isolation areas A2, the convex structure 322 connected with the isolation structure 310 within any one of the second isolation areas A2 may be arranged protruding towards the other one of the second isolation areas A2. Herein, the orthographic projections of the two second isolation areas A2 on the base plate 100 may be of the same or different areas, which is not limited in the present application. Optionally, the extension sizes of the two second isolation areas A2, which are opposing to each other, in the first direction X may be the same.

In some optional embodiments, the length of the second edge B2 may be greater than the length of the first edge B1, so that the convex structure 322 may have a greater raising degree relative to the isolation structure 310, and gas may be better directed away from the isolation structure 310 under the guiding effect of the second edge B2, so as to reduce the influence of the gas on the isolation structure 310, thereby better increasing the structure stability of the display panel 10.

Optionally, the length of the first edge B1 is greater than or equal to 5 microns and less than or equal to 300 microns, or the length of the second edge B2 is greater than or equal to 5 microns and less than or equal to 300 microns. By reasonably setting the lengths of the first edge B1 and the second edge B2, the first edge B1 and the second edge B2 will not have excessively large sizes, that is, the gas will not have an excessively large discharging path when moving along the first edge B1 and the second edge B2, so as to facilitate the gas to be discharged outwardly along the first edge B1 and the second edge B2, and also the first edge B1 and the second edge B2 will not have excessively small sizes, so as to better enhance gas guiding effect of the convex structure 322. For example, the length of the first edge B1 may be at least one of 60 microns, 120 microns, 180 microns, 240 microns, 300 microns, and the length of the second edge B2 may be at least one of 50 microns, 100 microns, 150 microns, 200 microns, 250 microns.

Optionally, the minimum spacing between adjacent convex structures 322 is greater than or equal to 5 microns and less than or equal to 300 microns. By reasonably setting the minimum spacing between adjacent convex structures 322, the adjacent convex structures 322 will not form an excessively large spacing, so that the gas on the edge portion of the isolation structure 310 between the adjacent convex structures 322 may be more easily moved to the edge of the convex structures 322, and thus gas is less likely to be excessively retained at the edge portion of the isolation structure 310 between the adjacent convex structures 322, so as to facilitate the gas to be discharged outwardly through the convex structure 322, and also the adjacent convex structures 322 will not form an excessively small spacing, so that gas is less likely to be retained between the isolation structure 310 and the adjacent convex structures 322. For example, the minimum spacing between adjacent convex structures 322 may be at least one of 50 microns, 100 microns, 150 microns, 200 microns, 250 microns, 300 microns.

As shown in FIG. 33, in some optional embodiments, the pixel defining layer 200 includes a pixel defining portion 210 and a pixel opening 220 enclosed and formed by the pixel defining portion 210, the pixel defining portion 210 is arranged around at least a portion of the first electrode 411, and the orthographic projection of the pixel opening 220 on the base plate 100 is located within the orthographic projection of the isolation opening 310a on the base plate 100.

In these optional embodiments, the first electrode 411 and the isolation structure 310 may be electrically insulated from each other by the pixel defining portion 210, so that the second electrode 431 is less likely to be short circuited with the first electrode 411 through the isolation structure 310, so as to increase the operation stability of the display panel 10.

In some embodiments of the present application, the relative positions between the pixel defining portion 210 and the isolation structure 310 and between the pixel defining portion 210 and the convex structure 322 may be set in various ways. For example, the isolation structure 310 and the convex structure 322 may be arranged at a side of the pixel defining portion 210 away from the base plate 100, i.e., the isolation structure 310 and the convex structure 322 may be arranged directly on the pixel defining portion 210. Alternatively, for example, the pixel defining portion 210 may be provided with an accommodation slot, and at least a portion of the isolation structure 310 and the convex structure 322 may be located within the accommodation slot, so that the isolation structure 310 and the convex structure 322 are less likely to have an excessively great height relative to the base plate 100, and thus the thickness of the display panel 10 can be better reduced. For ease of description, in the following embodiments, for example, the isolation structure 310 and the convex structure 322 are arranged at the side of the pixel defining portion 210 away from the base plate 100.

In some embodiments of the present application, when organic material is formed on the isolation structure 310 and the convex structure 322 during the manufacturing of the display panel 10, the convex structure 322 arranged in the present application may better discharge the gas that is likely to be generated when the organic material is deposited.

For example, reference may be made to the corresponding figures of the method in the following embodiments, the convex structure 322 arranged in the present application may better discharge the gas at the corresponding position when the photoresist is deposited. Specifically, during the manufacturing of the display panel 10, a pixel defining material layer 11, which may be configured to form the pixel defining layer 200, may be prepared as a whole on the formed first electrode 411, and then the isolation structure 310 and the convex structure 322 may be prepared on the pixel defining material layer 11, in which the whole pixel defining material layer 11 covering the first electrode 411 may better protect the first electrode 411, so that when the materials of the isolation structure 310 and the convex structure 322 are etched, the first electrode 411 is less likely to be damaged by the etching material which is blocked by the pixel defining material layer 11. After the isolation structure 310 and the convex structure 322 are prepared on the pixel defining material layer 11, the pixel defining material layer 11 may be patterned using a photolithographic process to form the pixel defining layer 200 including the pixel defining portion 210 and the pixel opening 220 enclosed and formed by the pixel defining portion 210. Therefore, when a first protective material layer 10a (which may include, for example, the photoresist) is deposited, as a whole along a certain direction, on the pixel defining material layer 11, the isolation structure 310, and the convex structure 322 during the photolithographic process, under the extrusion force of the deposited material of the first protective material layer 10a, the gas between the material of the first protective material layer 10a and the edge portion of the isolation structure 310 away from the display area AA and the gas between the material of the first protective material layer 10a and the convex structure 322 may be discharged outwardly, under the guide of the convex structure 322, from the edge of the convex structure 322, thereby better increasing the structure stability of the display panel 10.

The embodiments of the first aspect of the present application further provide a display panel 10 provided with a functional hole H, the display panel 10 includes: a base plate 100; an isolation structure 310 arranged at one side of the base plate 100 and around at least a portion of the functional hole H, the isolation structure 310 enclosing and forming an isolation opening 310a; a convex structure 322 connected with a side of the isolation structure 310 towards the functional hole H; and a light-emitting layer 420 including a light-emitting unit 421 arranged within the isolation opening 310a.

Referring to FIGS. 31 to 35, the display panel 10 further according to the embodiments of the present application is provided with a functional hole H to enhance the light transmission performance of the display panel 10. When the display panel 10 is applied to a display apparatus, the photosensitive assembly for sensing light in the display apparatus may be correspondingly arranged at the functional hole H, and thus the photosensitive assembly can better sense light through the functional hole H. Herein, the photosensitive assembly may include: a distance sensor, a camera, an under-screen fingerprint recognition module, an infrared light emitting diode, a proximity sensor, and the like.

The display panel 10 includes a base plate 100, an isolation structure 310, a convex structure 322, and a light-emitting layer 420. The isolation structure 310 is arranged at one side of the base plate 100 and encloses and forms an isolation opening 310a, and the isolation structure 310 may be used to divide the sub-pixels of the display panel 10. The light-emitting layer 420 includes a light-emitting unit 421 arranged within the isolation opening 310a, so that the display panel 10 may be used to emit light and display. By arranging that the convex structure 322 is connected with the isolation structure 310 and arranged at a side of the isolation structure 310 towards the functional hole H, when new material is formed on the isolation structure 310 during the manufacturing of the display panel 10, for example, when organic material is formed on the isolation structure 310, the convex structure 322 protruding relative to the isolation structure 310 can improve the gas discharging path during the formation of the material, so that when the material is deposited on the isolation structure 310 along a certain direction, under the extrusion force of the deposited material, the gas between the material and an edge portion of the isolation structure 310 away from the display area AA, the gas between the material and the convex structure 322, or the gas between the material and the base plate 100 may be discharged outwardly, under the guide of the convex structure 322, from the edge of the convex structure 322, thereby better increasing the structure stability of the display panel 10.

Moreover, by arranging the convex structure 322, which is protruding, at the edge portion of the isolation structure 310, when the isolation structure 310 is etched and prepared, the etching material close to the functional hole H can also etch the material of the convex structure 322, so that the convex structure 322 may better restrict the delivery of the etching material towards the isolation structure 310 to better reduce the etching amount of the etching material on the material of the isolation structure 310, and thus the isolation structure 310 is less likely to be damaged by over etching, thereby better increasing the structure stability of the display panel 10.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

For example, the base plate 100 may be the base plate 100 in any of the above embodiments. For example, the light-emitting layer 420 may be the light-emitting layer 420 in any of the above embodiments, and the display panel 10 may further include the first electrode layer 410 and the second electrode layer 430 in any of the above embodiments. For example, the isolation structure 310 may be the isolation structure 310 in any of the above embodiments, and the isolation structure 310 may include the first isolation portion 311 and the second isolation portion 312 in any of the above embodiments, so that the isolation structure 310 may be configured to separate the material of the light-emitting layer 420 when preparing the light-emitting layer 420, so as to divide sub-pixels. For example, the convex structure 322 may be the convex structure 322 in any of the above embodiments, so as to increase the ability of the convex structure 322 for guiding and discharging gas.

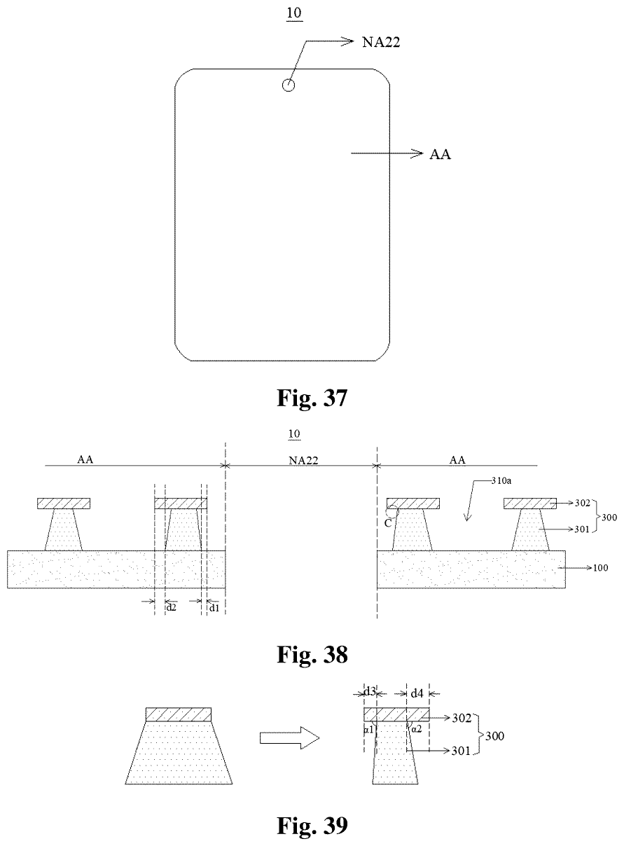

Referring to FIGS. 37 and 38, in which FIG. 37 shows a schematic diagram of a distribution of various areas of a display panel according to an embodiment of the present application, and FIG. 38 shows a schematic structural diagram of a portion of film layers of a display panel according to an embodiment of the present application.

The embodiments of the first aspect of the present application further provide a display panel 10, and in the embodiments, the display panel 10 includes a second sub-area NA22 and a display area AA at least partially surrounding the second sub-area NA22, the light transmittance of the second sub-area NA22 is greater than the light transmittance of the display area AA, and the shape of the second sub-area NA22 may be a circle, a rectangle, and a teardrop, etc., which is not limited in the embodiments.

The display panel 10 includes a base plate 100 and an isolation structure layer 300 located on one side of the base plate 100 and enclosing and forming an isolation opening 310a on the base plate 100 corresponding to the display area AA. In a direction away from the base plate 100, the isolation structure layer 300 includes a first isolation layer 301 and a second isolation material layer 302 that are stacked, in which an orthographic projection of the first isolation layer 301 on the base plate 100 is located within an orthographic projection of the second isolation material layer 302 on the base plate 100.

In the embodiments, in order to disconnect the light-emitting material layer and the cathode layer between adjacent isolation openings 310a at the isolation structure, the second isolation material layer 302 needs to protrude relative to the first isolation layer 301 towards the isolation opening 310a, so as to form an undercut structure (Undercut) which can disconnect the vapor deposited light-emitting material layer and cathode layer at the isolation structure layer 300. Similarly, an undercut structure is also formed at a side of the second isolation material layer 302 towards the second sub-area NA22, and since the area of the second sub-area NA22 is much greater than the area of the isolation opening 310a, when the photoresist layer is deposited, the air between the photoresist layer and the underlying film layer may spread from the center of the aperture area to the periphery of the aperture area and accumulate at the isolation structure layer 300 at the periphery of the aperture area, and specifically, the accumulated air may gather in a concave area C (at the dotted line circle in the figures) formed at the junction position between the first isolation layer 301 and the second isolation material layer 302. The inventors have found that the greater the concave depth of the concave area C, the easier the air accumulating, which is unbeneficial for the air to be released along the gap between the optical adhesive and the isolation structure layer 300.

In the embodiments, in the isolation structure layer 300 surrounding the second sub-area NA22, a protrusion length d1 of a side of the second isolation material layer 302 towards the second sub-area NA22 relative to the first isolation layer 301 is less than a protrusion length d2 of a side of the second isolation material layer 302 away from the second sub-area NA22 relative to the first isolation layer 301. Herein, the protrusion length of the second isolation material layer 302 relative to the first isolation layer 301 refers to a protrusion length of an orthographic projection of the second isolation material layer 302 on the base plate 100 relative to an orthographic projection of the first isolation layer 301 on the base plate 100. For example, the protrusion length d1 of the side of the second isolation material layer 302 towards the second sub-area NA22 relative to the first isolation layer 301 refers to the protrusion length, in the direction towards the second sub-area NA22, of the orthographic projection of the second isolation material layer 302 on the base plate 100 relative to the orthographic projection of the first isolation layer 301 on the base plate 100.

With the above configuration, while it is ensured that the undercut structure at the side of the isolation structure layer 300 away from the second sub-area NA22 can separate the vapor deposited light-emitting material layer and cathode layer, a concave area C with less concave depth may be formed at the side of the isolation structure layer 300 close to the second sub-area NA22, which facilitates releasing the air accumulated in the second sub-area NA22, when the photoresist layer is deposited, along the gap between the optical adhesive and the isolation structure, and reducing the air accumulation at the concave area C, and thus no great air pressure is formed and the display effect of the display panel 10 is ensured.

Reference is made to patent applications No. PCT/CN2023/134518, 202310759370.2, 202310740412.8, 202310707209.0, and 202311346196.5 for the relevant technical solutions of the isolation structure layer 300 in the present application.

Optionally, the display panel 10 further according to the embodiments of the first aspect of the present application may be the display panel 10 in any of the above embodiments, and thus the display panel 10 further according to the embodiments of the present application may have the beneficial effects of the display panel 10 in any of the above embodiments, which will not be repeated herein.

In the embodiments, referring to FIG. 39, the above shape of the isolation structure layer 300 may be achieved by controlling the lateral side etching depth of the first isolation layer 301. As shown in FIG. 39, the cross-section of the isolation structure layer 300 is a trapezoid in shape prior to the lateral side etching, and by controlling the lateral side etching depths of the first isolation layer 301 located at the two waists of the trapezoid, the lateral side etching depth of a side of the first isolation layer 301 away from the second sub-area NA22 is greater than the lateral side etching depth of a side of the first isolation layer 301 towards the second sub-area NA22. In other words, as shown in FIG. 39, at the junction position between the first isolation layer 301 and the second isolation material layer 302, the concave depth of the first isolation layer 301 relative to the second isolation material layer 302 is d4 at the side away from the second sub-area NA22, and the concave depth of the first isolation layer 301 relative to the second isolation material layer 302 is d3 at the side towards the second sub-area NA22, in which the concave depth d4 is greater than the concave depth d3.

Optionally, the concave depth d4 may be the first spacing S1 in any of the above embodiments, and the concave depth d3 may be the second spacing S2 in any of the above embodiments.

Further, in the embodiments, at a position close to the second sub-area NA22, an angle between a surface of the second isolation material layer 302 towards the base plate 100 and a surface of the first isolation layer 301 towards the second sub-area NA22 is α1, and an angle between the surface of the second isolation material layer 302 towards the base plate 100 and a surface of the first isolation layer 301 away from the second sub-area NA22 is α2, in which the angle α1 is less than the angle α2. The greater the above angle, the more beneficial to the release of air along the gap between the photoresist layer and the surface of the isolation structure layer 300.

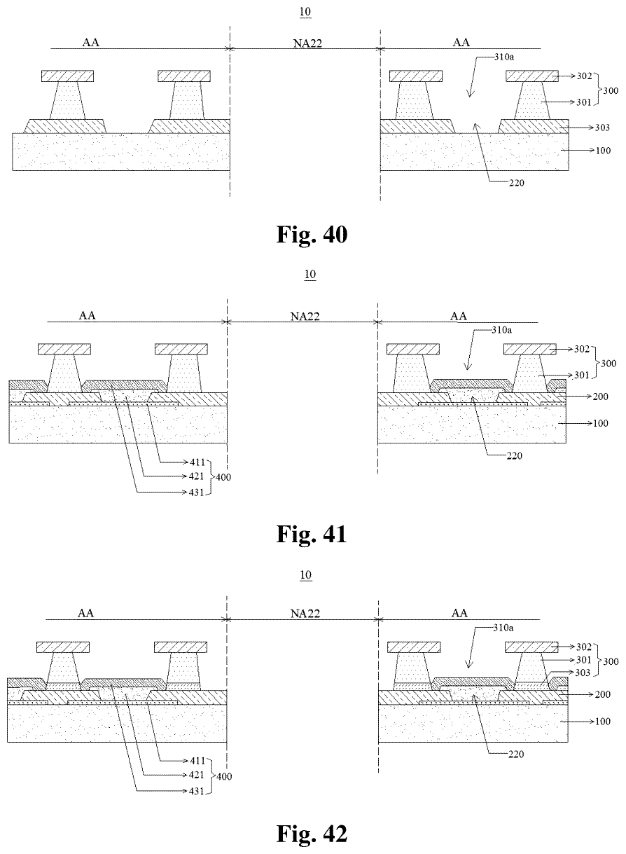

In the embodiments, referring to FIG. 40, the display panel 10 further includes a pixel defining layer 200 located at one side of the base plate 100, and the isolation structure layer 300 is located a side of the pixel defining layer 200 away from the base plate 100. The pixel defining layer 200 includes a pixel opening 220, and an orthographic projection of the pixel opening 220 on the base plate 100 is located within an orthographic projection of the isolation opening 310a on the base plate 100. In other words, the orthographic projection of the isolation opening 310a on the base plate 100 covers the orthographic projection of the pixel opening 220 on the base plate 100.

Referring to FIG. 41, in the embodiments, the display panel 10 further includes a light-emitting device 400 arranged within the isolation opening 310a and including a first electrode 411, a light-emitting unit 421, and a second electrode 431 that are stacked in sequence in a direction away from the base plate 100. The first electrodes 411 are distributed at intervals at one side of the base plate 100, and exemplarily, the first electrodes 411 are distributed at the base plate 100 corresponding to the isolation openings 310a and exposed by the pixel openings 220. The light-emitting unit 421 extends from the pixel opening 220 to the side of the pixel defining layer 200 away from the base plate 100, the second electrode 431 extends from within the pixel opening 220 to the side of the pixel defining layer 200 away from the base plate 100 and is connected with the isolation structure layer 300, and exemplarily, the second electrode 431 extends from within the pixel opening 220 to the side of the pixel defining layer 200 away from the base plate 100 and is connected with the first isolation layer 301. Exemplarily, in the embodiments, the first electrode 411 may be the anode of the light-emitting device 400, the second electrode 431 may be the cathode of the light-emitting device 400, and the first isolation layer 301 may be a conductive isolation portion which may connect the second electrodes of adjacent light-emitting devices 400 together. By connecting the first isolation layer 301 with a power supply signal voltage (VSS), the light-emitting devices 400 at different positions may have the same VSS, so as to improve the display uniformity of the display panel.

Referring to FIG. 42, in the embodiments, the isolation structure layer 300 further includes a third isolation layer 303 located at a side of the first isolation layer 301 towards the base plate 100, i.e., in the direction away from the base plate 100, the third isolation layer 303, the first isolation layer 301, and the second isolation material layer 302 are stacked in sequence. An orthographic projection of the third isolation layer 303 on the base plate 100 is located within an orthographic projection of the second isolation material layer 302 on the base plate 100, and an orthographic projection of the first isolation layer 301 on the base plate 100 is located within the orthographic projection of the third isolation layer 303 on the base plate 100. Exemplarily, the third isolation layer 303 may be a conductive isolation portion, and the second electrode 142 is connected with the conductive isolation portion.

In a direction perpendicular to the plane in which the base plate 100 is located, the height of the first isolation layer 301 is greater than the height of the third isolation layer 303, and in the embodiments, the material of the first isolation layer 301 includes aluminum, the material of the second isolation material layer 302 includes titanium, and the material of the third isolation layer 303 includes molybdenum.

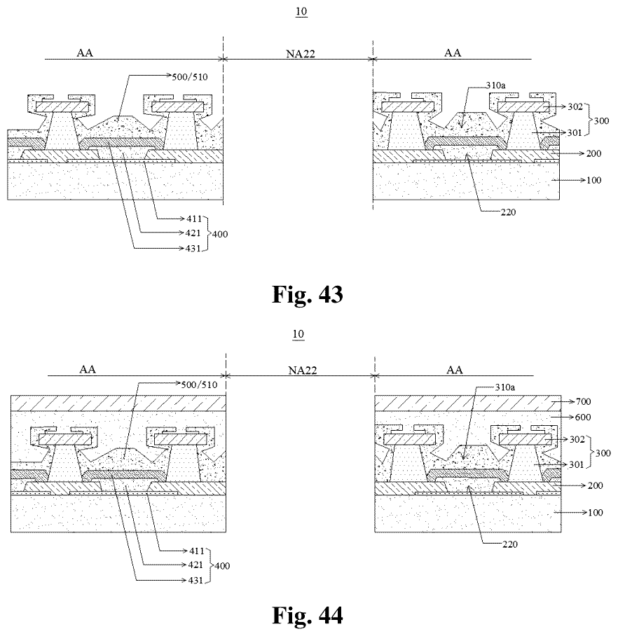

Referring to FIG. 43, the display panel 10 includes a first encapsulation layer 500 including a plurality of encapsulation units 510, different encapsulation units 510 are configured to encapsulate the light-emitting devices 400 within different isolation openings 310a, and adjacent encapsulation units 510 are spaced apart at the isolation structure layer 300. Exemplarily, two adjacent encapsulation units 510 are disconnected at a side of the isolation structure layer 300 away from the base plate 100. The encapsulation unit 510 may be prepared by chemical vapor deposition.

Referring to FIG. 44, the display panel 10 further includes a second encapsulation layer 600 and a third encapsulation layer 700, the second encapsulation layer 600 covers the isolation structure layer 300 and the light-emitting device 400, and the second encapsulation layer 600 forms a flat surface at a side away from the base plate 100. The third encapsulation layer 700 is located at side of the second encapsulation layer 600 away from the base plate 100. Herein, the second encapsulation layer 600 may be prepared by inkjet printing, and the third encapsulation layer 700 may be prepared by chemical vapor deposition. The first encapsulation layer 500 and the third encapsulation layer 700 are inorganic encapsulation layers, the second encapsulation layer 600 is an organic encapsulation layer, and the first encapsulation layer 500, the second encapsulation layer 600, and the third encapsulation layer 700 form the thin film encapsulation structure of the display panel 10.

In the embodiments, at a position close to the second sub-area NA22, the isolation structure layer 300 surrounds the second sub-area NA22. Unlike conventional OLED display panels, the display panel according to the embodiments may achieve individual light-emitting device encapsulation, and to this end, in the embodiments, the isolation structure layer 300 close to the second sub-area NA22 may not be intentionally configured to block the water and oxygen entering the display area AA from the second sub-area NA22. To this end, in the embodiments, the isolation structure layer 300 surrounding the second sub-area NA22 may be a continuously distributed isolation structure or a non-continuously distributed isolation structure, which may be arranged based on different panel design requirements. For example, if different light-emitting devices 400 need to be individually controlled, the isolation structure layers 300 defining different isolation openings 310a are electrically insulated from each other, in which case the isolation structure layer 300 surrounding the second sub-area NA22 is a non-continuously distributed isolation structure; if different light-emitting devices 400 at different positions need to be supplied with the same cathode voltage signal, the isolation structure layers 300 defining different isolation openings 310a may be connected with each other, in which case the isolation structure layer 300 surrounding the second sub-area NA22 is a continuously distributed isolation structure. Preferably, in the embodiments, the isolation structure layer 300 surrounding the second sub-area NA22 may be a continuously distributed isolation structure.

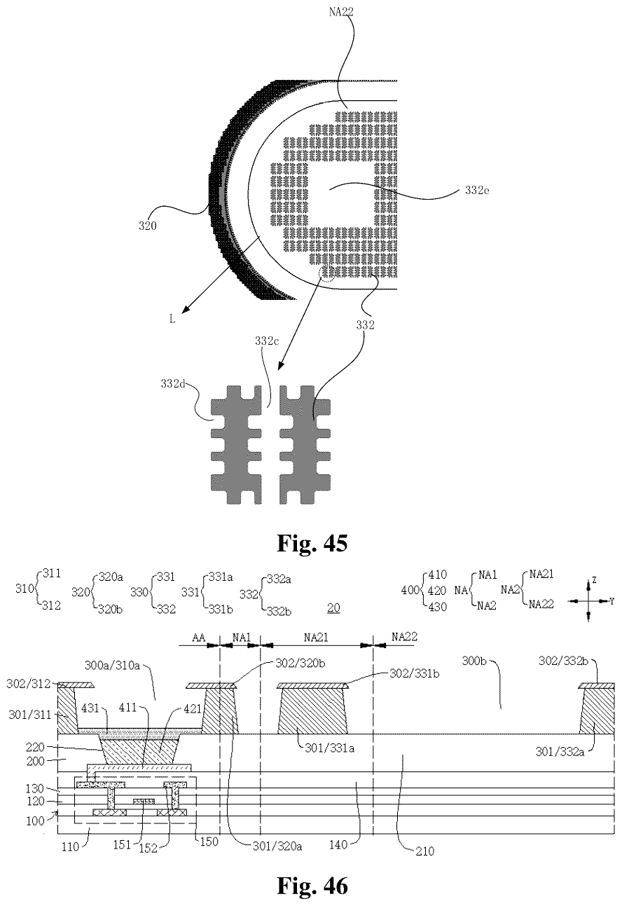

FIG. 45 shows a partially enlarged diagram of the second sub-area NA22 according to an embodiment of the present application, and FIG. 46 shows a partial sectional view of a display panel motherboard 20 according to an embodiment of the present application.

Referring to FIGS. 45 and 46 in conjunction with the figures in the above embodiments, the embodiments of the second aspect of the present application provide a display panel motherboard 20 having a display area AA and a non-display area NA, the non-display area NA includes a first area NA1 adjacent to the display area AA and a second area NA2 located at a side of the first area NA1 away from the display area AA, the second area NA2 includes a first sub-area NA21 and a second sub-area NA22 located at a side of the first sub-area NA21 away from the first area NA1, the display panel 10 includes: a base plate 100; a pixel defining layer 200 arranged at one side of the base plate 100, the pixel defining layer 200 including a pixel defining portion 210 and a plurality of pixel openings 220 enclosed and formed by the pixel defining portion 210; an isolation structure layer 300 arranged at a side of the pixel defining layer 200 away from the base plate 100, the isolation structure layer 300 including an isolation structure 310, an edge structure 320, and an auxiliary structure 330 spaced apart from the edge structure 320, the isolation structure 310 enclosing and forming an isolation opening 310a located in the display area AA and in communication with the pixel opening 220, the isolation structure 310 including a first isolation portion 311 and a second isolation portion 312 located at a side of the first isolation portion 311 away from the base plate 100, the edge structure 320 being located in the first area NA1 and enclosing and forming a functional opening 300b, the edge structure 320 including a first edge portion 320a and a second edge portion 320b located at a side of the first edge portion 320a away from the base plate 100, the auxiliary structure 330 including a second auxiliary structure 332 located in the second sub-area NA22, a protrusion length of at least a portion of the second edge portion 320b relative to the first edge portion 320a and towards the functional opening 300b being less than a protrusion length of the second isolation portion 312 relative to the first isolation portion 311 and towards the isolation opening 310a; and a plurality of light-emitting devices 400, at least a portion of a structure of the light-emitting device 400 being arranged within a corresponding isolation opening 310a.

The display panel motherboard 20 according to the embodiments of the present application has a display area AA and a non-display area NA, and the display panel motherboard 20 includes a base plate 100, a pixel defining layer 200, an isolation structure layer 300, and a plurality of light-emitting devices 400. The pixel defining layer 200 includes a pixel defining portion 210 and a plurality of pixel openings 220 enclosed and formed by the pixel defining portion 210, the isolation structure layer 300 is arranged at a side of the pixel defining layer 200 away from the base plate 100, the isolation structure layer 300 includes an isolation structure 310, an edge structure 320, and an auxiliary structure 330 spaced apart from the edge structure 320. The isolation structure 310 encloses and forms an isolation opening 310a located in the display area AA and in communication with the pixel opening 220, and both the isolation structure 310 and the pixel defining layer 200 may be used to divide the sub-pixels of the display panel motherboard 20. At least a portion of a structure of the light-emitting device 400 is arranged within a corresponding isolation opening 310a, so that the light-emitting device 400 within the isolation opening 310a can be used to achieve light emitting and display of the display area AA in the display panel motherboard 20.

The edge structure 320 is located in the first area NA1 and encloses and forms a functional opening 300b, which may facilitate increasing the light transmittance of the non-display area NA, so that when the display panel motherboard 20 is applied to a display apparatus, the photosensitive assembly for sensing light in the display apparatus may be correspondingly arranged under the functional opening, and thus the photosensitive assembly can better sense light through the functional opening.

The isolation structure 310 includes a first isolation portion 311 and a second isolation portion 312 located at a side of the first isolation portion 311 away from the base plate 100, the edge structure 320 includes a first edge portion 320a and a second edge portion 320b located at a side of the first edge portion 320a away from the base plate 100, and a protrusion length of at least a portion of the second edge portion 320b relative to the first edge portion 320a and towards the functional opening 300b is less than a protrusion length of the second isolation portion 312 relative to the first isolation portion 311 and towards the isolation opening 310a.

By arranging a greater protrusion length of the second isolation portion 312 relative to the first isolation portion 311 and towards the isolation opening 310a, when preparing the light-emitting device 400 of the display panel motherboard 20, at least a portion of the material of the light-emitting device 400 may be directly vapor deposited as a whole, and the second isolation portion 312 enclosing and forming the isolation opening 310a can block at least a portion of the material for preparing the light-emitting device 400 to separate the material of the light-emitting device 400 between adjacent sub-pixels, so as to facilitate forming a plurality of light-emitting devices 400 that are spaced apart and located within the isolation openings 310a. Therefore, no fine mask is needed when preparing the light-emitting device 400 of the display panel motherboard 20, for example, no fine metal mask is needed when vapor depositing the material of the light-emitting device 400, thereby better reducing the production and preparation costs of the display panel motherboard 20.

By arranging a less protrusion length of at least a portion of the second edge portion 320b enclosing and forming the functional opening 300b relative to the first edge portion 320a and towards the functional opening 300b, when new material is formed on the isolation structure layer 300 during the manufacturing of the display panel motherboard 20, for example, when organic material is formed on the isolation structure layer 300, the second edge portion 320b located at the periphery of the functional opening 300b within the non-display area NA is less likely to block the organic material, and the new material may better fall in the vicinity of the first edge portion 320a at the periphery of the functional opening 300b. Moreover, when new material is formed on the isolation structure layer 300, the second edge portion 320b with a less protrusion length is less likely to excessively block gas discharging, so that gas is less likely to be retained under the second edge portion 320b at the periphery of the functional opening 300b, thereby better increasing the structure stability and processing reliability of the display panel motherboard 20.

By arranging that the auxiliary structure 330 includes a second auxiliary structure 332 located in the second sub-area NA22, when the isolation structure layer 300 is etched and prepared, the etching material located within the functional opening 300b can also etch the material of the second auxiliary structure 332, so that the second auxiliary structure 332 may restrict the delivery of the etching material within the functional opening 300b towards the edge structure 320 to better reduce the etching amount of the etching material on the material of the edge structure 320, and thus the edge structure 320 is less likely to be damaged by over etching, thereby better increasing the structure stability of the display panel motherboard 20. Moreover, the second auxiliary structure 332 not only reduces the etching amount of the etching material on the material of the edge structure 320, but also can facilitate achieving the topography of the edge structure 320 in the above embodiments. That is, the arrangement of the second auxiliary structure 332 can reduce the etching amount of the etching material on the material of the edge structure 320, so as to facilitate forming the topography in which the protrusion length of at least a portion of the second edge portion 320b relative to the first edge portion 320a and towards the functional opening 300b is less than the protrusion length of the second isolation portion 312 relative to the first isolation portion 311 and towards the isolation opening 310a.

Optionally, the display panel motherboard 20 according to the embodiments of the second aspect of the present application may be used to manufacture the display panel 10 in any of the above embodiments. For example, the second sub-area NA22 of the display panel motherboard 20 may be perforated to remove the second auxiliary structure 332 located within the second sub-area NA22 and a portion of the base plate 100 located under the second auxiliary structure 332 and to form a functional hole H, thereby forming the display panel 10 in any of the above embodiments. Herein, except the distinguishing structural features of the functional hole H and the second auxiliary structure 332, the structure of the display panel motherboard 20 according to the embodiments of the second aspect of the present application may be arranged with reference the structure of the display panel 10 in any of the above embodiments, and thus the display panel motherboard 20 according to the embodiments of the present application may have the beneficial effects of the display panel 10 in any of the above embodiments, which will not be repeated herein.

Optionally, the second auxiliary structure 332 may include a third auxiliary portion 332a and a fourth auxiliary portion 332b located at side of the third auxiliary portion 332a away from the base plate 100, in which the third auxiliary portion 332a may be arranged in the same layer and made of the same material as the first isolation portion 311 of the isolation structure 310 in any one of the above embodiments, and the fourth auxiliary portion 332b may be arranged in the same layer and made of the same material as the second isolation portion 312 of the isolation structure 310 in any one of the above embodiments, so that the second auxiliary structure 332 may be prepared by the same or similar preparation process as the isolation structure 310 in any of the above embodiments.

In some optional embodiments, there may be a plurality of auxiliary structures 330, a drainage groove 332c is formed between adjacent second auxiliary structures 332, and the second auxiliary structure 332 is provided with a drainage auxiliary groove 332d in communication with the drainage groove 332c.

In these optional embodiments, by arranging the drainage groove 332c and the drainage auxiliary groove 332d, when new material is formed on the isolation structure layer 300 during the manufacturing of the display panel motherboard 20, the contact area and the adhesion between the second auxiliary structure 332 and the new material are increased, which may reduce gas accumulation at the periphery the second auxiliary structure 332, thereby better reducing the probability of defect.

In some optional embodiments, the second auxiliary structure 332 includes a through hole penetrating the second auxiliary structure 332, and the through hole is formed as the positioning marking opening 332e, or a pattern formed in the area surrounded by a plurality of second auxiliary structures 332 is formed as the positioning marking opening 332e.

In these optional embodiments, the positioning marking opening 332e may be configured to position the mask plate used in preparing the light-emitting device 400 or other structure. By arranging the positioning marking opening 332e in the second sub-area NA22, the alignment and fixing accuracy of the mask plate may be improved, and the manufacturing accuracy of the display panel 10 is enhanced.

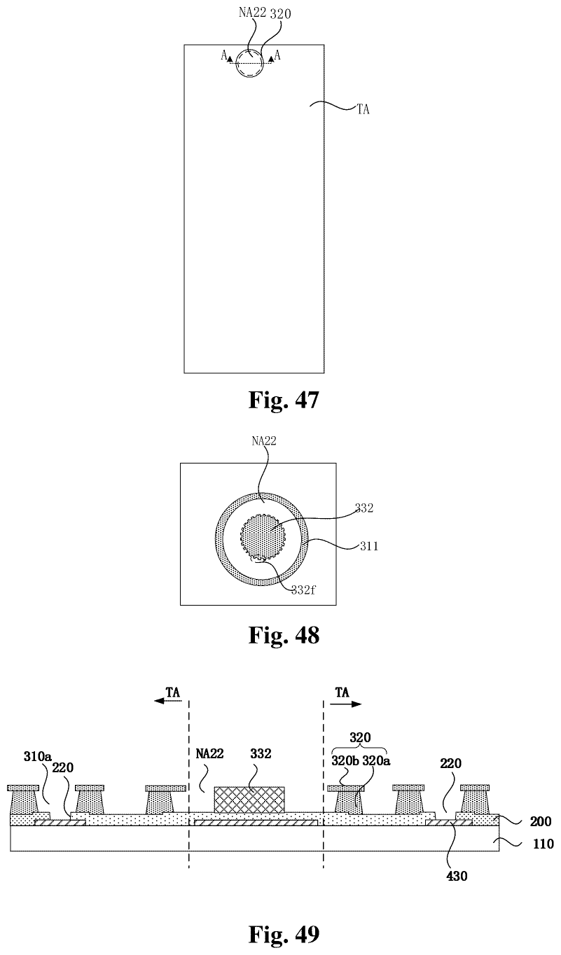

The embodiments of the second aspect of the present application further provide a display panel motherboard. FIG. 47 shows a top view of a display panel motherboard 20 according to an embodiment of the present application, FIG. 48 shows a partially enlarged diagram of a second sub-area NA22 of the display panel in FIG. 47, and FIG. 49 shows a sectional view of the display panel motherboard 20 along a section line A-A in FIG. 47. Referring to FIGS. 47 to 49, the display panel motherboard 20 includes: a substrate 110; a pixel defining layer 200 located at one side of the substrate 110; a defining structure located at a side of the pixel defining layer 200 away from the substrate 110 and comprising an edge structure 320 and at least one second auxiliary structure 332; in which the edge structure 320 is located in a first specific area TA, and the defining structure encloses and forms a plurality of isolation openings 310a in the first specific area TA, and the edge structure 320 surrounds at least a portion of a second sub-area NA22; the at least one second auxiliary structure 332 is located in the second sub-area NA22.

Optionally, the display panel motherboard 20 further according to the embodiments of the second aspect of the present application may be the display panel motherboard 20 in any of the above embodiments, and thus the display panel motherboard 20 further according to the embodiments of the present application may have the beneficial effects of the display panel motherboard 20 in any of the above embodiments, which will not be repeated herein.

Optionally, the display panel motherboard 20 further according to the embodiments of the second aspect of the present application may be used to manufacture the display panel 10 in any of the above embodiments. For example, the second sub-area NA22 of the display panel motherboard 20 may be perforated to remove the second auxiliary structure 332 located within the second sub-area NA22 and a portion of the substrate 110 located under the second auxiliary structure 332 and to form a functional hole, thereby forming the display panel 10 in any of the above embodiments. Herein, except the distinguishing structural features of the functional hole H and the second auxiliary structure 332, the structure of the display panel motherboard 20 according to the embodiments of the second aspect of the present application may be arranged with reference the structure of the display panel 10 in any of the above embodiments, and thus the display panel motherboard 20 according to the embodiments of the present application may have the beneficial effects of the display panel 10 in any of the above embodiments, which will not be repeated herein.

Optionally, the defining structure may include the isolation structure 310 and the edge structure 320 in any of the above embodiments.

Herein, the first specific area TA may subsequently form a display area for displaying image, and the second sub-area NA22 may subsequently form a hole area which facilitates arranging the photosensitive assembly such as a camera; in some other embodiments, the first specific area TA may further include a non-display area located between the display area and the hole area. The first specific area TA surrounds at least a portion of the second sub-area NA22, and exemplarily, the first specific area TA surrounds all or a portion of the second sub-area NA22. The display panel motherboard 20 may further include a driving circuit layer located between the substrate 110 and the pixel defining layer 200, the driving circuit layer may include a plurality of pixel driving circuits for driving the light-emitting structures to emit light, and each light-emitting structure corresponds to a pixel driving circuit. The pixel driving circuit may include at least two thin-film transistors and at least one capacitor, and exemplarily, each pixel driving circuit may include seven thin-film transistors and one capacitor. The driving circuit layer is electrically connected with the first electrode layer 410. The first electrode layer 410 may be the anode or cathode of the light-emitting structure.

In addition, the edge structure 320 and the second auxiliary structure 332 are arranged on a surface of the pixel defining layer 200 away from the substrate 110; the edge structure 320 is arranged in the first specific area TA and surrounds at least a portion of the second sub-area NA22. The edge structure 320 may include a first edge portion 320a and a second edge portion 320b arranged at a side of the first edge portion 320a away from the substrate 110, an orthographic projection of the second edge portion 320b on the substrate 110 covers an orthographic projection of the first edge portion 320a on the substrate 110, and an edge of the orthographic projection of the second edge portion 320b on the substrate 110 does not overlap an edge of the orthographic projection of the first edge portion 320a on the substrate 110; and the second auxiliary structure 332 is arranged in the second sub-area NA22.

The pixel defining layer 200 within each isolation opening 310a may include a pixel opening 220. The isolation opening 310a of the defining structure is configured to separate a plurality of light-emitting structures from each other, each isolation opening 310a includes a pixel opening 220, each pixel opening 220 is configured to arrange a light-emitting structure, the second electrode of each light-emitting structure may be disconnected from the second electrodes of the other light-emitting structures through the defining structure, and each light-emitting structure is individually encapsulated; in other embodiments, each isolation opening 310a includes a plurality of pixel openings 220, and the light-emitting structures arranged in the plurality of pixel openings 220 emit lights of the same color. The edge structure 320 surrounding at least a portion of the second sub-area NA22 may mean that the edge structure 320 surrounds all or a portion of the second sub-area NA22. Exemplarily, the edge structure 320 surrounds all the second sub-area NA22 if the first specific area TA surrounds all the second sub-area NA22, and the edge structure 320 surrounds a portion of the second sub-area NA22 if the first specific area TA surrounds a portion of the second sub-area NA22.

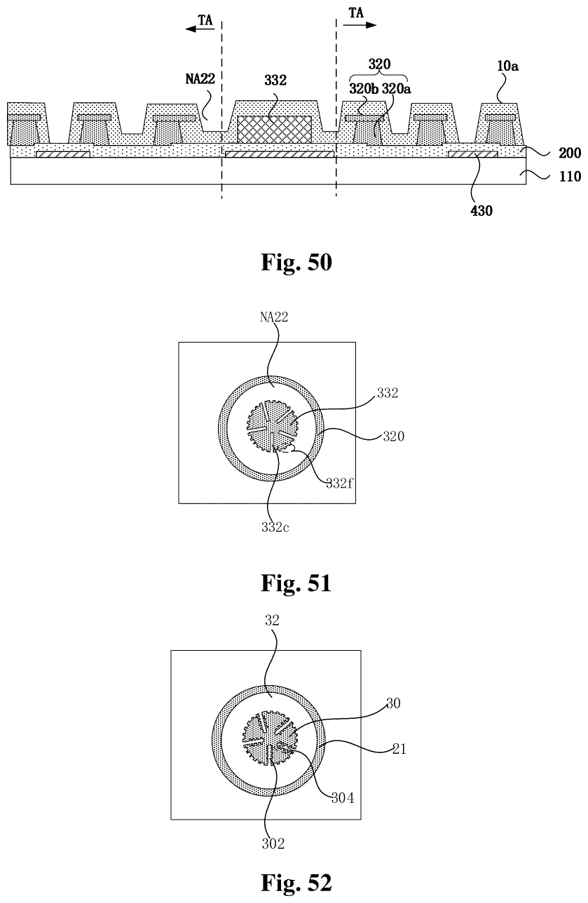

Specifically, FIG. 50 shows a sectional view of a preparation process of the display panel motherboard 20 according to an embodiment of the present application. Referring to FIGS. 49 and 50, in the preparation process of the display panel motherboard 20, the pixel defining layer 200 is first prepared, then the edge structure 320 and the second auxiliary structure 332 are prepared, and then the pixel defining layer 200 is patterned to form the pixel opening 220. A first protective material layer 10a needs to be deposited in patterning the pixel defining layer 200 and patterned through a photolithographic process to expose the pixel defining layer 200 to be etched. FIG. 50 illustrates the patterned first protective material layer 10a which exposes the pixel defining layer 200 to be etched in the first specific area TA. By arranging the second auxiliary structure 332 in the second sub-area NA22, the preparation yield of the display panel motherboard 20 may be improved.

In addition, the second sub-area NA22 may be provided with one, two, or more second auxiliary structures 332. The second auxiliary structure 332 may increase the adhesion between the first protective material layer 10a and the second sub-area NA22. The second auxiliary structure 332 may further guide the first protective material layer 10a so that the first protective material layer 10a completely covers the area of the second sub-area NA22 adjacent to the edge structure 320, which may reduce gas accumulation. The second auxiliary structure 332 may be made of a metal material, so as to increase the metal density of the second sub-area NA22, reduce the side etching amount of the edge structure 320, and reduce gas accumulation.

In the embodiments of the present application, the second auxiliary structure 332 and the edge structure 320 are arranged on a surface of the pixel defining layer 200 away from the substrate 110, the edge structure 320 is arranged in the first specific area TA and surrounds at least a portion of the second sub-area NA22, and the second auxiliary structure 332 is arranged in the second sub-area NA22, so that in etching the pixel defining layer 200, when the first protective material layer 10a for etching the pixel defining layer 200 is deposited, the second auxiliary structure 332 may fit the deposited first protective material layer 10a, thereby improving the preparation yield of the display panel motherboard 20.

Optionally, still referring to FIGS. 48 to 50, at least a portion of the edge of the orthographic projection of the second auxiliary structure 332 on the substrate 110 is a concave-convex edge.

Specifically, the convex portion of the concave-convex edge is convex outwardly towards the exterior of the second auxiliary structure 332, and the concave portion is concave inwardly towards the interior of the second auxiliary structure 332. At least a portion of the edge of the orthographic projection of the second auxiliary structure 332 on the substrate 110 being a concave-convex edge may mean that a portion of the edge of the orthographic projection of the second auxiliary structure 332 on the substrate 110 is a concave-convex edge, or that the entire edge of the orthographic projection of the second auxiliary structure 332 on the substrate 110 is a concave-convex edge.

The surface of the pixel defining layer 200 between the second auxiliary structure 332 and the edge structure 320 and the surface of the second auxiliary structure 332 form a certain height difference, so that when the photoresist is deposited, the photoresist on the surface of the second auxiliary structure 332 may better flow onto the surface of the pixel defining layer 200 between the second auxiliary structure 332 and the edge structure 320, and thus the photoresist may cover the area close to the edge structure 320, and moreover, the contact between the photoresist and the second auxiliary structure 332 increases the adhesion, thereby reducing the probability of defect. In addition, by arranging that at least a portion of the orthographic projection of the edge of the second auxiliary structure 332 adjacent to the edge structure 320 on the substrate 110 forms a concave-convex edge, the first protective material layer 10a between the edge structure 320 and the second auxiliary structure 332 have a great contact area with the second auxiliary structure 332, so that the adhesion between the first protective material layer 10a and the second auxiliary structure 332 is great, thereby further reducing the probability of defect.

Optionally, the edge of the orthographic projection of the second auxiliary structure 332 on the substrate 110 has at least one of a serration shape, a wave shape, or a fold line shape.

Specifically, all the edges of the serration shape, the wave shape, or the fold line shape may achieve a great contact area between the edge structure 320 and the first protective material layer 10a.

FIG. 51 shows an enlarged diagram of yet another second sub-area NA22 according to an embodiment of the present application. Optionally, referring to FIG. 51, the second auxiliary structure 332 includes at least one drainage groove 332c which extends from the edge of the second auxiliary structure 332 to the center of the second auxiliary structure 332, and the drainage groove 332c is connected to the outside environment, i.e., the end of the drainage groove 332c away from the center of the second auxiliary structure 332 is connected to the outside environment.

Specifically, by arranging the drainage groove 332c, the contact area and adhesion between the second auxiliary structure 332 and the first protective material layer 10a are further increased, and thus the probability of defect is further reduced.

Optionally, there are a plurality of drainage grooves 332c distributed at intervals along the periphery of the second auxiliary structure 332.

Exemplarily, the plurality of drainage grooves 332c are uniformly distributed along the periphery of the second auxiliary structure 332.

Optionally, in a direction perpendicular to the substrate 110, the depth of the drainage groove 332c is equal to the thickness of the second auxiliary structure 332.

That is, in the thickness direction of the second auxiliary structure 332, the drainage groove 332c penetrates the second auxiliary structure 332, which increases the sidewall area of the drainage groove 332c, and further increases the contact area and adhesion between the second auxiliary structure 332 and the first protective material layer 10a, and thus the probability of defect is further reduced.

FIG. 52 shows an enlarged diagram of yet another second sub-area NA22 according to an embodiment of the present application. Optionally, with reference to FIG. 52, at least a portion the edge of the orthographic projection of the drainage groove 332c on the substrate 110 forms a concave-convex structure 332f, which further increases the sidewall area of the drainage groove 332c, and further increases the contact area and adhesion between the second auxiliary structure 332 and the first protective material layer 10a, and thus the probability of defect is further reduced.

Optionally, the edge of the orthographic projection of the drainage groove 332c on the substrate 110 has at least one of a serration shape, a wave shape, or a fold line shape.

Specifically, all the edges of the serration shape, the wave shape, or the fold line shape may achieve a great contact area between the edge structure 320 and the first protective material layer 10a, which may better increase the adhesion between the first protective material layer 10a and the second auxiliary structure 332.

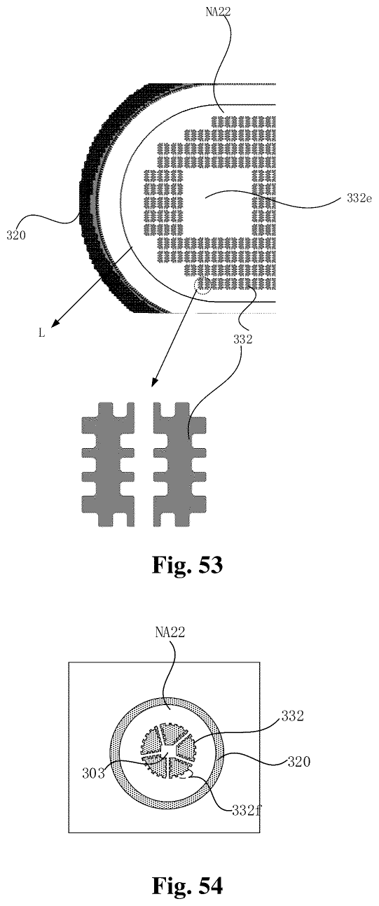

FIG. 53 shows a partially enlarged diagram of yet another sub-area NA22 according to an embodiment of the present application. Optionally, referring to FIGS. 50 and 53, the second sub-area NA22 includes at least two second auxiliary structures 332, and a gap is between adjacent second auxiliary structures 332.

Specifically, the at least two second auxiliary structures 332 may be distributed in an array. The edges of each second auxiliary structure 332 are all in contact with the first protective material layer 10a, which further increases the contact area and adhesion between the second auxiliary structure 332 and the first protective material layer 10a, and thus the probability of defect is further reduced. Moreover, a spacing is between adjacent second auxiliary structures 332, so that no closed pattern is formed between the second auxiliary structures 332, and when the photoresist is subsequently deposited, gas accumulation at the photoresist and the second auxiliary structures 332 is effectively avoided.

Optionally, the orthographic projection of the edge of each second auxiliary structure 332 on the substrate 110 includes a concave-convex edge, which further increases the contact area and adhesion between the second auxiliary structure 332 and the first protective material layer 10a, and thus the probability of defect is further reduced.

FIG. 54 shows an enlarged diagram of yet another second sub-area NA22 according to an embodiment of the present application. Optionally, referring to FIGS. 53 and 54, the display panel motherboard 20 further comprises a positioning marking opening 332e located in the second sub-area NA22.

Herein, the positioning marking opening 332e is configured to position the mask plate used in preparing the light-emitting layer 420 or other structure. By arranging the positioning marking opening 332e in the second sub-area NA22, the alignment and fixing accuracy of the mask plate may be further improved, and the manufacturing accuracy of the display panel 10 is enhanced.

Optionally, the second auxiliary structure 332 includes a through hole which is the positioning marking opening 332e, or referring to FIG. 53 or 54, the area surrounded by a plurality of second auxiliary structures 332 is the positioning marking opening 332e.

With the above configuration, the first protective material layer 10a may be filled in the positioning marking opening 332e, which further increases the contact area and adhesion between the second auxiliary structure 332 and the first protective material layer 10a, and thus the probability of defect is further reduced.

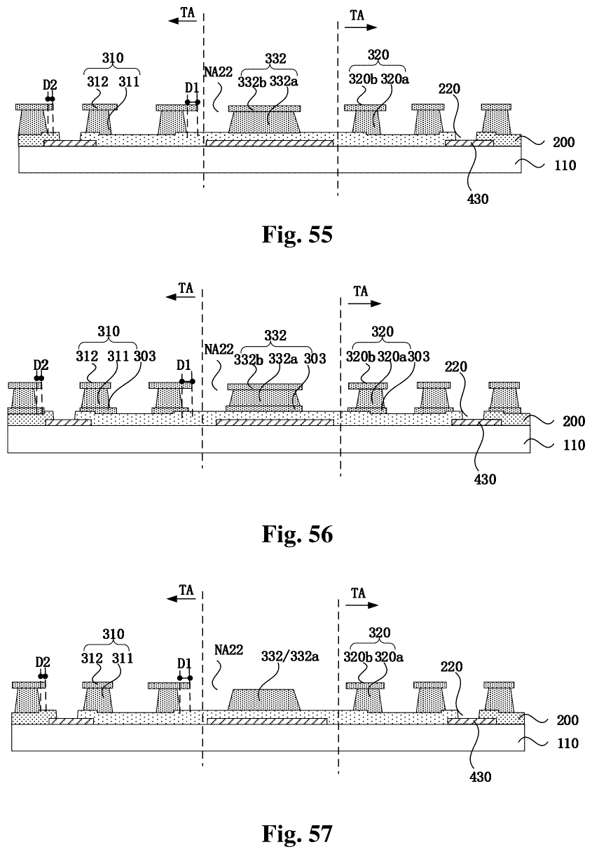

Optionally, FIG. 55 shows a sectional view of yet another display panel motherboard 20 according to an embodiment of the present application. Referring to FIG. 55, in a direction perpendicular to the substrate 110, the thickness of the second auxiliary structure 332 is the same as the height of the edge structure 320, and the second auxiliary structure 332 and the edge structure 320 are made of the same material.

With the above configuration, the second auxiliary structure 332 and the edge structure 320 may be prepared in the same process, which reduces the process cost.

Optionally, referring to FIG. 55, the edge structure 320 includes a first edge portion 320a and a second edge portion 320b arranged at a side of the first edge portion 320a away from the substrate 110, an orthographic projection of the second edge portion 320b on the substrate 110 covers an orthographic projection of the first edge portion 320a on the substrate 110, and an edge of the orthographic projection of the second edge portion 320b on the substrate 110 does not overlap an edge of the orthographic projection of the first edge portion 320a on the substrate 110.

Specifically, the orthographic projection of the second edge portion 320b on the substrate 110 covers the orthographic projection of the first edge portion 320a on the substrate 110, and the edge of the orthographic projection of the second edge portion 320b on the substrate 110 does not overlap the edge of the orthographic projection of the first edge portion 320a on the substrate 110, i.e., the first edge portion 320a in the edge structure 320 is concave relative to the second edge portion 320b by a certain distance.

Optionally, the second auxiliary structure 332 includes a third auxiliary portion 332a and a fourth auxiliary portion 332b; the fourth auxiliary portion 332b is arranged at a side of the third auxiliary portion 332a away from the substrate, an orthographic projection of the fourth auxiliary portion 332b on the substrate 110 covers an orthographic projection of the third auxiliary portion 332a on the substrate 110, and an edge of the orthographic projection of the fourth auxiliary portion 332b on the substrate 110 does not overlap an edge of the orthographic projection of the third auxiliary portion 332a on the substrate 110.

Specifically, the orthographic projection of the fourth auxiliary portion 332b on the substrate 110 covers the orthographic projection of the third auxiliary portion 332a on the substrate 110, and the edge of the orthographic projection of the fourth auxiliary portion 332b on the substrate 110 does not overlap the edge of the orthographic projection of the third auxiliary portion 332a on the substrate 110, i.e., the third auxiliary portion 332a is concave relative to the fourth auxiliary portion 332b by a certain distance. With the above configuration, the second auxiliary structure 332 and the edge structure 320 may be prepared by the same process, no new process is added, which reduces the process cost.

Optionally, the third auxiliary portion 332a and the first edge portion 320a are arranged in the same layer and have the same material and thickness; and the fourth auxiliary portion 332b and the second edge portion 320b are arranged in the same layer and have the same material and thickness.

With the above configuration, the second auxiliary structure 332 and the edge structure 320 may be formed in the same process, which reduces the process cost. Moreover, the third auxiliary portion 332a and the first edge portion 320a are made of the same material, so that in forming the edge structure 320, the etching solution for etching the first edge portion 320a simultaneously etches the third auxiliary portion 332a, which may avoid an excessive side etching amount of the etching solution on the first edge portion 320a, and thus avoid a great concavity of the first edge portion 320a, reduce gas accumulation, and reduce the defect of the production line.

Optionally, the material of the third auxiliary portion 332a and the first edge portion 320a includes aluminum, silver, or copper; and the material of the fourth auxiliary portion 332b and the second edge portion 320b includes titanium or molybdenum. Specifically, the material of the third auxiliary portion 332a and the first edge portion 320a is aluminum, and the material of the fourth auxiliary portion 332b and the second edge portion 320b is titanium.

Optionally, FIG. 56 shows a sectional view of yet another display panel motherboard 20 according to an embodiment of the present application. Referring to FIG. 56, the edge structure 320 further includes a third isolation layer 303 arranged at a side of the first edge portion 320a towards the substrate 110, and an orthographic projection of the first edge portion 320a on the substrate 110 is located within an orthographic projection of the third isolation layer 303 on the substrate 110; the second auxiliary structure 332 further includes a third isolation layer 303 arranged at a side of the third auxiliary portion 332a towards the substrate 110, and an orthographic projection of the third auxiliary portion 332a on the substrate 110 is located within an orthographic projection of the third isolation layer 303 on the substrate 110.

Specifically, both the edge structure 320 and the second auxiliary structure 332 have I-shaped cross-sections, and the second auxiliary structure 332 and the edge structure 320 may be prepared by the same process, which reduces the process cost.

Optionally, the third isolation layer 303 of the edge structure 320 and the third isolation layer 303 of the second auxiliary structure 332 are arranged in the same layer and have the same material and thickness.

With the above configuration, the third isolation layer 303 of the edge structure 320 and the third isolation layer 303 of the second auxiliary structure 332 may be formed in the same process, and the second auxiliary structure 332 and the edge structure 320 may be formed in the same process, which reduces the process cost.

Optionally, the material of the third isolation layer 303 of the edge structure 320 and the third isolation layer 303 of the second auxiliary structure 332 includes molybdenum or titanium. Specifically, the material of the third isolation layer 303 of the edge structure 320 and the third isolation layer 303 of the second auxiliary structure 332 is molybdenum.

Optionally, referring to FIG. 53, there are a plurality of second auxiliary structures 332 located in the second sub-area NA22, and the plurality of second auxiliary structures 332 are spaced apart.

Optionally, if the second auxiliary structure 332 includes the third auxiliary portion 332a, the fourth auxiliary portion 332b, and the third isolation layer 303, the edge of the orthographic projection of the second auxiliary structure 332 on the substrate 110 has at least one of a serration shape, a wave shape, or a fold line shape, which further increases the adhesion between a first photoresist layer and the second auxiliary structures 332, thereby further reducing the probability of defect.

Furthermore, referring to FIGS. 55 and 56, the defining structure further includes an isolation structure 310 located at a side of the pixel defining layer 200 away from the substrate 110, and the isolation structure 310 is located in the first specific area TA and at a side of the edge structure 320 away from the second auxiliary structure 332.

Specifically, the isolation structure 310 includes a first isolation portion 311 and a second isolation portion 312, the first isolation portion 311 and the first edge portion 320a are arranged in the same layer and have the same material and thickness; the second isolation portion 312 and the second edge portion 320b are arranged in the same layer and have the same material and thickness; and an orthographic projection of the second isolation portion 312 on the substrate 110 covers an orthographic projection of the first isolation portion 311 on the substrate 110, and an edge of the orthographic projection of the second isolation portion 312 on the substrate 110 does not overlap an edge of the orthographic projection of the first isolation portion 311 on the substrate 110. A distance between an edge of the orthographic projection of a side of the second edge portion 320b towards the second sub-area NA22 on the substrate 110 and an edge of the orthographic projection of a side of the first edge portion 320a towards the second sub-area NA22 on the substrate 110 is D1, a distance between the edge of the orthographic projection of the second isolation portion 312 on the substrate 110 and the edge of the orthographic projection of the first isolation portion 311 on the substrate 110 is D2, and D1 is greater than or equal to D2.

Further, a difference between D1 and D2 is less than or equal to 0.3 μm, i.e., D1−D2≤0.3 μm. For example, the difference between D1 and D2 is 0.3 μm, 0.25 μm, 0.2 μm, 0.18 μm, 0.15 μm, 0.12 μm, 0.08 μm, 0.05 μm, 0.03 μm, 0.01 μm, or 0 μm, and the like.

Referring to FIG. 56, the isolation structure 310 further includes a third isolation layer 303 arranged at a side of the first isolation portion 311 towards the substrate 110, and an orthographic projection of the first isolation portion 311 on the substrate 110 is located within an orthographic projection of the third isolation layer 303 on the substrate 110. It is noted that the edge structure 320 and the isolation structure 310 may be connected to form a mesh structure in the first specific area TA, and the edge structure 320 and the isolation structure 310 may enclose and form the isolation opening at which the pixel opening 220 is arranged, or the isolation structure 310 may enclose and form the isolation opening at which the pixel opening 220 is arranged; in other embodiments, the edge structure 320 and the isolation structure 310 may be not connected, in which case the isolation structure 310 in the first specific area TA encloses and forms the isolation opening at which the pixel opening 220 may be arranged.

Optionally, the third isolation layer 303 of the edge structure 320 and the third isolation layer 303 of the isolation structure 310 are arranged in the same layer and have the same material and thickness. Therefore, the edge structure 320 and the isolation structure 310 may be formed in the same process, which reduces the process cost.

The embodiments of the second aspect of the present application further provide a display panel motherboard. FIG. 57 shows a sectional view of yet another display panel motherboard 20 according to an embodiment of the present application, and referring to FIG. 57, the display panel motherboard 20 includes: a substrate 110; a pixel defining layer 200 located at one side of the substrate 110; a defining structure and at least one second auxiliary structure 332 located at a side of the pixel defining layer 200 away from the substrate 110; in which the defining structure includes an edge structure 320 located in a first specific area TA and surrounding at least a portion of a second sub-area NA22; the edge structure 320 includes a first edge portion 320a and a second edge portion 320b arranged at a side of the first edge portion 320a away from the substrate, an orthographic projection of the second edge portion 320b on the substrate 110 covers an orthographic projection of the first edge portion 320a on the substrate 110, and an edge of the orthographic projection of the second edge portion 320b on the substrate 110 does not overlap an edge of the orthographic projection of the first edge portion 320a on the substrate 110; the at least one second auxiliary structure 332 is located in the second sub-area NA22; and the second auxiliary structure 332 includes a third auxiliary portion 332a having the same material as the first edge portion 320a.

In the embodiments of the present application, the second auxiliary structure 332 and the edge structure 320 are arranged on a surface of the pixel defining layer 200 away from the substrate 110, the edge structure 320 is arranged in the first specific area TA and surrounds at least a portion of the second sub-area NA22, the second auxiliary structure 332 is arranged in the second sub-area NA22 and includes the third auxiliary portion 332a having the same material as the first edge portion 320a, so that in forming the edge structure 320 and the second auxiliary structure 332 by etching, the etching solution for etching the first edge portion 320a may simultaneously etch the third auxiliary portion 332a, which may avoid an excessive side etching amount of the etching solution on the first edge portion 320a, and thus avoid a great concavity of the first edge portion 320a, reduce gas accumulation, and improve the preparation yield of the display panel motherboard 20.

Optionally, the display panel motherboard 20 further according to the embodiments of the second aspect of the present application may be the display panel motherboard 20 in any of the above embodiments, and thus the display panel motherboard 20 further according to the embodiments of the present application may have the beneficial effects of the display panel motherboard 20 in any of the above embodiments, which will not be repeated herein.

Optionally, the display panel motherboard 20 further according to the embodiments of the second aspect of the present application may be used to manufacture the display panel 10 in any of the above embodiments. For example, the second sub-area NA22 of the display panel motherboard 20 may be perforated to remove the second auxiliary structure 332 located within the second sub-area NA22 and a portion of the substrate 110 located under the second auxiliary structure 332 and to form a functional hole, thereby forming the display panel 10 in any of the above embodiments. Herein, except the distinguishing structural features of the functional hole H and the second auxiliary structure 332, the structure of the display panel motherboard 20 according to the embodiments of the second aspect of the present application may be arranged with reference the structure of the display panel 10 in any of the above embodiments, and thus the display panel motherboard 20 according to the embodiments of the present application may have the beneficial effects of the display panel 10 in any of the above embodiments, which will not be repeated herein.

Optionally, the defining structure may include the isolation structure 310 and the edge structure 320 in any of the above embodiments.

Optionally, the material of the third auxiliary portion 332a and the first edge portion 320a includes aluminum, silver, or copper; and the material of the second edge portion 320b includes titanium or molybdenum. Specifically, the material of the third auxiliary portion 332a and the first edge portion 320a is aluminum, and the material of the second edge portion 320b is titanium.

The first specific area TA and the second sub-area NA22 in the embodiments may be made refer to the above description of embodiments; in addition, the edge structure 320 may further include a third isolation layer 303, and the second auxiliary structure 332 may include a third isolation layer 303, the specific design of which may refer to the above description of embodiments and will not be repeated herein; in some other embodiments, the second auxiliary structure 332 may not include the third isolation layer 303, i.e., only the third auxiliary portion 332a.

Optionally, still referring to FIG. 53, there are a plurality of second auxiliary structures 332 located in the second sub-area NA22, and the plurality of second auxiliary structures 332 are distributed at intervals.

Optionally, at least a portion of the edge of the orthographic projection of the third auxiliary portion 332a on the substrate is a concave-convex edge.

Specifically, the structure and function of the concave-convex edge of the third auxiliary portion 332a are similar to those of the concave-convex edge as shown in FIG. 48, and will not be repeated herein.

Optionally, the edge of the orthographic projection of the third auxiliary portion 332a on the substrate has at least one of a serration shape, a wave shape, or a fold line shape.

Furthermore, as shown in FIG. 57, the defining structure further includes an isolation structure 310 located at a side of the pixel defining layer 200 away from the substrate 110, and the isolation structure 310 is located in the first specific area TA and at a side of the edge structure 320 away from the second auxiliary structure 332.

Specifically, the isolation structure 310 includes a first isolation portion 311 and a second isolation portion 312, the first isolation portion 311 and the first edge portion 320a are arranged in the same layer and have the same material and thickness; the second isolation portion 312 and the second edge portion 320b are arranged in the same layer and have the same material and thickness; and an orthographic projection of the second isolation portion 312 on the substrate 110 covers an orthographic projection of the first isolation portion 311 on the substrate 110, and an edge of the orthographic projection of the second isolation portion 312 on the substrate 110 does not overlap an edge of the orthographic projection of the first isolation portion 311 on the substrate 110. A distance between an edge of the orthographic projection of a side of the second edge portion 320b towards the second sub-area NA22 on the substrate 110 and an edge of the orthographic projection of a side of the first edge portion 320a towards the second sub-area NA22 on the substrate 110 is D1, a distance between the edge of the orthographic projection of the second isolation portion 312 on the substrate 110 and the edge of the orthographic projection of the first isolation portion 311 on the substrate 110 is D2, and D1 is greater than or equal to D2.

Further, a difference between D1 and D2 is less than or equal to 0.3 μm, i.e., D1−D2≤0.3 μm. For example, the difference between D1 and D2 is 0.3 μm, 0.25 μm, 0.2 μm, 0.18 μm, 0.15 μm, 0.12 μm, 0.08 μm, 0.05 μm, 0.03 μm, 0.01 μm, or 0 μm, and the like.

In some embodiments, the isolation structure 310 further includes a third isolation layer 303, the details of which may refer to the description of the third isolation layer 303 in the above embodiments, and will not be repeated herein.

In addition, reference is made to patent applications No. 202310771124.9, 202310740412.8, 202310855866.X, 202311017132.0, 202311124847.6, and 202311091555.7 for the relevant content of the defining structure.

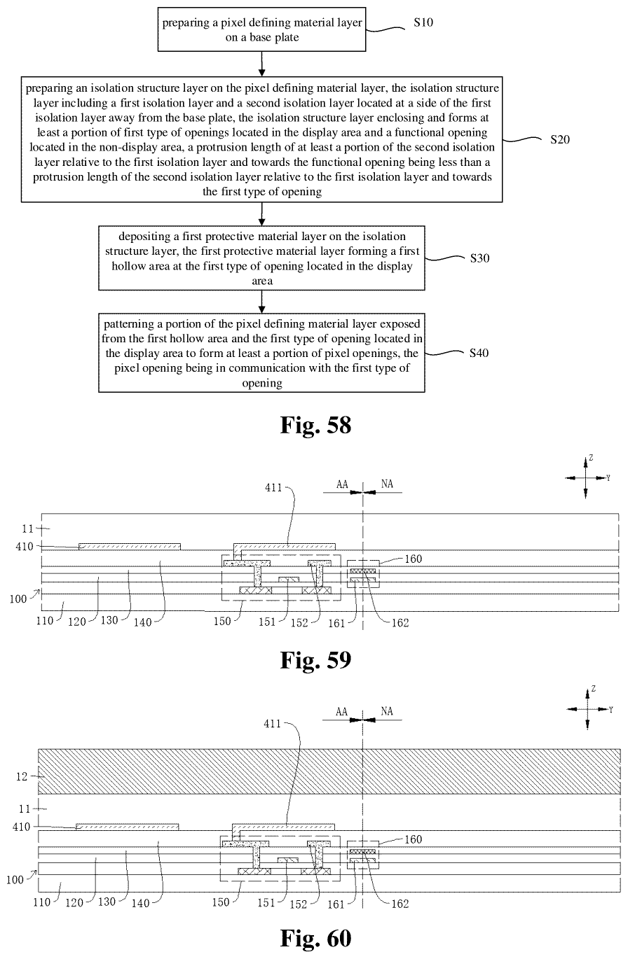

FIG. 58 shows a flow chart of a method for manufacturing the display panel 10 according to an embodiment of the present application, and FIGS. 59 to 65 show schematic diagrams of a preparation process of a method for manufacturing the display panel 10 according to an embodiment of the present application.

Referring to FIGS. 59 to 65 in conjunction with FIG. 58, the embodiments of the third aspect of the present application provide a method for manufacturing the display panel 10, in which the display panel 10 may be the display panel 10 according to any of the above embodiments of the first aspect and has a display area AA and a non-display area NA, and the method includes the following steps S10-S40.

Step S10: as shown in FIG. 59, preparing a pixel defining material layer 11 on a base plate 100.

Step S20: as shown in FIGS. 60 to 63, preparing an isolation structure layer 300 on the pixel defining material layer 11, the isolation structure layer 300 including a first isolation layer 301 and a second isolation layer 302 located at a side of the first isolation layer 301 away from the base plate 100, the isolation structure layer 300 enclosing and forms at least a portion of first type of openings 300a located in the display area AA and a functional opening 300b located in the non-display area NA, a protrusion length of at least a portion of the second isolation layer 302 relative to the first isolation layer 301 and towards the functional opening 300b being less than a protrusion length of the second isolation layer 302 relative to the first isolation layer 301 and towards the first type of opening 300a.

Optionally, the isolation structure layer 300 may be the isolation structure layer 300 in any of the above embodiments, and may include the isolation structure 310, the edge structure 320, and the auxiliary structure 330 in any of the above embodiments.

Optionally, the functional opening 300b may facilitate increasing the light transmittance of the non-display area NA, so that when the display panel 10 is applied to a display apparatus, the photosensitive assembly for sensing light in the display apparatus may be correspondingly arranged under the functional opening, and thus the photosensitive assembly can better sense light through the functional opening.

Step S30: as shown in FIG. 64, depositing a first protective material layer 10a on the isolation structure layer 300, the first protective material layer 10a forming a first hollow area 10aa at the first type of opening 300a located in the display area AA.

Optionally, the first protective material layer 10a may include photoresist.

Step S40, as shown in FIG. 64A, patterning a portion of the pixel defining material layer 11 exposed from the first hollow area 10aa and the first type of opening 300a located in the display area AA to form at least a portion of pixel openings 220, the pixel opening 220 being in communication with the first type of opening 300a.

In the method for manufacturing the display panel 10 according to the embodiments of the present application, by arranging, in step S20, that the protrusion length of at least a portion of the second isolation layer 302 relative to the first isolation layer 301 and towards the functional opening 300b is less than the protrusion length of the second isolation layer 302 relative to the first isolation layer 301 and towards the first type of opening 300a, when the first protective material layer 10a is deposited in step S30, the second isolation layer 302 located at the periphery of the functional opening 300b within the non-display area NA is less likely to block the organic material, and the new material may better fall in the vicinity of the first isolation layer 301 at the periphery of the functional opening 300b. Moreover, when the first protective material layer 10a is deposited in step S30, the second isolation layer 302 with a less protrusion length is less likely to excessively block gas discharging, so that gas is less likely to be retained under the second isolation layer 302 at the periphery of the functional opening 300b, thereby better increasing the structure stability and processing reliability of the display panel 10.

In some optional embodiments, step S20 may include the following steps S21-S24.

Step S21: as shown in FIG. 60, preparing, on the pixel defining material layer 11, a first isolation material layer 12 located in the display area AA and the non-display area NA.

Optionally, the first isolation material layer 12 may participate in forming the first isolation layer 301.

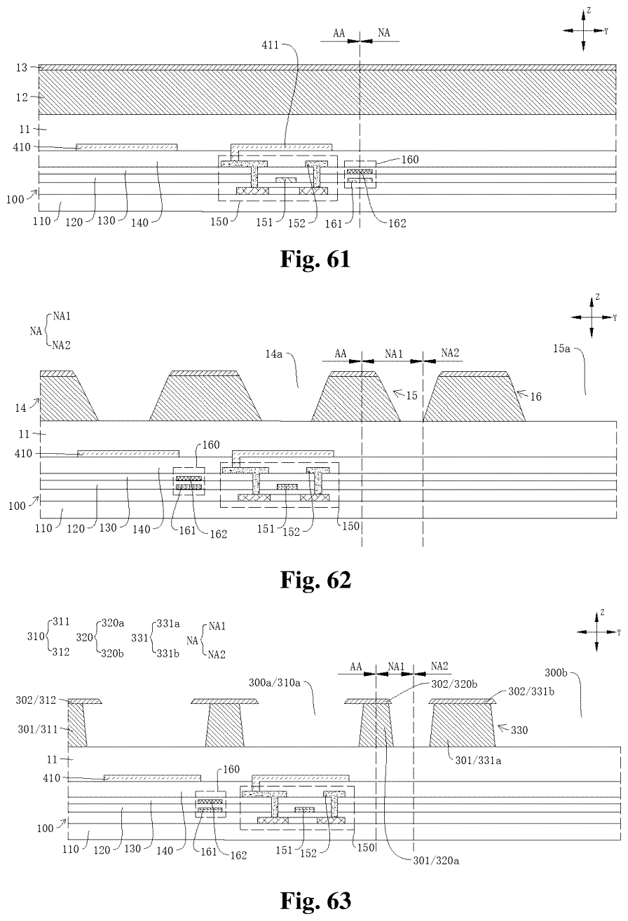

Step S22: as shown in FIG. 61, preparing, on the first isolation material layer 12, a second isolation material layer 13 located in the display area AA and the non-display area NA.

Optionally, the second isolation material layer 13 may participate in forming the second isolation layer 302.

Step S23: as shown in FIG. 62, dry etching the first isolation material layer 12 and the second isolation material layer 13 within the display area AA and the non-display area NA to form an isolation preliminary structure 14 at least partially located in the display area AA, an edge preliminary structure 15 connected with the isolation preliminary structure 14 and located in the non-display area NA, and an auxiliary preliminary structure 16 spaced apart from the edge preliminary structure 15 and located in the non-display area NA, the isolation preliminary structure 14 enclosing and forming an isolation preliminary opening 14a, the edge preliminary structure 15 enclosing and forming a functional preliminary opening 15a, and the auxiliary preliminary structure 16 being located within the functional preliminary opening 15a.

Optionally, the isolation preliminary structure 14 may be configured to form the isolation structure 310 of the isolation structure layer 300, the isolation preliminary opening 14a may be configured to form the isolation opening 310a of the isolation structure 310, the edge preliminary structure 15 may be configured to form the edge structure 320 of the isolation structure layer 300, the functional preliminary opening 15a may be configured to form the functional opening 300b of the edge structure 320, and the auxiliary preliminary structure 16 may be configured to form the auxiliary structure 330.

Optionally, the auxiliary preliminary structure 16 may be closer to the edge preliminary structure 15, so that less etching material is located between the auxiliary preliminary structure 16 and the edge preliminary structure 15 in the subsequent preparation process, and thus the auxiliary preliminary structure 16 may better influence the etching degree of the etching material on the edge preliminary structure 15 in the subsequent preparation process. For example, the auxiliary preliminary structure 16 may better reduce the etching degree of the etching material on the edge preliminary structure 15 in the subsequent preparation process, so as to better facilitate forming, in the subsequent preparation process, the topography in which the protrusion length of at least a portion of the second edge portion 320b relative to the first edge portion 320a and towards the functional opening 300b is less than the protrusion length of the second isolation portion 312 relative to the first isolation portion 311 and towards the isolation opening 310a.

Step S24: as shown in FIG. 63, wet etching the isolation preliminary structure 14, the edge preliminary structure 15, and the auxiliary preliminary structure 16 to form the isolation structure layer 300.

In these optional embodiments, by preparing the auxiliary preliminary structure 16 located within the functional preliminary opening 15a in step S23, when the isolation preliminary structure 14, the edge preliminary structure 15, and the auxiliary preliminary structure 16 are wet etched in step S24, the etching material located within the functional opening 300b can also etch the auxiliary preliminary structure 16, so that auxiliary preliminary structure 16 may restrict the delivery of the etching material within the functional opening 300b towards the edge preliminary structure 15 to better reduce the etching amount of the etching material on the material of the edge preliminary structure 15, and thus the edge preliminary structure 15 is less likely to be damaged by over etching, thereby better increasing the structure stability of the display panel 10. Moreover, the auxiliary preliminary structure 16 not only reduces the etching amount of the etching material on the material of the edge preliminary structure 15, but also can facilitate achieving the topography of the edge structure 320 in the above embodiments. That is, the arrangement of the auxiliary preliminary structure 16 can reduce the etching amount of the etching material on the material of the edge preliminary structure 15, so as to facilitate forming the topography in which the protrusion length of at least a portion of the second isolation layer 302 relative to the first isolation layer 301 and towards the functional opening 300b is less than the protrusion length of the second isolation layer 302 relative to the first isolation layer 301 and towards the first type of opening 300a, and specifically, facilitate forming the topography in which the protrusion length of at least a portion of the second edge portion 320b relative to the first edge portion 320a and towards the functional opening 300b is less than the protrusion length of the second isolation portion 312 relative to the first isolation portion 311 and towards the isolation opening 310a.

In some optional embodiments, the isolation structure layer 300 includes an isolation structure 310 at least partially located in the display area AA, an edge structure 320 connected with the isolation structure 310 and located in the non-display area NA, and an auxiliary structure 330 spaced apart from the edge structure 320 and located in the non-display area NA, as shown in FIG. 46, the auxiliary structure 330 includes a second auxiliary structure 332, and after step S40, the method may include the following step S50.

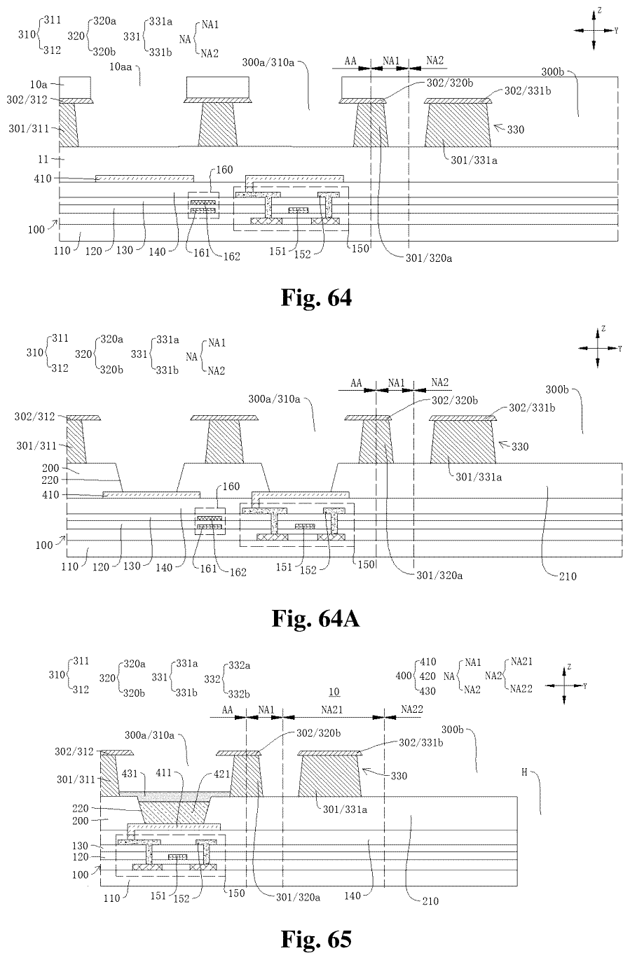

Step S50: as shown in FIGS. 46 and 65, perforating the isolation structure layer 300 and the base plate 100 to remove the second auxiliary structure 332 located within the non-display area NA and a portion of the base plate 100 under the second auxiliary structure 332 and form a functional hole H.

Optionally, the preparation of the light-emitting device 400 in any of the above embodiments may be performed between step S40 and step S50.

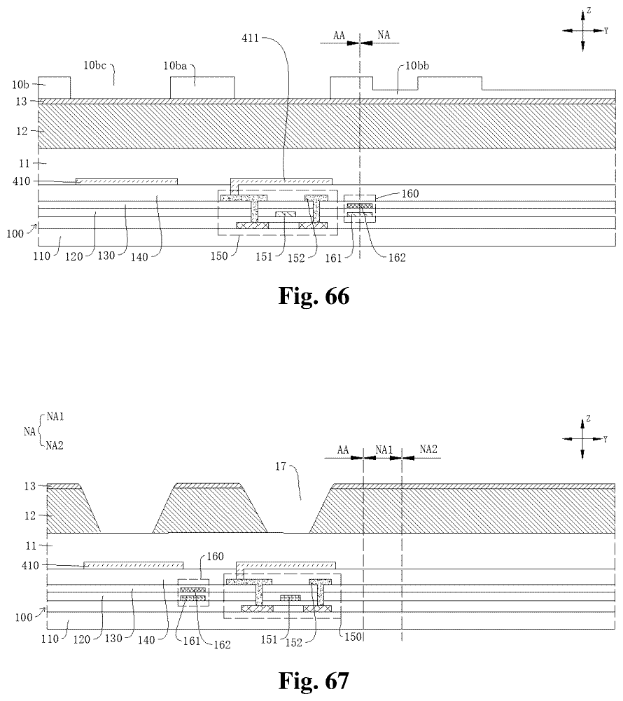

FIG. 66 shows a schematic diagram of a preparation process of a method for manufacturing the display panel 10 according to another embodiment of the present application.

In some optional embodiments, step S20 may include the following steps S21-S24.

Step S21: as shown in FIG. 60, preparing, on the pixel defining material layer 11, a first isolation material layer 12 located in the display area AA and the non-display area NA.

Step S22: as shown in FIG. 61, preparing, on the first isolation material layer 12, a second isolation material layer 13 located in the display area AA and the non-display area NA.

Step S23: as shown in FIG. 66, preparing a second protective material layer 10b at a side of the second isolation material layer 13 away from the base plate 100, the second protective material layer 10b having a second hollow area 10bc, a first thickness area 10ba, and a second thickness area 10bb, a thickness of the second protective material layer 10b located in the first thickness area 10ba being greater than a thickness of the second protective material layer 10b located in the second thickness area 10bb.

Optionally, the second protective material layer 10b may include photoresist.

Optionally, the second protective material layer 10b may be prepared at the side of the second isolation material layer 13 away from the base plate 100 using a half-tone mask plate, so as to facilitate preparing the second protective material layer 10b including the second hollow area 10bc, the first thickness area 10ba, and the second thickness area 10bb.

Optionally, the second hollow area 10bc may be correspondingly arranged above a position in the first isolation material layer 12 and the second isolation material layer 13 at which the first type of opening 300a is to be formed, and the second thickness area 10bb may be correspondingly arranged above a position in the first isolation material layer 12 and the second isolation material layer 13 at which a second type of opening is to be formed.

Step S24: as shown in FIG. 63, patterning film layers under the second hollow area 10bc to form at least a portion of the first type of openings 300a located in the display area AA; removing the second protective material layer 10b within the second thickness area 10bb and retaining a portion of the second protective material layer 10b in the first thickness area, and patterning film layers under the second thickness area 10bb to form the functional opening 300b located in the non-display area NA.

In these optional embodiments, by preparing, in step S23, the second protective material layer 10b having the second hollow area 10bc, the first thickness area 10ba, and the second thickness area 10bb at the side of the second isolation material layer 13 away from the base plate 100, and arranging that the thickness of the second protective material layer 10b located in the first thickness area 10ba is greater than the thickness of the second protective material layer 10b located in the second thickness area 10bb, the etching material may greatly etch, in step S24, the first isolation material layer 12 and the second isolation material layer 13 under the hollow area, so as to form the first type of opening 300a of the first isolation layer 301 with a greater protrusion length at the periphery, while in the second thickness area 10bb, since the etching material may first etch the second protective material layer 10b in the second thickness area 10b, the etching material less etches the first isolation material layer 12 and the second isolation material layer 13 under the second thickness area 10bb, so as to form the functional opening 300b with a less protrusion length at the periphery.

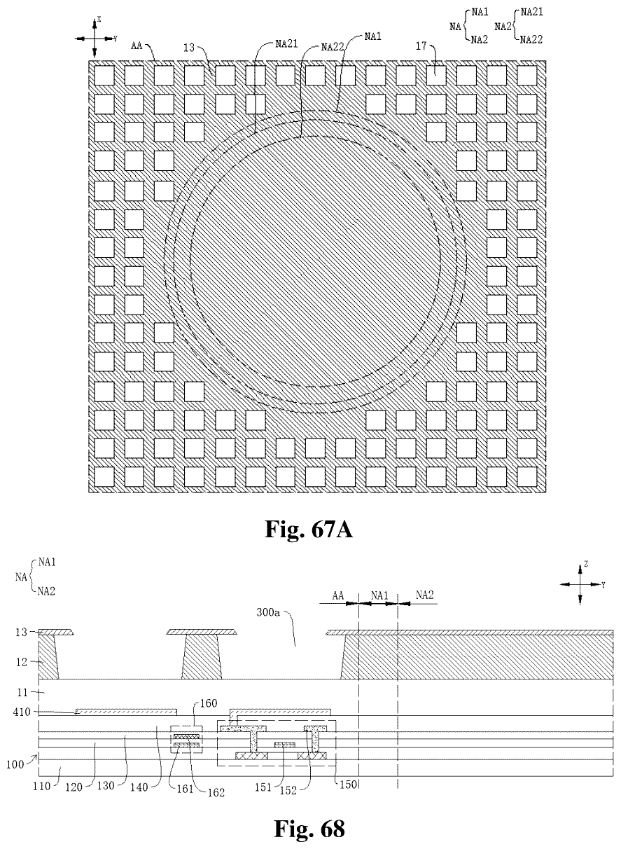

FIGS. 67 to 69 show schematic diagrams of a preparation process of a method for manufacturing the display panel 10 according to yet another embodiment of the present application.

In some optional embodiments, step S20 includes the following steps S21-S25.

Step S21: as shown in FIG. 60, preparing, on the pixel defining material layer 11, a first isolation material layer 12 located in the display area AA and the non-display area NA.

Step S22: as shown in FIG. 61, preparing, on the first isolation material layer 12, a second isolation material layer 13 located in the display area AA and the non-display area NA.

Step S23: as shown in FIGS. 67 and 67A, dry etching the first isolation material layer 12 and the second isolation material layer 13 within the display area AA to form a first type of preliminary opening 17 located within the display area AA.

Optionally, the first type of preliminary opening 17 may be configured to form the first type of opening 300a located within the display area AA.

Step S24: as shown in FIG. 68, wet etching an inner wall of the first type of preliminary opening 17 to form at least a portion of the first type of openings 300a located in the display area AA.

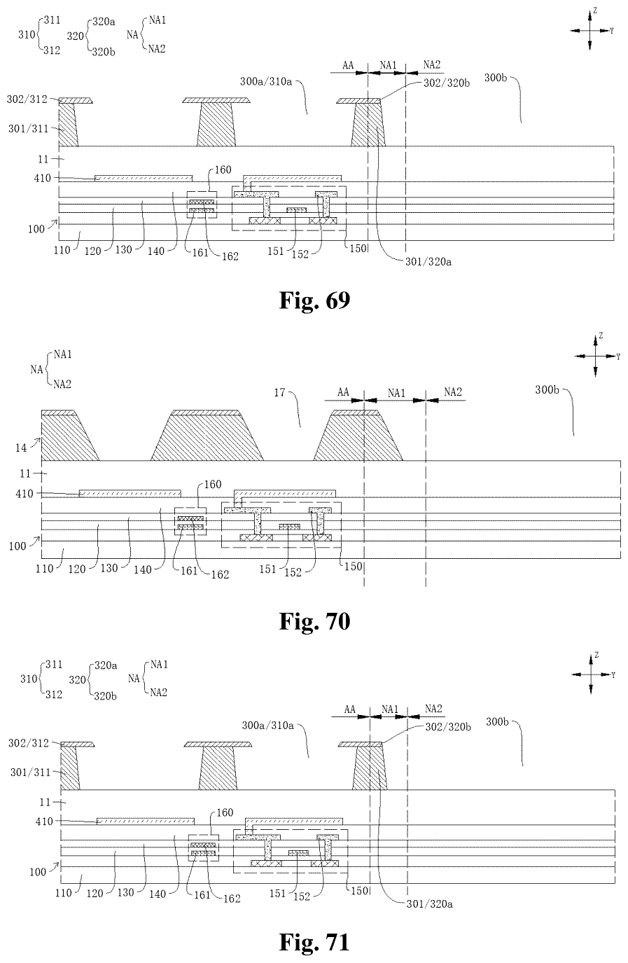

Step S25: as shown in FIG. 69, dry etching the first isolation material layer 12 and the second isolation material layer 13 within the non-display area NA to form the functional opening 300b located in the non-display area NA.

Optionally, step S25 may be performed after step S24, as shown in FIGS. 66 to 69. Optionally, step S25 may be performed before step S23, i.e., the first isolation material layer 12 and the second isolation material layer 13 within the non-display area NA may be dry etched first to form the functional opening 300b located in the non-display area NA, and then steps S23 and S24 are performed sequentially to prepare the first type of opening 300a, which is not limited in the present application.

In these optional embodiments, by separately preparing the first type of opening 300a and the functional opening 300b, the protrusion length of the second isolation layer 302 relative to the first isolation layer 301 and towards the first type of opening 300a and the protrusion length of the second isolation layer 302 relative to the first isolation layer 301 and towards the functional opening 300b may be better regulated individually, so as to facilitate forming the topography in which the protrusion length of at least a portion of the second isolation layer 302 relative to the first isolation layer 301 and towards the functional opening 300b is less than the protrusion length of the second isolation layer 302 relative to the first isolation layer 301 and towards the first type of opening 300a

Moreover, by dry etching the first isolation material layer 12 and the second isolation material layer 13 within the non-display area NA to form the functional opening 300b located in the non-display area NA, the protrusion length of the second edge portion 320b at the periphery of the functional opening 300b relative to the first edge portion 320a and towards the functional opening 300b may be equal to 0, so that when the first protective material layer 10a is formed on the isolation structure layer 300, the gas at the periphery of the functional opening 300b may be better discharged outwardly along the sidewalls of the first edge portion 320a and the second edge portion 320b, thereby better increasing the structure stability and processing reliability of the display panel 10.

FIGS. 70 and 71 show schematic diagrams of a preparation process of a method for manufacturing the display panel 10 according to yet another embodiment of the present application.

In some optional embodiments, step S20 includes the following steps S21-S24.

Step S21: as shown in FIG. 60, preparing, on the pixel defining material layer 11, a first isolation material layer 12 located in the display area AA and the non-display area NA.

Step S22: as shown in FIG. 61, preparing, on the first isolation material layer 12, a second isolation material layer 13 located in the display area AA and the non-display area NA.

Step S23: as shown in FIG. 70, dry etching the first isolation material layer 12 and the second isolation material layer 13 within the display area AA and the non-display area NA to form a first type of preliminary opening 17 located within the display area AA and the functional opening located 300b in the non-display area NA.

Optionally, the first type of preliminary opening 17 may be configured to form the first type of opening 300a.

Optionally, by dry etching the first isolation material layer 12 and the second isolation material layer 13 within the non-display area NA to form the functional opening 300b located in the non-display area NA, the protrusion length of the second edge portion 320b at the periphery of the functional opening 300b relative to the first edge portion 320a and towards the functional opening 300b may be equal to 0, so that when the first protective material layer 10a is formed on the isolation structure layer 300, the gas at the periphery of the functional opening 300b may be better discharged outwardly along the sidewalls of the first edge portion 320a and the second edge portion 320b, thereby better increasing the structure stability and processing reliability of the display panel 10.

Step S24: as shown in FIG. 71, wet etching an inner wall of the first type of preliminary opening 17 to form at least a portion of the first type of openings 300a located in the display area AA.

In these optional embodiments, by simultaneously preparing the first type of preliminary opening 17 and the functional opening 300b in step S23, the manufacturing efficiency of the display panel 10 can be better increased. By wet etching only the inner wall of the first type of preliminary opening 17 in step S24, the etching material will not damage the inner wall of the functional opening 300b, thereby facilitating forming the topography in which the protrusion length of at least a portion of the second isolation layer 302 relative to the first isolation layer 301 and towards the functional opening 300b is less than the protrusion length of the second isolation layer 302 relative to the first isolation layer 301 and towards the first type of opening 300a

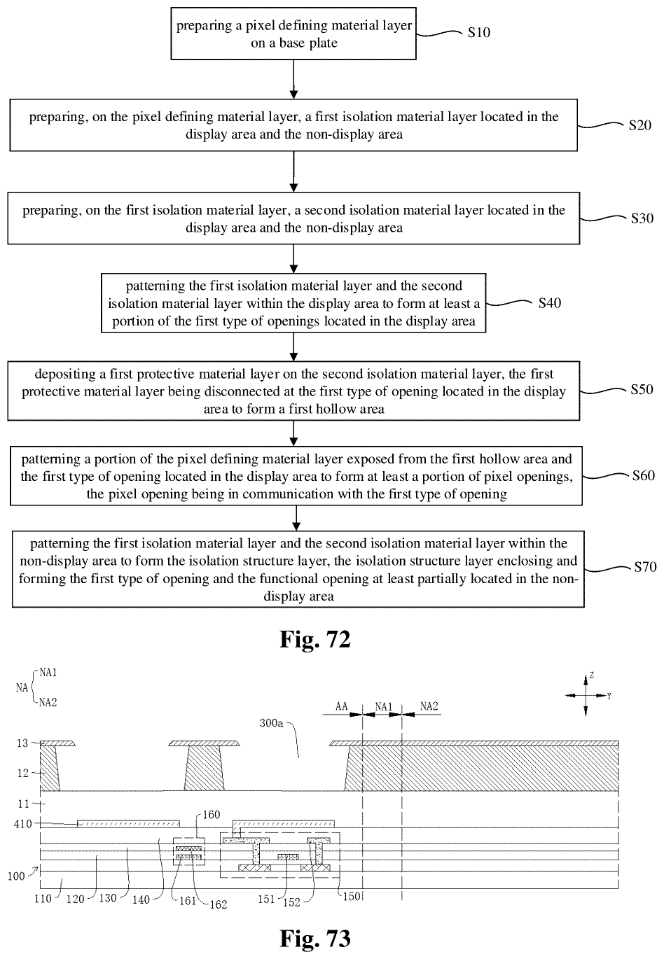

FIG. 72 shows a flow chart of a method for manufacturing the display panel 10 according to another embodiment of the present application, and FIGS. 73 to 77 show schematic diagrams of a preparation process of a method for manufacturing the display panel 10 according to yet another embodiment of the present application.

Referring to FIGS. 73 to 77 in conjunction with FIG. 72, the embodiments of the third aspect of the present application further provide a method for manufacturing the display panel 10, in which the display panel 10 may be the display panel 10 according to any of the above embodiments of the first aspect and has a display area AA and a non-display area NA, and the method includes the following steps S10-S70.

Step S10: as shown in FIG. 59, preparing a pixel defining material layer 11 on a base plate 100.

Step S20: as shown in FIG. 60, preparing, on the pixel defining material layer 11, a first isolation material layer 12 located in the display area AA and the non-display area NA.

Step S30: as shown in FIG. 61, preparing, on the first isolation material layer 12, a second isolation material layer 13 located in the display area AA and the non-display area NA.

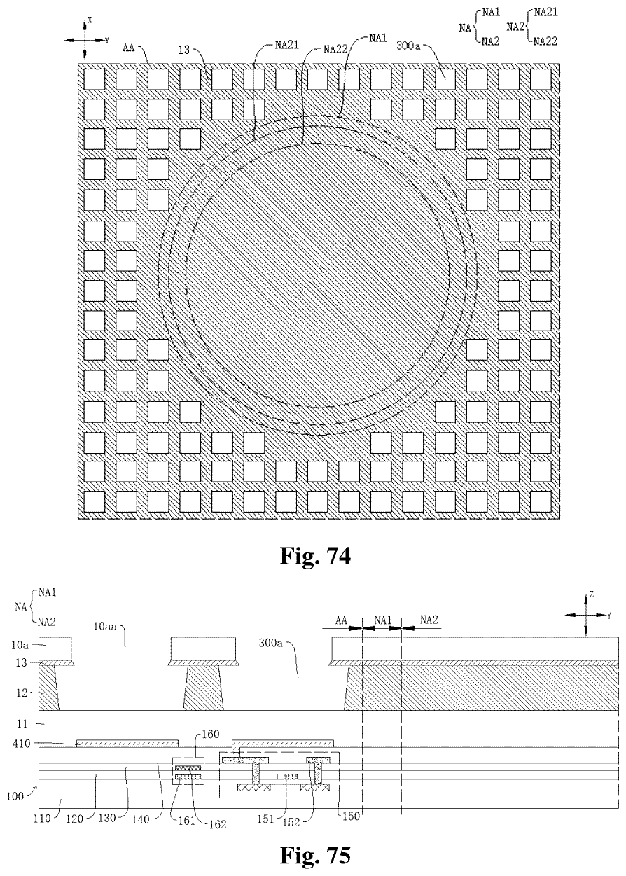

Step S40: as shown in FIGS. 73 and 74, patterning the first isolation material layer 12 and the second isolation material layer 13 within the display area AA to form at least a portion of the first type of openings 300a located in the display area AA.

Step S50: as shown in FIG. 75, depositing a first protective material layer 10a on the second isolation material layer 13, the first protective material layer 10a forming a first hollow area 10aa at the first type of opening 300a located in the display area AA.

Optionally, the first protective material layer 10a may include the photoresist.

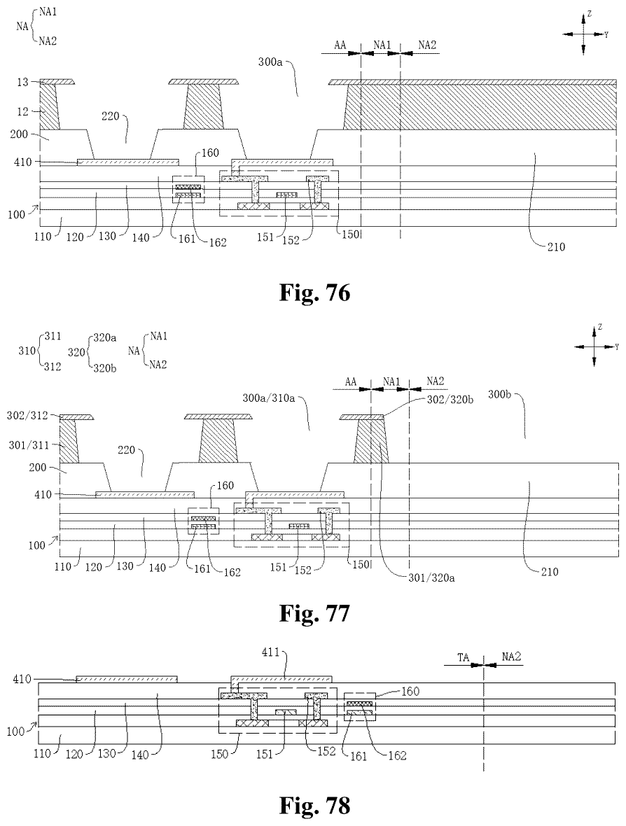

Step S60, as shown in FIG. 76, patterning a portion of the pixel defining material layer 11 exposed from the first hollow area 10aa and the first type of opening 300a located in the display area AA to form at least a portion of pixel openings 220, the pixel opening 220 being in communication with the first type of opening 300a.

Step S70, as shown in FIG. 77, patterning the first isolation material layer 12 and the second isolation material layer 13 within the non-display area NA to form the isolation structure layer 300, the isolation structure layer 300 enclosing and forming the first type of opening 300a and the functional opening 300b at least partially located in the non-display area NA.

Optionally, in step S70, the first isolation material layer 12 and the second isolation material layer 13 within the non-display area NA may be dry etched to form the functional opening 300b, so as to increase the manufacturing efficiency of the display panel 10.

In these optional embodiments, by preparing the pixel opening 220 before step S70, the surface of the second isolation material layer 13 away from the base plate 100 can be relatively flat before step S70, so that when the first protective material layer 10a is deposited in step S50, gas is less likely to be retained between the first protective material layer 10a and the second isolation material layer 13, thereby better increasing the structure stability and processing reliability of the display panel 10.

FIGS. 78 to 82 show schematic diagrams of a preparation process of a method for manufacturing the display panel 10 according to yet another embodiment of the present application, and FIG. 83 shows a flow chart of a method for manufacturing the display panel 10 according to yet another embodiment of the present application.

The embodiments of the third aspect of the present application further provide a method for manufacturing the display panel 10, referring to FIG. 83 in conjunction with FIGS. 78 to 82, the display panel 10 may be the display panel 10 according to any of the above embodiments of the first aspect and may have a first specific area TA and a second area NA2, and the method includes the following steps S01-S05.

Step S01: as shown in FIG. 78, preparing a first electrode layer 410 on the base plate 100, the first electrode layer 410 including at least two first electrodes 411 spaced apart.

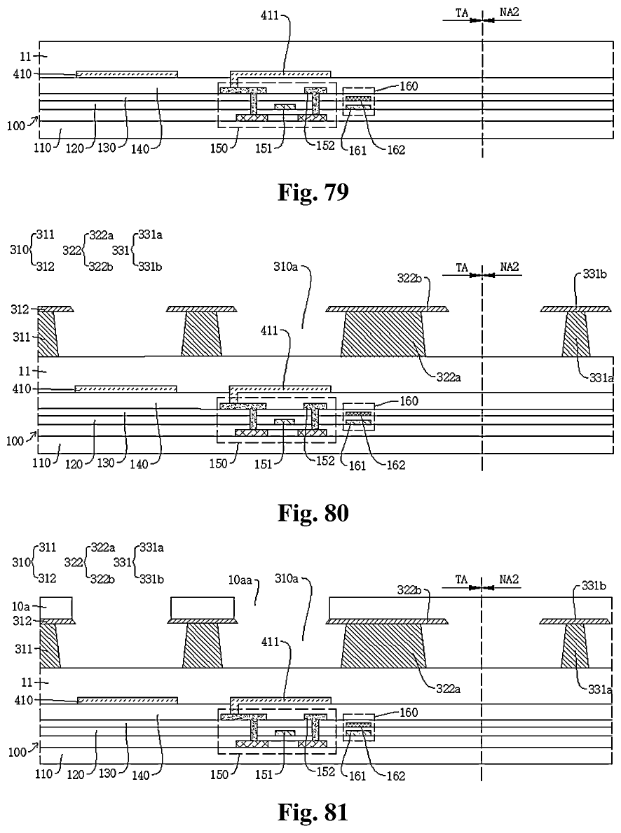

Step S02: as shown in FIG. 79, preparing a pixel defining material layer 11 on the first electrode layer 410.

Step S03: as shown in FIG. 80, preparing an isolation structure 310 and a convex structure 322 on the pixel defining material layer 11 to form a base, the isolation structure 310 being located in the first specific area TA and enclosing and forming an isolation opening 310a, and the convex structure 322 being connected with the isolation structure 310 and arranged at a side of the isolation structure 310 towards the second area NA2.

Optionally, step S03 may further include: preparing a first auxiliary structure 331 on the pixel defining material layer 11, in which the first auxiliary structure 331 may be arranged at a side of the convex structure 322 away from the isolation structure 310 and located within the second area NA2.

Step S04: as shown in FIG. 81, depositing a first protective material layer 10a on the base, the first protective material layer 10a forming a first hollow area 10aa at the isolation opening 310a.

Herein, the first protective material layer 10a may be configured to protect the underlying film layer structure, so that the film layer structure under the first protective material layer 10a is less likely to be etched by the etching material, while the film layer structure not covered by the first protective material layer 10a may be etched by the etching material. For example, the etching material may etch, through the first hollow area 10a formed at the position where the first protective material layer 10a is disconnected, the pixel defining material layer 11 exposed from the first hollow area 10aa and the isolation opening 310a. Optionally, the material of the first protective material layer 10a includes an organic material. For example, the material of the first protective material layer 10a may include photoresist.

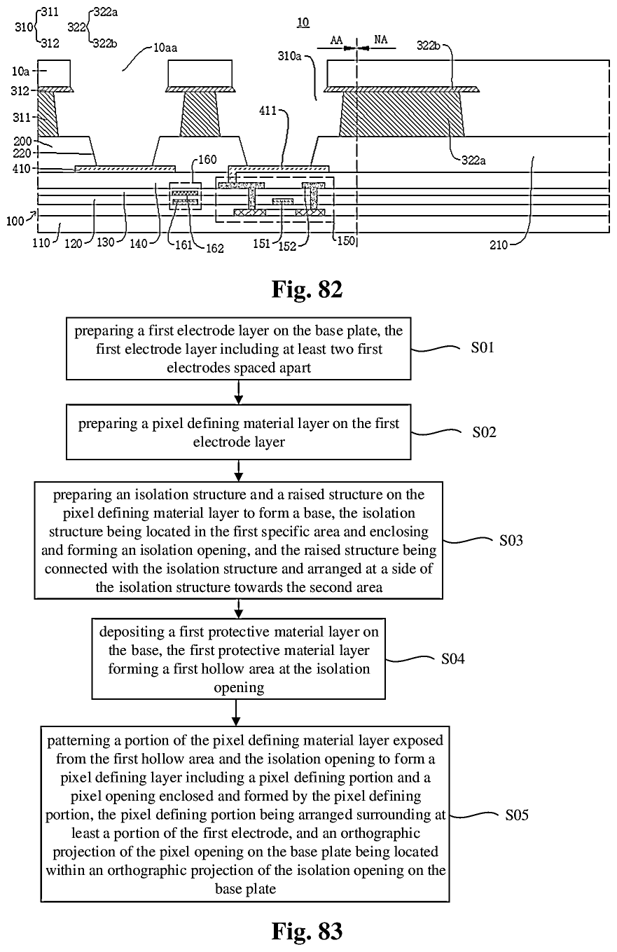

Step S05: as shown in FIG. 82, patterning a portion of the pixel defining material layer 11 exposed from the first hollow area 10aa and the isolation opening 310a to form a pixel defining layer 200 including a pixel defining portion 210 and a pixel opening 220 enclosed and formed by the pixel defining portion 210, the pixel defining portion 210 being arranged surrounding at least a portion of the first electrode 411, and an orthographic projection of the pixel opening 220 on the base plate 100 being located within an orthographic projection of the isolation opening 310a on the base plate 100.

In the method for manufacturing the display panel 10 according to the embodiments of the present application, by patterning the pixel defining material layer 11 after the isolation structure 310 and the convex structure 322 are prepared, when the material of the isolation structure 310 and the convex structure 322 are etched, the first electrode 411 is less likely to be damaged by the etching material which is blocked by the pixel defining material layer 11. Herein, when the first protective material layer 10a is deposited before the pixel defining material layer 11 is patterned, under the extrusion force of the deposited material of the first protective material layer 10a, the gas between the material of the first protective material layer 10a and the edge of the isolation structure 310 towards the second area NA2, the gas between the material of the first protective material layer 10a and the convex structure 322, or the gas between the material of the first protective material layer 10a and the base plate 100 may be discharged outwardly, under the guide of the convex structure 322, from the edge of the convex structure 322, thereby better increasing the structure stability of the display panel 10.

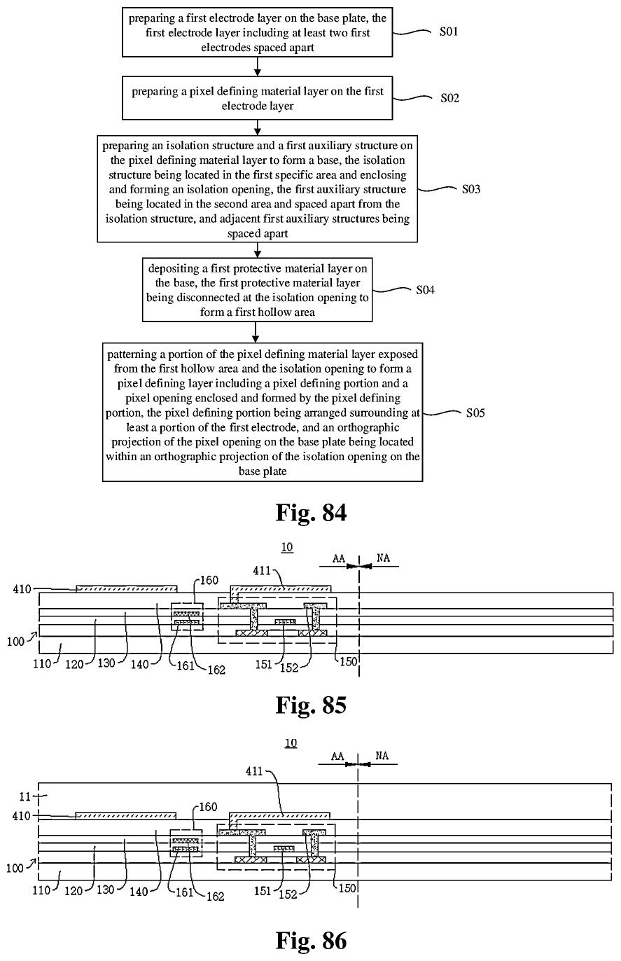

FIG. 84 shows a flow chart of a method for manufacturing the display panel 10 according to yet another embodiment of the present application.

The embodiments of the third aspect of the present application further provide a method for manufacturing the display panel 10, referring to FIG. 84 in conjunction with FIGS. 78 to 82, the display panel 10 may be the display panel 10 according to any of the above embodiments of the first aspect and may have a first specific area TA and a second area NA2, and the method includes the following steps S01-S05.

Step S01: as shown in FIG. 78, preparing a first electrode layer 410 on the base plate 100, the first electrode layer 410 including at least two first electrodes 411 spaced apart.

Step S02: as shown in FIG. 79, preparing a pixel defining material layer 11 on the first electrode layer 410.

Step S03: as shown in FIG. 80, preparing an isolation structure 310 and a first auxiliary structure 331 on the pixel defining material layer 11 to form a base, the isolation structure 310 being located in the first specific area TA and enclosing and forming an isolation opening 310a, the first auxiliary structure 331 being located in the second area NA2 and spaced apart from the isolation structure 310, and adjacent first auxiliary structures 331 being spaced apart.

Optionally, step S03 may further include: preparing a convex structure 322 on the pixel defining material layer 11, in which the convex structure 322 may be connected with the isolation structure 310 and arranged at a side of the isolation structure 310 towards the second area NA2.

Step S04: as shown in FIG. 81, depositing a first protective material layer 10a on the base, the first protective material layer 10a forming a first hollow area 10aa at the isolation opening 310a.

Herein, the first protective material layer 10a may be configured to protect the underlying film layer structure, so that the film layer structure under the first protective material layer 10a is less likely to be etched by the etching material, while the film layer structure not covered by the first protective material layer 10a may be etched by the etching material. For example, the etching material may etch, through the first hollow area 10a formed at the position where the first protective material layer 10a is disconnected, the pixel defining material layer 11 exposed from the first hollow area 10aa and the isolation opening 310a. Optionally, the material of the first protective material layer 10a includes an organic material. For example, the material of the first protective material layer 10a may include photoresist.

Step S05: as shown in FIG. 82, patterning a portion of the pixel defining material layer 11 exposed from the first hollow area 10aa and the isolation opening 310a to form a pixel defining layer 200 including a pixel defining portion 210 and a pixel opening 220 enclosed and formed by the pixel defining portion 210, the pixel defining portion 210 being arranged surrounding at least a portion of the first electrode 411, and an orthographic projection of the pixel opening 220 on the base plate 100 being located within an orthographic projection of the isolation opening 310a on the base plate 100.

In the method for manufacturing the display panel 10 according to the embodiments of the present application, by patterning the pixel defining material layer 11 after the isolation structure 310 and the first auxiliary structure 331 are prepared, when the material of the isolation structure 310 and the first auxiliary structure 331 are etched, the first electrode 411 is less likely to be damaged by the etching material which is blocked by the pixel defining material layer 11. Herein, when the first protective material layer 10a is deposited before the pixel defining material layer 11 is patterned, under the extrusion force of the deposited material of the first protective material layer 10a, the gas between the material and the first auxiliary structure 331 or the gas between the material and the base plate 100 may be discharged outwardly, under the guide of the spacing between the adjacent first auxiliary structures 331, from the edge of the first auxiliary structure 331, thereby better increasing the processing reliability of the display panel 10.

Reference is made e to patent applications No. PCT/CN2023/134518, CN202310619767.1, CN202310492119.4, CN202311346196.5, CN202310775778.9, which are incorporated herein by reference, for the relevant technical solutions, e.g., structure, material, and preparation method, of the isolation structure (also referred to as the partition structure).

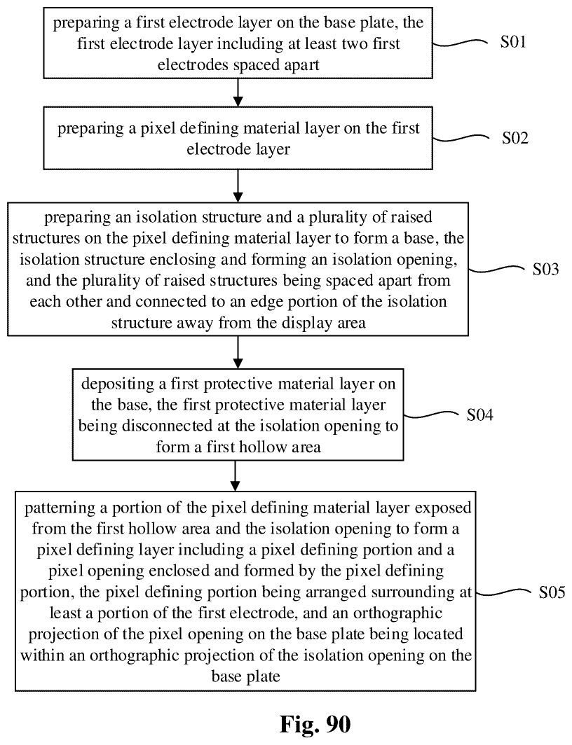

FIGS. 85 to 89 show schematic diagrams of a preparation process of a method for manufacturing the display panel 10 according to yet another embodiment of the present application, and FIG. 90 shows a flow chart of a method for manufacturing the display panel 10 according to yet another embodiment of the present application.

The embodiments of the third aspect of the present application provide a method for manufacturing the display panel 10, referring to FIG. 90 in conjunction with FIGS. 85 to 89, the display panel 10 may be the display panel 10 according to any of the above embodiments of the first aspect and may have a display area AA and a non-display area NA that are adjacent, and the method includes the following steps S01-S05.

Step S01: as shown in FIG. 85, preparing a first electrode layer 410 on the base plate 100, the first electrode layer 410 including at least two first electrodes 411 spaced apart.

Step S02: as shown in FIG. 86, preparing a pixel defining material layer 11 on the first electrode layer 410.

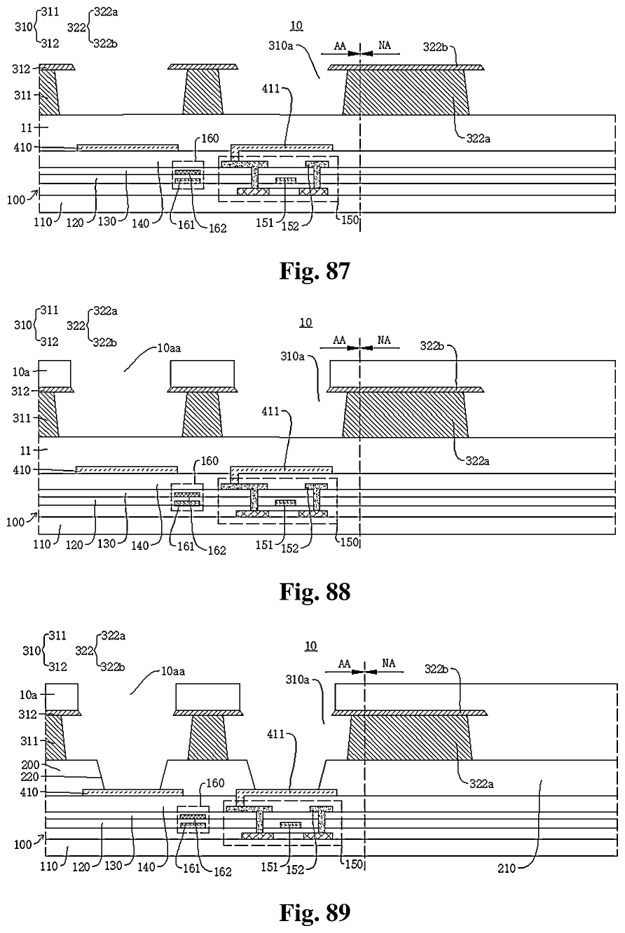

Step S03: as shown in FIG. 87, preparing an isolation structure 310 and a plurality of convex structures 322 on the pixel defining material layer 11 to form a base, the isolation structure 310 enclosing and forming an isolation opening 310a, and the plurality of convex structures 322 being spaced apart from each other and connected to an edge portion of the isolation structure 310 away from the display area AA.

Step S04: as shown in FIG. 88, depositing a first protective material layer 10a on the base, the first protective material layer 10a forming a first hollow area 10aa at the isolation opening 310a.

Herein, the first protective material layer 10a may be configured to protect the underlying film layer structure, so that the film layer structure under the first protective material layer 10a is less likely to be etched by the etching material, while the film layer structure not covered by the first protective material layer 10a may be etched by the etching material. For example, the etching material may etch, through the first hollow area 10a formed at the position where the first protective material layer 10a is disconnected, the pixel defining material layer 11 exposed from the first hollow area 10aa and the isolation opening 310a. Optionally, the material of the first protective material layer 10a includes an organic material. For example, the material of the first protective material layer 10a may include photoresist.

Step S05: as shown in FIG. 89, patterning a portion of the pixel defining material layer 11 exposed from the first hollow area 10aa and the isolation opening 310a to form a pixel defining layer 200 including a pixel defining portion 210 and a pixel opening 220 enclosed and formed by the pixel defining portion 210, the pixel defining portion 210 being arranged surrounding at least a portion of the first electrode 411, and an orthographic projection of the pixel opening 220 on the base plate 100 being located within an orthographic projection of the isolation opening 310a on the base plate 100.

In the method for manufacturing the display panel 10 according to the embodiments of the present application, by patterning the pixel defining material layer 11 after the isolation structure 310 and the convex structure 322 are prepared, when the material of the isolation structure 310 and the convex structure 322 are etched, the first electrode 411 is less likely to be damaged by the etching material which is blocked by the pixel defining material layer 11. Herein, when the first protective material layer 10a is deposited before the pixel defining material layer 11 is patterned, under the extrusion force of the deposited material of the first protective material layer 10a, the gas between the material of the first protective material layer 10a and the edge portion of the isolation structure 310 away from the display area AA, the gas between the material of the first protective material layer 10a and the convex structure 322, or the gas between the material of the first protective material layer 10a and the base plate 100 may be discharged outwardly, under the guide of the convex structure 322, from the edge of the convex structure 322, thereby better increasing the structure stability of the display panel 10.

Reference is made to patent applications No. PCT/CN2023/134518, CN202310619767.1, CN202310492119.4, CN202311346196.5, CN202310775778.9, which are incorporated herein by reference, for the relevant technical solutions, e.g., structure, material, and preparation method, of the isolation structure (also referred to as the partition structure, etc.).

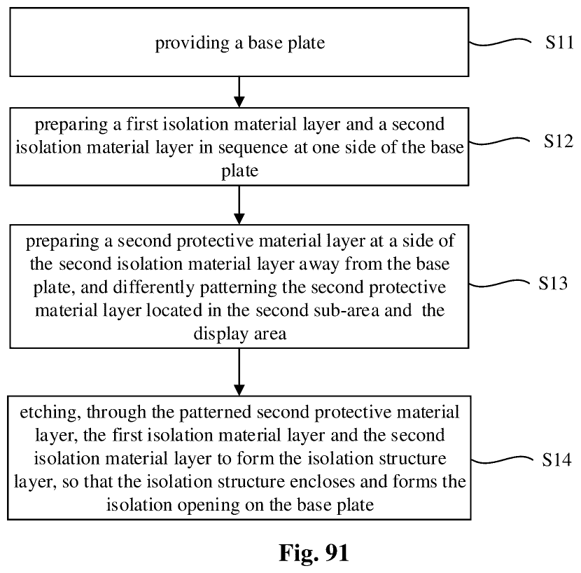

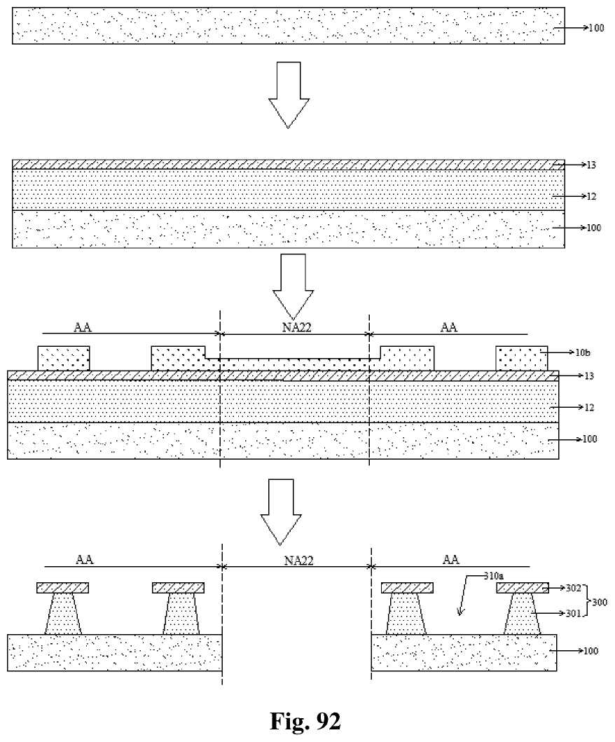

Based on the same inventive concept, the embodiments of the third aspect of the present application further provide a method for manufacturing a display panel. Referring to FIGS. 91 and 92, in which FIG. 91 shows a flow chart of a method for manufacturing a display panel according to an embodiment of the present application, and FIG. 92 shows a process flow chart corresponding to FIG. 91. The method for manufacturing a display panel is described in detail below in conjunction with FIGS. 91 and 92.

Step S11: providing a base plate 100.

In the embodiments, the base plate 100 is a multi-film layer structure and includes at least a plurality of metal layers and an insulating layer located between adjacent metal layers, and a pixel circuit for providing a driving signal for a light-emitting device is formed within the base plate 100.

Step S12: preparing a first isolation material layer 12 and a second isolation material layer 13 in sequence at one side of the base plate 100.

In the step, the first isolation material layer 12 is first prepared at one side of the base plate 100, and then the second isolation material layer 13 is prepared at a side of the first isolation material layer 12 away from the base plate 100, in which the film thickness of the first isolation material layer 12 is greater than the film thickness of the second isolation material layer 13. Exemplarily, the first isolation material layer 12 is a layer of aluminum, and the second isolation material layer 13 is a layer of titanium.

In step S13, preparing a second protective material layer 10b at a side of the second isolation material layer 13 away from the base plate 100, and differently patterning the second protective material layer 10b located in the second sub-area NA22 and the display area AA.

By differently patterning the photoresist layer in the display area AA and the second sub-area NA22, the topography when forming the isolation structure in subsequent etching can be adjusted and controlled. Exemplarily, in the embodiments, the photoresist layer at the position corresponding to the isolation opening in the display area AA may be removed, and the photoresist layer corresponding to the aperture area may be thinned.

Step S14: etching, through the patterned second protective material layer 10b, the first isolation material layer 12 and the second isolation material layer 13 to form the isolation structure layer 300, so that the isolation structure 310 encloses and forms the isolation opening 310a on the base plate 100.

The first isolation material layer 12 is etched to form the first isolation layer 301, and the second isolation material layer 13 is etched to form the second isolation material layer 302. In the isolation structure layer 300 surrounding the second sub-area NA22, a protrusion length of a side of the second isolation material layer 302 towards the second sub-area NA22 relative to the first isolation layer 301 is less than a protrusion length of a side of the second isolation material layer 302 away from the second sub-area NA22 relative to the first isolation layer 301. Herein, the protrusion length of the second isolation material layer 302 relative to the first isolation layer 301 refers to a protrusion length of an orthographic projection of the second isolation material layer 302 on the base plate 100 relative to an orthographic projection of the first isolation layer 301 on the base plate 100. For example, the protrusion length of the side of the second isolation material layer 302 towards the second sub-area NA22 relative to the first isolation layer 301 refers to the protrusion length, in the direction towards the second sub-area NA22, of the orthographic projection of the second isolation material layer 302 on the base plate 100 relative to the orthographic projection of the first isolation layer 301 on the base plate 100.

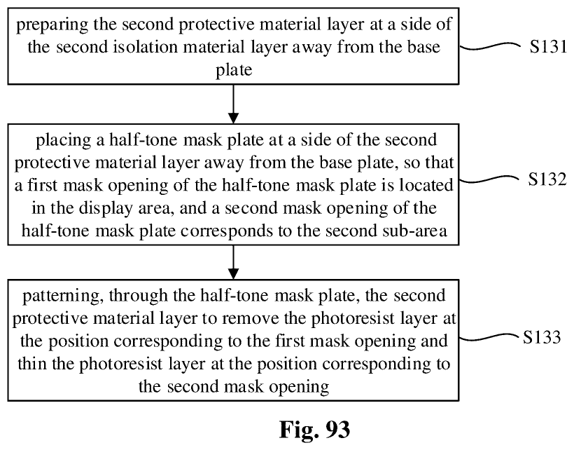

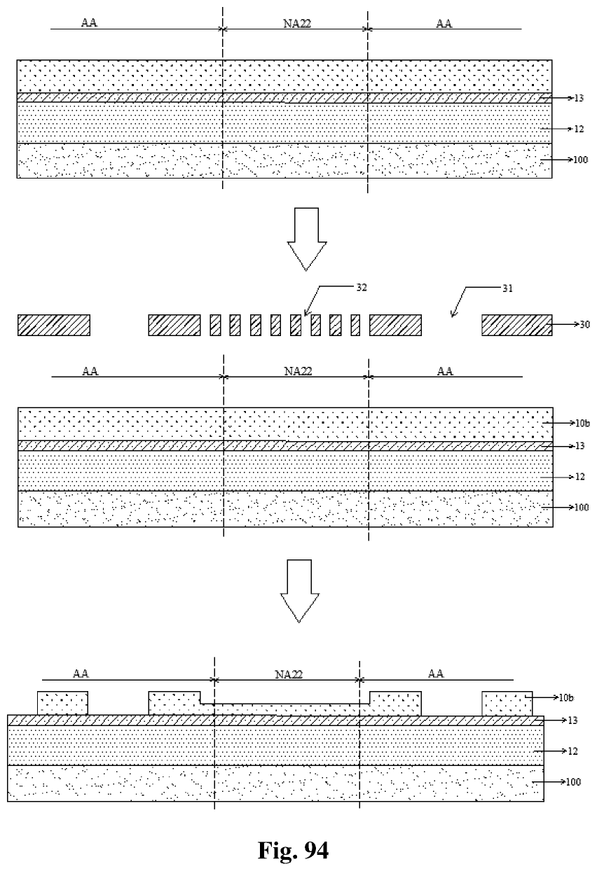

Further, referring to FIGS. 93 and 94, in the embodiments, step S13 may be performed by the following steps S131-S133.

Step S131: preparing the second protective material layer 10b at a side of the second isolation material layer 13 away from the base plate 100.

Step S132: placing a half-tone mask plate 30 at a side of the second protective material layer 10b away from the base plate 100, so that a first mask opening 31 of the half-tone mask plate 30 is located in the display area AA, and a second mask opening 32 of the half-tone mask plate 30 corresponds to the second sub-area NA22.

Herein, the light transmittance of the first mask opening 31 is greater than the light transmittance of the second mask opening 32, the first mask opening 31 corresponds to the isolation opening in the display area, and the second mask opening 32 corresponds to at least the second sub-area NA22.

Step S133: patterning, through the half-tone mask plate 30, the second protective material layer 10b to remove the photoresist layer at the position corresponding to the first mask opening 31 and thin the photoresist layer at the position corresponding to the second mask opening 32.

In the above method, only one half-tone mask plate 30 is required to differently pattern the photoresist layer in the display area and the aperture area, and thus there is no need to separately pattern the display area and the aperture area using two different mask plates, which may simply the process step and reduce one mask plate, and reduce the manufacturing cost of the display panel.

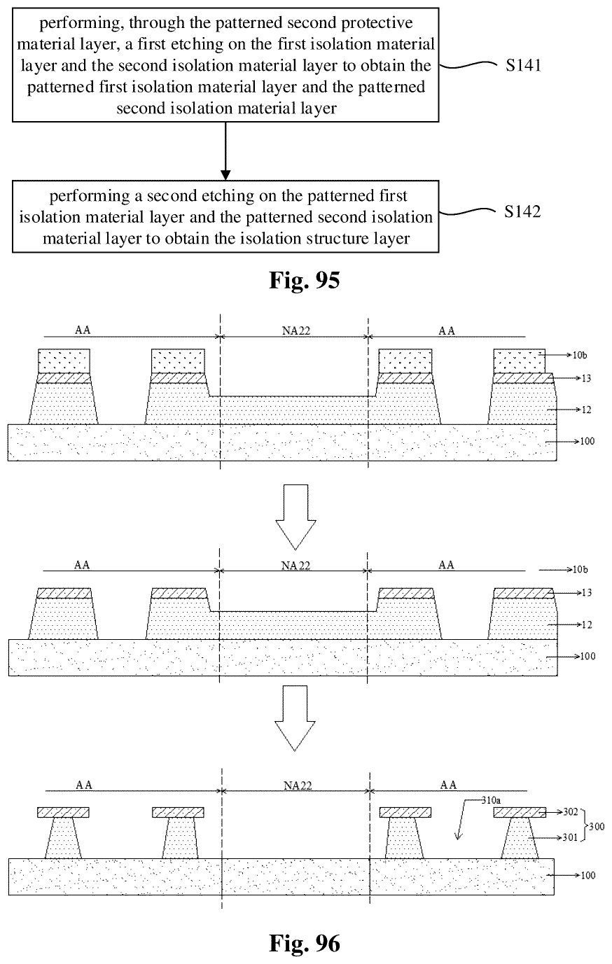

In the embodiments, referring to FIGS. 95 and 96, step S14 may be performed by the following steps S141-S142.

Step S141: performing, through the patterned second protective material layer 10b, a first etching on the first isolation material layer 12 and the second isolation material layer 13 to obtain the patterned first isolation material layer 12 and the patterned second isolation material layer 13.

The first etching is a dry etching and mainly configured to form the general topography of the isolation structure. Specifically, in the display area AA, since the photoresist layer at the position corresponding to the isolation opening is etched and removed, the etching gas may directly act on the first isolation material layer 12 and the second isolation material layer 13 to etch through the first isolation material layer 12 and the second isolation material layer 13; in the second sub-area NA22, the thinned photoresist layer exists, the etching gas may first etch and remove the thinned photoresist layer, and then etch the first isolation material layer 12 and the second isolation material layer 13. Exemplarily, in the second sub-area NA22, the etching gas etches the first isolation material layer 12 and a portion of the second isolation material layer 13.

Step S142: performing a second etching on the patterned first isolation material layer 12 and the patterned second isolation material layer 13 to obtain the isolation structure layer 300.

The second etching is a wet etching and mainly configured to further etch to form an undercut structure based on the formed general topography of the isolation structure, so as to obtain the final isolation structure layer 300. Specifically, in the display area AA, the etching solution laterally etches the second isolation material layer 13; in the second sub-area NA22, the etching solution laterally and downwardly etches the second isolation material layer 13. In the embodiments, the rate at which the etching solution laterally etches the second isolation material layer 13 in the second sub-area NA22 may be less than the rate at which the etching solution laterally etches the second isolation material layer 13 in the display area AA. Therefore, the isolation structure layer 300 close to the second sub-area NA22 has the following structural feature, i.e., the protrusion length of a side of the second isolation material layer 302 towards the second sub-area NA22 relative to the first isolation layer 301 is less than the protrusion length of a side of the second isolation material layer 302 away from the second sub-area NA22 relative to the first isolation layer 301.

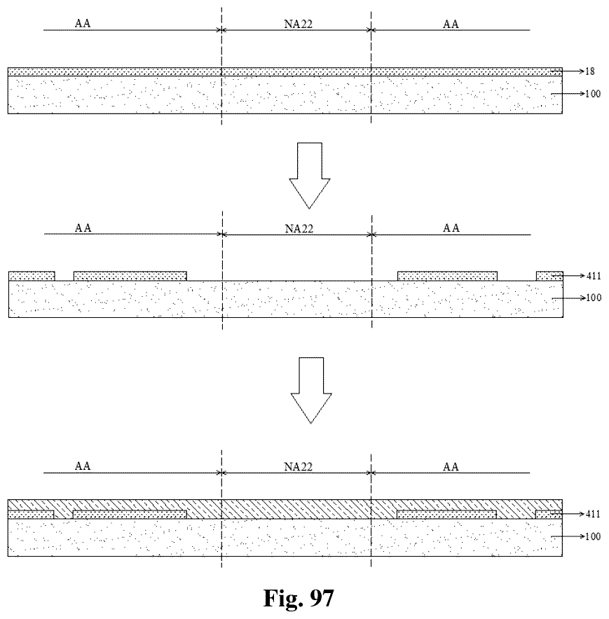

Further, referring to FIG. 97, in the embodiments, the method for manufacturing a display panel according to the embodiments may further include the following steps before step S12.

First, a metal layer 18 is formed at one side of the base plate 100.

Next, the metal layer 18 is patterned to form the first electrode 411 of the light-emitting device.

Then, a pixel defining layer 200 is prepared at a side of the base plate 100 with the first electrode 411.

Further, in the embodiments, the method for manufacturing a display panel according to the embodiments may further include, after step S14: patterning the pixel defining layer located within the isolation opening to form a pixel opening to expose the first electrode from the pixel opening.

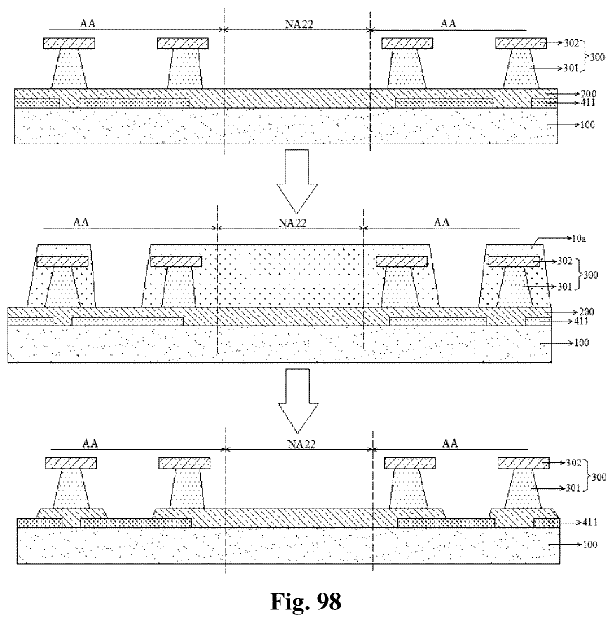

Referring to FIG. 98, this step may be specifically achieved as follows.

First, a first protective material layer 10a is deposited at a side of the pixel defining layer 200 away from the base plate 100.

Since the isolation structure formed as above has the structural feature that the protrusion length of a side of the second isolation material layer 302 towards the second sub-area NA22 relative to the first isolation layer 301 is less than the protrusion length of a side of the second isolation material layer 302 away from the second sub-area NA22 relative to the first isolation layer 301, in the second sub-area NA22, air may not be excessively accumulated during the deposition of the first protective material layer 10a, which otherwise causes process defect.

Next, the first protective material layer 10a is patterned, the first protective material layer 10a placed within the isolation opening is removed, the pixel defining layer 200 located within the isolation opening is exposed, the exposed pixel defining layer 200 is etched to obtain the pixel opening, and the first electrode is exposed from the pixel opening.

In the embodiments, the method for manufacturing a display panel according to the embodiments further includes the following steps.

First, a light-emitting material layer and a second electrode layer are vapor deposited in sequence to form a light-emitting device at the pixel opening.

Next, the film layer corresponding to the aperture area is cut and removed.

In the method for manufacturing a display panel as described above, the prepared isolation structure has the feature that the protrusion length of a side of the second isolation portion towards the aperture area relative to the first isolation portion is less than the protrusion length of a side of the second isolation portion away from the second sub-area NA22 relative to the first isolation portion, so that when the photoresist layer is prepared on the isolation structure, the isolation structure located at the periphery of the aperture area can release at least a portion of the gas in the photoresist layer located in the aperture area, thereby reducing process defect and ensuring the display effect of the display panel.

The embodiments of the fourth aspect of the present application provide a display apparatus including the display panel 10 of any of the above implementations or the display panel 10 manufactured by the method of any of the above implementations. Since the display device according to the embodiments of the fourth aspect of the present application includes the display panel 10 of any of the above embodiments of the first aspect and the display panel 10 manufactured by the method of any of the above implementations of the third aspect, the display device according to the embodiments of the fourth aspect of the present application has the beneficial effects of the display panel 10 of any of the above embodiments of the first aspect and the display panel 10 manufactured by the method of any of the above implementations of the third aspect, which will not be repeated herein.

The display apparatus in the embodiments of the present application includes, but is not limited to, a cell phone, a Personal Digital Assistant (PDA), a tablet computer, an e-book, a TV, a door access control, a smart landline phone, a console, and other devices with display function.

Optionally, the light transmittance of the display panel 10 within at least a portion of the non-display area NA may be greater than the light transmittance of the display panel 10 within the display area AA. The display apparatus may further include a photosensitive assembly arranged corresponding to the functional opening of the display panel 10 and configured to sense light. For example, the display apparatus may include a photosensitive assembly arranged at the functional hole H.

Optionally, the type of the photosensitive assembly may be set in various ways. For example, the photosensitive assembly may include at least one of a distance sensor, a camera, an under-screen fingerprint recognition module, an infrared light emitting diode, a proximity sensor, or other components capable of sensing light.

Those skilled in the art should understand that the above embodiments are exemplary and not restrictive. Different technical features in different embodiments may be combined to achieve beneficial effects. Those skilled in the art should be able to understand and implement other variations of the disclosed embodiments by studying the accompanying drawings, the specification, and the claims. In the claims, the term “comprise” and its variants do not exclude other apparatus or steps; an article, when not modified by a quantifier, is intended to include one or more entities of the article and may be used interchangeably with “one or more articles”; the terms “first”, “second”, etc., are used to identify names, but not to indicate any particular order. Any reference numeral in the claims should not be construed as limiting the protection scope. A plurality of functions in the claims may be achieved by a single hardware or software module. Some technical features are recited in different dependent claims, but this does not mean that these technical features cannot be combined to achieve beneficial effects.

What is claimed is:

1. A display panel having a display area and a non-display area, the display panel comprising:
a base plate;
a pixel defining layer arranged at one side of the base plate, the pixel defining layer comprising a pixel defining portion and a plurality of pixel openings enclosed and formed by the pixel defining portion;
an isolation structure layer arranged at a side of the pixel defining layer away from the base plate, the isolation structure layer comprising a first isolation layer and a second isolation layer located at a side of the first isolation layer away from the base plate, the isolation structure layer enclosing and forming a plurality of first type of openings located in the display area and a functional opening located in the non-display area, the first type of opening being in communication with a corresponding one of the pixel openings;
a plurality of light-emitting devices, at least a portion of a structure of the light-emitting device being arranged within a corresponding one of the first type of openings; and
a protrusion length of at least a portion of the second isolation layer enclosing and forming the functional opening relative to the first isolation layer and towards the functional opening being less than a protrusion length of the second isolation layer enclosing and forming at least a portion of the first type of openings relative to the first isolation layer and towards the first type of opening.

2. The display panel according to claim 1, wherein the first type of openings comprise a first type of sub-opening and a second type of sub-opening with an opening area less than the first type of sub-opening, and the protrusion length of at least a portion of the second isolation layer enclosing and forming the functional opening relative to the first isolation layer and towards the functional opening is less than a protrusion length of the second isolation layer enclosing and forming the first type of sub-opening relative to the first isolation layer and towards the first type of opening.

3. The display panel according to claim 1, wherein a minimum spacing between an orthographic projection of an edge of the second isolation layer corresponding to the first type of opening on the base plate and an orthographic projection of an edge of a surface of the first isolation layer away from the base plate corresponding to the first type of opening on the base plate is a first spacing, a minimum spacing between an orthographic projection of an edge of the second isolation layer corresponding to the functional opening on the base plate and an orthographic projection of an edge of the surface of the first isolation layer away from the base plate corresponding to the functional opening on the base plate is a second spacing, and the second spacing is less than the first spacing.

4. The display panel according to claim 1, wherein an angle between a surface of the second isolation layer towards the base plate and a surface of the first isolation layer towards the first type of opening is less than an angle between at least a portion of the surface of the second isolation layer towards the base plate and a surface of the first isolation layer towards the functional opening.

5. The display panel according to claim 1, wherein an orthographic projection of an edge of the second isolation layer corresponding to the functional opening on the base plate at least partially overlaps an orthographic projection of an edge of a surface of the first isolation layer away from the base plate corresponding to the functional opening on the base plate.

6. The display panel according to claim 1, wherein the isolation structure layer comprises an isolation structure at least partially located in the display area and an edge structure located in the non-display area, the first type of openings comprise an isolation opening enclosed and formed by the isolation structure, the edge structure encloses and forms the functional opening, and the isolation structure comprises a first isolation portion and a second isolation portion located at a side of the first isolation portion away from the base plate, and
the edge structure comprises a first edge portion and a second edge portion located at a side of the first edge portion away from the base plate, and a protrusion length of at least a portion of the second edge portion relative to the first edge portion and towards the functional opening is less than a protrusion length of the second isolation portion relative to the first isolation portion and towards the isolation opening.

7. The display panel according to claim 6, wherein an orthographic projection of an edge of the second edge portion corresponding to the functional opening on the base plate at least partially overlaps an orthographic projection of an edge of a surface of the first edge portion away from the base plate corresponding to the functional opening on the base plate.

8. The display panel according to claim 6, wherein the functional opening comprises a first recess arranged in an edge area and penetrating the edge structure in a thickness direction of the display panel.

9. The display panel according to claim 8, wherein a protrusion length of at least a portion of the second edge portion relative to the first edge portion and towards the first recess is less than the protrusion length of the second isolation portion relative to the first isolation portion and towards the isolation opening.

10. The display panel according to claim 8, wherein the non-display area comprises a first area adjacent to the display area and a second area located at a side of the first area away from the display area, the edge structure is located in the first area and comprises a main structure connected with the isolation structure and a plurality of convex structures protruding towards the second area relative to the main structure, and the first recess is located between adjacent convex structures.

11. The display panel according to claim 10, wherein the convex structure comprises a first convex portion and a second convex portion located at a side of the first convex portion away from the base plate, and a protrusion length of at least a portion of the second convex portion relative to the first convex portion and towards the functional opening is less than a protrusion length of the second isolation portion relative to the first isolation portion of the isolation structure and towards the isolation opening; or
the main structure comprises a first main portion and a second main portion located at a side of the first main portion away from the base plate, and a protrusion length of at least a portion of the second main portion relative to the first main portion and towards the first recess is less than the protrusion length of the second isolation portion relative to the first isolation portion of the isolation structure and towards the isolation opening.

12. The display panel according to claim 11, wherein an orthographic projection of the second convex portion on the base plate is located within an orthographic projection of the first convex portion on the base plate; or
an orthographic projection of an edge of the second convex portion corresponding to the functional opening on the base plate at least partially overlaps an orthographic projection of an edge of a surface of the first convex portion away from the base plate corresponding to the functional opening on the base plate.

13. The display panel according to claim 11, wherein an orthographic projection of the second main portion on the base plate is located within an orthographic projection of the first main portion on the base plate; or
an orthographic projection of an edge of the second main portion corresponding to the first recess on the base plate at least partially overlaps an orthographic projection of an edge of a surface of the first main portion away from the base plate corresponding to the first recess on the base plate.

14. The display panel according to claim 9, wherein in a direction from the display area to a center of the functional opening, a size of the first recess in a direction perpendicular to a straight line from the display area to the center of the functional opening gradually increases.

15. The display panel according to claim 6, wherein the isolation structure layer further comprises an auxiliary structure located within the functional opening and spaced apart from the edge structure.

16. The display panel according to claim 15, wherein the non-display area comprises a first area adjacent to the display area and a second area located at a side of the first area away from the display area, the edge structure is located in the first area, the second area comprises a first sub-area and a second sub-area located at a side of the first sub-area away from the first area, the auxiliary structure comprises a plurality of first auxiliary structures located in the first sub-area, and the plurality of first auxiliary structures are spaced apart and distributed around a periphery of the second sub-area.

17. The display panel according to claim 16, wherein the first auxiliary structure comprises a first auxiliary portion and a second auxiliary portion located at a side of the first auxiliary portion away from the base plate, and
a protrusion length of at least a portion of the second auxiliary portion relative to the first auxiliary portion and towards the functional opening is less than the protrusion length of the second isolation portion relative to the first isolation portion and towards the isolation opening.

18. The display panel according to claim 17, wherein an orthographic projection of the second auxiliary portion on the base plate is located within an orthographic projection of the first auxiliary portion on the base plate; or
an orthographic projection of an edge of the second auxiliary portion on the base plate at least partially overlaps an orthographic projection of an edge of a surface of the first auxiliary portion away from the base plate on the base plate.

19. The display panel according to claim 16, wherein the display panel is provided with a functional hole in the second sub-area, and the edge structure and the first auxiliary structure are arranged around at least a portion of the functional hole.

20. A display panel having a second sub-area and a display area surrounding the second sub-area;
the display panel comprising:
a base plate;
an isolation structure layer located on the base plate and enclosing and forming an isolation opening;
in a direction away from the base plate, the isolation structure layer comprising a first isolation layer and a second isolation layer that are stacked; and
in the isolation structure layer around the second sub-area, a protrusion length of a side of the second isolation layer in a direction towards the second sub-area relative to the first isolation layer being less than a protrusion length of a side of the second isolation layer in a direction away from the second sub-area relative to the first isolation layer.

21. A method for manufacturing a display panel having a display area and a non-display area, the method comprising:
preparing a pixel defining material layer on a base plate;
preparing an isolation structure layer on the pixel defining material layer, the isolation structure layer comprising a first isolation layer and a second isolation layer located at a side of the first isolation layer away from the base plate, the isolation structure layer enclosing and forming at least a portion of first type of openings located in the display area and a functional opening located in the non-display area, a protrusion length of at least a portion of the second isolation layer enclosing and forming the functional opening relative to the first isolation layer and towards the functional opening being less than a protrusion length of the second isolation layer enclosing and forming at least a portion of the first type of openings relative to the first isolation layer and towards the first type of opening;
depositing a first protective material layer on the isolation structure layer, the first protective material layer forming a first hollow area at the first type of opening located in the display area; and
patterning a portion of the pixel defining material layer exposed from the first hollow area and the first type of opening located in the display area to form at least a portion of pixel openings, the pixel opening being in communication with the first type of opening.

22. The method according to claim 21, wherein the step of preparing the isolation structure layer on the pixel defining material layer comprises:
preparing, on the pixel defining material layer, a first isolation material layer located in the display area and the non-display area;
preparing, on the first isolation material layer, a second isolation material layer located in the display area and the non-display area;
dry etching the first isolation material layer and the second isolation material layer within the display area and the non-display area to form an isolation preliminary structure at least partially located in the display area, an edge preliminary structure connected with the isolation preliminary structure and located in the non-display area, and an auxiliary preliminary structure spaced apart from the edge preliminary structure and located in the non-display area, the isolation preliminary structure enclosing and forming an isolation preliminary opening, the edge preliminary structure enclosing and forming a functional preliminary opening, and the auxiliary preliminary structure being located within the functional preliminary opening; and
wet etching the isolation preliminary structure, the edge preliminary structure, and the auxiliary preliminary structure to form the isolation structure layer.

23. The method according to claim 22, wherein the isolation structure layer comprises an isolation structure at least partially located in the display area, an edge structure connected with the isolation structure and located in the non-display area, and an auxiliary structure spaced apart from the edge structure and located in the non-display area, the auxiliary structure comprises a second auxiliary structure, and after the step of patterning the portion of the pixel defining material layer exposed from the first hollow area and the first type of opening located in the display area to form at least a portion of pixel openings, the method comprises:
perforating the isolation structure layer and the base plate to remove the second auxiliary structure located within the non-display area and a portion of the base plate under the second auxiliary structure and form a functional hole.

24. The method according to claim 21, wherein the step of preparing the isolation structure layer on the pixel defining material layer comprises:
preparing, on the pixel defining material layer, a first isolation material layer located in the display area and the non-display area;
preparing, on the first isolation material layer, a second isolation material layer located in the display area and the non-display area;
preparing a second protective material layer at a side of the second isolation material layer away from the base plate, the second protective material layer having a second hollow area, a first thickness area, and a second thickness area, a thickness of the second protective material layer located in the first thickness area being greater than a thickness of the second protective material layer located in the second thickness area; and
patterning film layers under the second hollow area to form at least a portion of the first type of openings located in the display area; removing the second protective material layer within the second thickness area and retaining a portion of the second protective material layer in the first thickness area, and patterning film layers under the second thickness area to form the functional opening located in the non-display area.

25. The method according to claim 21, wherein the step of preparing the isolation structure layer on the pixel defining material layer comprises:
preparing, on the pixel defining material layer, a first isolation material layer located in the display area and the non-display area;
preparing, on the first isolation material layer, a second isolation material layer located in the display area and the non-display area;
dry etching the first isolation material layer and the second isolation material layer within the display area to form a first type of preliminary opening located within the display area;
wet etching an inner wall of the first type of preliminary opening to form at least a portion of the first type of openings located in the display area; and
dry etching the first isolation material layer and the second isolation material layer within the non-display area to form the functional opening located in the non-display area.

26. The method according to claim 21, wherein the step of preparing the isolation structure layer on the pixel defining material layer comprises:
preparing, on the pixel defining material layer, a first isolation material layer located in the display area and the non-display area;
preparing, on the first isolation material layer, a second isolation material layer located in the display area and the non-display area;
dry etching the first isolation material layer and the second isolation material layer within the display area and the non-display area to form a first type of preliminary opening located within the display area and the functional opening located in the non-display area; and
wet etching an inner wall of the first type of preliminary opening to form at least a portion of the first type of openings located in the display area.

27. A display apparatus, comprising:
the display panel according to claim 1; and
a photosensitive assembly arranged corresponding to the functional opening of the display panel.
